(19) United States
(12) Patent Application Publication
(10) Pub. No.: US 2021/0350481 A1
(43) Pub. Date: Nov. 11, 2021

(54) PROPERTY ENHANCEMENT SERVICES

(71) Applicant: SKYLIGHT TOOLS, INC., San Francisco, CA (US)

(72) Inventors: Fiona Lake Waslander, Toronto (CA); Jasper Malcolmson, San Francisco, CA (US); Josh Levitan, San Francisco, CA (US); Michael Gentili, Toronto (CA); Adam Santangelo, Toronto (CA); Ruslan Spivak, Newmarket (CA)

(21) Appl. No.: 16/426,949

(22) Filed: May 30, 2019

Related U.S. Application Data
(60) Provisional application No. 62/678,453, filed on May 31, 2018.

(51) Int. Cl. G06Q 50/16; G06Q 10/06; G06F 17/50

(52) U.S. Cl. CPC G06Q 50/163; G06F 17/5004; G06Q 10/06315; G06Q 10/06313

(57) ABSTRACT

Systems, methods, and computer-readable media for a property enhancement service are provided that may include automatically translating scope elements of a renovation objective into one or more construction activities that may then be used to determine an amount of work by a property service provider to complete the renovation objective.

### CROSS-REFERENCE(S) TO RELATED APPLICATION(S)

This application claims the benefit of prior filed U.S. Provisional Patent Application No. 62/678,453, filed May 31, 2018, which is hereby incorporated by reference herein in its entirety.

### TECHNICAL FIELD

This disclosure relates to property enhancement services.

### BACKGROUND OF THE DISCLOSURE

Conventional transactions between property managers and property service providers have several disadvantages including, but not limited to, inefficient networking between service seekers and service providers, inability to foster trust between networking parties, inability to facilitate fair market price agreement on service, and/or inability to ensure efficient dispute resolution.

### SUMMARY OF THE DISCLOSURE

This document describes systems, methods, and computer-readable media for a property enhancement service.

For example, a method for managing property renovations using a construction analysis system is provided, where the method may include receiving, at the construction analysis system, a renovation objective for a renovation plan for a property from a property manager, receiving, at the construction analysis system, a plurality of scope elements for the received renovation objective from a property designer, translating automatically, at the construction analysis system, each scope element of the received plurality of scope elements into at least one type of construction activity, receiving, at the construction analysis system, work information for various construction activity types from at least one property service provider, and determining automatically, at the construction analysis system, a work amount by the at least one property service provider for the received plurality of scope elements for the received renovation objective based on the received work information.

As another example, a non-transitory computer-readable storage medium storing at least one program, the at least one program including instructions, which when executed by at least one processor of a construction analysis system, may cause the construction analysis system to receive, at the construction analysis system, a renovation objective for a renovation plan for a property from a property manager, receive, at the construction analysis system, a plurality of scope elements for the received renovation objective from a property designer, translate automatically, at the construction analysis system, each scope element of the received plurality of scope elements into at least one type of construction activity, receive, at the construction analysis system, work information for various construction activity types from at least one property service provider, and determine automatically, at the construction analysis system, a work amount by the at least one property service provider for the received plurality of scope elements for the received renovation objective based on the received work information.

As yet another example, a construction analysis system is provided that may include a memory, a communications component, and a processor communicatively coupled to the memory and the communications component, the processor configured to receive, at the construction analysis system, a renovation objective for a renovation plan for a property from a property manager, receive, at the construction analysis system, a plurality of scope elements for the received renovation objective from a property designer, translate automatically, at the construction analysis system, each scope element of the received plurality of scope elements into at least one type of construction activity, receive, at the construction analysis system, work information for various construction activity types from at least one property service provider, and determine automatically, at the construction analysis system, a work amount by the at least one property service provider for the received plurality of scope elements for the received renovation objective based on the received work information.

This Summary is provided only to summarize some example embodiments, so as to provide a basic understanding of some aspects of the subject matter described in this document. Accordingly, it will be appreciated that the features described in this Summary are only examples and should not be construed to narrow the scope or spirit of the subject matter described herein in any way. Unless otherwise stated, features described in the context of one example may be combined or used with features described in the context of one or more other examples. Other features, aspects, and advantages of the subject matter described herein will become apparent from the following Detailed Description, FIGS., and Claims.

### BRIEF DESCRIPTION OF THE DRAWINGS

The discussion below makes reference to the following drawings, in which like reference characters may refer to like parts throughout, and in which:

FIG. 1 is a schematic view of an illustrative system that may provide a property enhancement service of the disclosure;

FIG. 2 is a more detailed schematic view of a subsystem of the system of FIG. 1;

FIGS. 3,4a-4c, 5a, 5b, 6a-6c, 7-10, 11a-11c, 12, 13, 14a, 14b, 15 19, 22 43, and 45a, 45b, 46, 47a-47d, 48 57 show illustrative screen shots that may presented to users of the PESP system;

FIGS. 20, 21, and 44 show illustrative processes implemented by the PESP system;

FIGS. 58 and 59 show flowcharts of illustrative processes that may provide features of the property enhancement service of the disclosure;

FIGS. 60-66 show flowcharts and illustrative screen shots of an exemplary home visit application of the property enhancement service of the disclosure;

FIG. 67 shows an illustrative screen shot of an exemplary change order submission form of the property enhancement service of the disclosure;

FIGS. 68-79 show illustrative screen shots of exemplary payment processes of the property enhancement service of the disclosure;

FIG. 80 is a flowchart of an illustrative construction analysis process of the property enhancement service of the disclosure;

FIGS. 81-83 show illustrative screen shots that may presented to users of the PESP system during a construction analysis process of the property enhancement service of the disclosure; and

FIGS. 84-89 show illustrative data structures that may be used during a construction analysis process of the property enhancement service of the disclosure.

### DETAILED DESCRIPTION OF THE DISCLOSURE

A property enhancement service is provided that may be operative to enable property managers and property service providers to engage with one another in an effective and/or efficient manner for executing successful transactions.

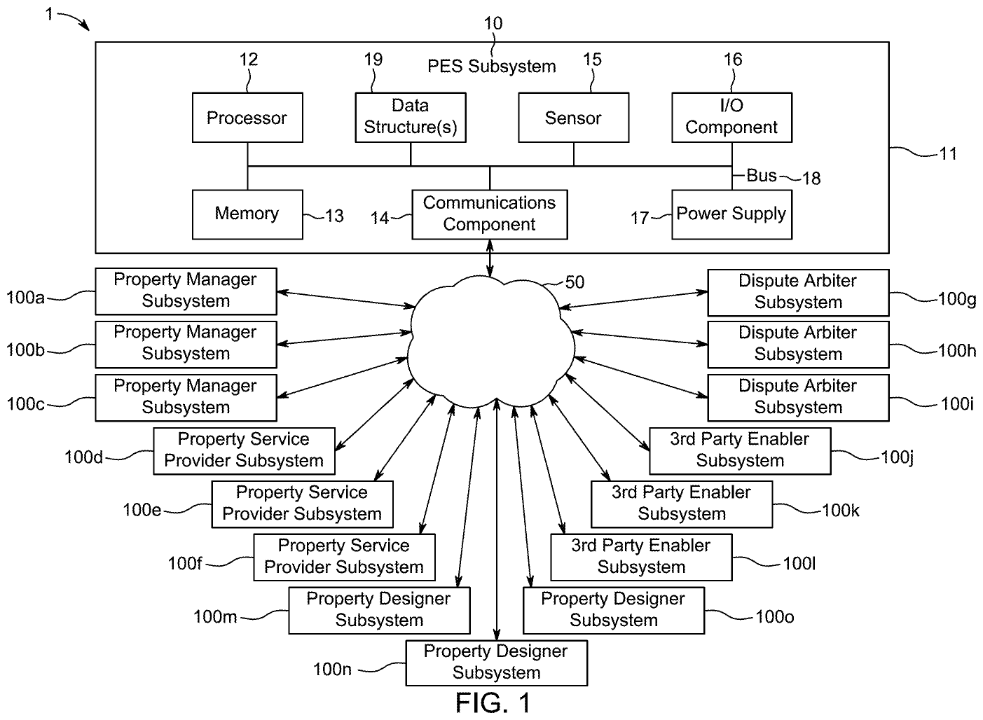

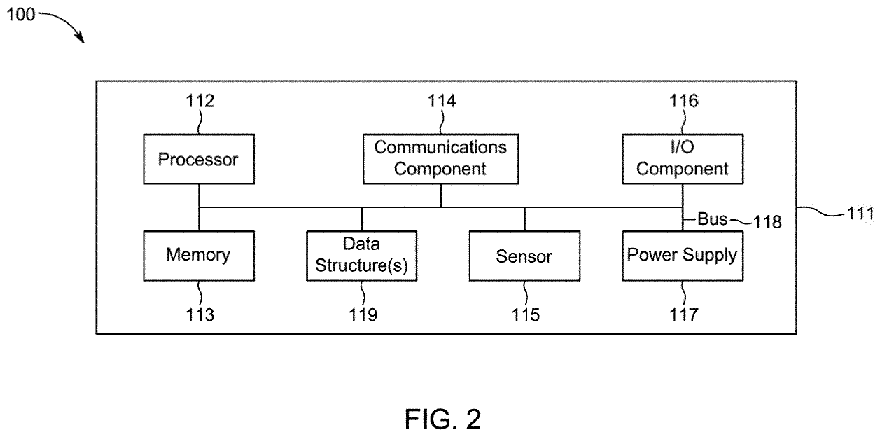

### Description of FIG. 1 and FIG. 2

FIG. 1 is a schematic view of an illustrative system 1 in which a property enhancement service may be facilitated amongst various entities. For example, as shown in FIG. 1, system 1 may include a property enhancement service (“PES”) subsystem 10, various subsystems 100 (e.g., one or more property manager (“PM”) subsystems 100a-100c, one or more property service provider (“PSP”) subsystems 100d-100f, one or more dispute arbiter (“DA”) subsystems 100g-100i, one or more third party enabler (“TPE”) subsystems 100j-1001, and/or one or more property designed subsystems 100m-100o), and at least one communications network 50 through which any two or more of the subsystems 10 and 100 may communicate. PES subsystem 10 may be operative to interact with any of the various subsystems 100 to provide a property enhancement service platform (“PESP”) of system 1 that may facilitate various property enhancement services, including, but not limited to, enabling property managers and property service providers to engage with one another in an effective and/or efficient manner for executing successful transactions in any suitable language(s) across any suitable network(s).

As shown in FIG. 2, and as described in more detail below, a subsystem 100 may include a processor component 112, a memory component 113, a communications component 114, a sensor component 115, an input/output (“I/O”) component 116, a power supply component 117, and/or a bus 118 that may provide one or more wired or wireless communication links or paths for transferring data and/or power to, from, or between various other components of subsystem 100. I/O component 116 may include at least one input component (e.g., a button, mouse, keyboard, microphone, etc.) to receive information from a user of subsystem 100 and/or at least one output component (e.g., an audio speaker, video display, haptic component, etc.) to provide information to a user of subsystem 100, such as a touch screen that may receive input information through a user's touch on a touch sensitive portion of a display screen and that may also provide visual information to a user via that same display screen. Memory 113 may include one or more storage mediums, including for example, a hard-drive, flash memory, permanent memory such as read-only memory (“ROM”), semi-permanent memory such as random access memory (“RAM”), any other suitable type of storage component, or any combination thereof. Communications component 114 may be provided to allow one subsystem 100 to communicate with a communications component of one or more other subsystems 100 or subsystem 10 or servers using any suitable communications protocol (e.g., via communications network 50). Communications component 114 can be operative to create or connect to a communications network for enabling such communication. Communications component 114 can provide wireless communications using any suitable short-range or long-range communications protocol, such as Wi-Fi (e.g., an 802.11 protocol), Bluetooth, radio frequency systems (e.g., 1200 MHz, 2.4 GHz, and 5.6 GHz communication systems), infrared, protocols used by wireless and cellular telephones and personal e-mail devices, or any other protocol supporting wireless communications. Communications component 114 can also be operative to connect to a wired communications network or directly to another data source wirelessly or via one or more wired connections or a combination thereof. Such communication may be over the internet or any suitable public and/or private network or combination of networks (e.g., one or more networks 50). Sensor 115 may be any suitable sensor that may be configured to sense any suitable data from an external environment of subsystem 100 or from within or internal to subsystem 100 (e.g., light data via a light sensor, audio data via an audio sensor, location-based data via a location-based sensor system (e.g., a global positioning system (“GPS”)), etc.). Power supply 117 can include any suitable circuitry for receiving and/or generating power, and for providing such power to one or more of the other components of subsystem 100. Subsystem 100 may also be provided with a housing 111 that may at least partially enclose one or more of the components of subsystem 100 for protection from debris and other degrading forces external to subsystem 100. Each component of subsystem 100 may be included in the same housing 111 (e.g., as a single unitary device, such as a laptop computer or portable media device) and/or different components may be provided in different housings (e.g., a keyboard input component may be provided in a first housing that may be communicatively coupled to a processor component and a display output component that may be provided in a second housing, and/or multiple servers may be communicatively coupled to provide for a particular subsystem). In some embodiments, subsystem 100 may include other components not combined or included in those shown or several instances of the components shown.

Processor 112 may be used to run one or more applications, such as an application that may be provided as at least a part of one data structure 119 that may be accessible from memory 113 and/or from any other suitable source (e.g., from PES subsystem 10 via an active internet connection). Such an application data structure 119 may include, but is not limited to, one or more operating system applications, firmware applications, communication applications, internet browsing applications (e.g., for interacting with a website provided by PES subsystem 10 for enabling subsystem 100 to interact with an online service of PES subsystem 10 (e.g., a PESP)), PES applications (e.g., a web application or a native application or a hybrid application that may be at least partially produced by PES subsystem 10 for enabling subsystem 100 to interact with an online service of PES subsystem 10 (e.g., a PESP)), or any other suitable applications. For example, processor 102 may load an application data structure 119 as a user interface program to determine how instructions or data received via an input component of I/O component 116 or via communications component 114 or via sensor component 115 or via any other component of subsystem 100 may manipulate the way in which information may be stored and/or provided to a user via an output component of I/O component 116 and/or to any other subsystem via communications component 114. As one example, an application data structure 119 may provide a user with the ability to interact with a property enhancement service or the PESP of PES subsystem 10, where such an application 119 may be a third party application that may be running on subsystem 100 (e.g., an application associated with PES subsystem 10 that may be loaded on subsystem 100 from PES subsystem 10 or via an application market) and/or that may be accessed via an internet application or web browser running on subsystem 100 (e.g., processor 112) that may be pointed to a uniform resource locator (“URL”) whose target or web resource may be managed by PES subsystem 10 or any other remote subsystem. Each subsystem 100 may be a portable media device (e.g., a smartphone), a laptop computer, a tablet computer, a desktop computer, an appliance, a wearable electronic device, a virtual reality device, at least one web or network server (e.g., for providing an online resource, such as a website or native online application, for presentation on one or more other subsystems) with an interface for an administrator of such a server, and/or the like. 100251 PES subsystem 10 may include a housing 11 that may be similar to housing 111, a processor component 12 that may be similar to processor 112, a memory component 13 that may be similar to memory component 113, a communications component 14 that may be similar to communications component 114, a sensor component 15 that may be similar to sensor component 115, an I/O component 16 that may be similar to I/O component 116, a power supply component 17 that may be similar to power supply component 117, and/or a bus 18 that may be similar to bus 118. Moreover, PES subsystem 10 may include one or more data sources or data structures or applications 19 that may include any suitable data or one or more applications (e.g., any application similar to application 119) for facilitating a property enhancement service or PESP that may be provided by PES subsystem 10 in conjunction with one or more subsystems 100. Some or all portions of PES subsystem 10 may be operated, managed, or otherwise at least partially controlled by an entity (e.g., administrator) responsible for providing a property enhancement service to one or more clients or other suitable entities.

PES subsystem 10 may communicate with one or more subsystems 100 via communications network 50. Network 50 may be the internet or any other suitable network, such that when intercoupled via network 50, any two subsystems of system 1 may be operative to communicate with one another (e.g., a subsystem 100 may access information (e.g., from a data structure 19 of PES subsystem 10, as may be provided as a property enhancement service via processor 12 and communications component 14 of PES subsystem 10) as if such information were stored locally at that subsystem 100 (e.g., in memory component 113)).

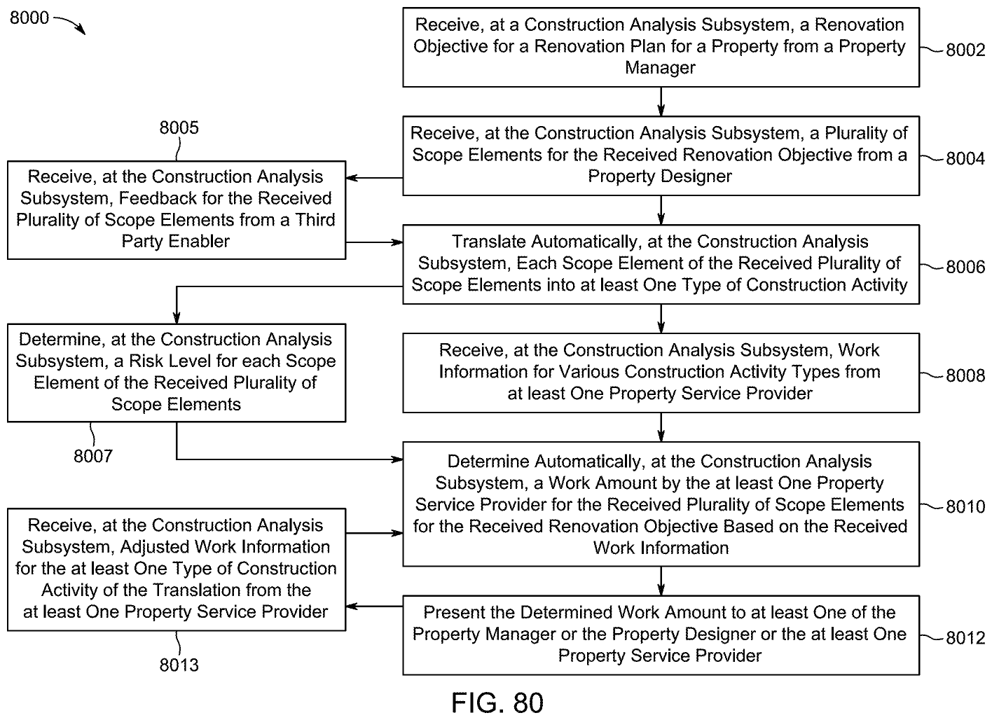

Various clients and/or partners may be enabled to interact with PES subsystem 10 for enabling the property enhancement services and the PESP. For example, at least one property manager subsystem of system 1 (e.g., each one of the one or more property manager subsystems 100a-100c) may be operated by any suitable property manager (“PM”) that may own, rent, or otherwise manage one or more pieces of property (e.g., plot of land, apartment unit, office unit, house, commercial building, residential apartment building, and/or any other suitable piece of real property or structure thereon or thereunderneath or any structure for land or air or sea (e.g., dock at a cottage, outdoor bathroom, swimming pool, landscaping work, fence, storage building, garage, infrastructure (e.g., water pipes, wells, septic systems, electrical systems, solar panels, etc.), house boat, floating house, etc.)). A PM may be referred to herein as a “homeowner” or “customer” that may be desirous of a renovation to be made to its property. For example, as described with respect to FIGS. 80-89, a renovation of a PM's property may be designed, scoped, costed or priced, and planned by the PESP. However, the PESP is not isolated to homeowners and may apply to any suitable PM, including, but not limited to, landlords, property managers, small business owners, or project managers hired to manage the build or renovation of a dwelling or other structure. Throughout this document the term “homeowner” may be used to generically refer to a customer or PM of the PESP. At least one property service provider subsystem of system 1 (e.g., each one of the one or more property service provider subsystems 100d-100f) may be operated by any suitable property service provider (“PSP”) that may provide any suitable service to a piece of property of a property manager (e.g., any suitable contractor or vendor or other party that may build, demolish, repair, enhance, design, dig, zone, add infrastructure to, landscape (e.g., treat agriculture or soil), garden (e.g., work on trees as an arborist), inspect, appraise, consult on, or otherwise adjust a characteristic of a piece of property (e.g., at the request of a property manager)). Throughout this document the term “contractor” may be used to generically refer to a PSP of the PESP (e.g., a construction professional who may ultimately lead an actual construction or renovation process). At least one dispute arbiter subsystem of system 1 (e.g., one or more of the one or more dispute arbiter subsystems 100g-100i) may be operated by any dispute arbiter (“DA”) that may have any suitable relationship to the subject matter of any suitable project between one or more PMs and one or more PSPs (e.g., any suitable arbiter or collection of arbiters, such as an arbiter PESP user, subject matter experts, regular citizens, licensed arbiters, lawyers, PMs and/or PSPs who have used the PESP, and/or the like). At least one third party enabler subsystem of system 1 (e.g., each one of the one or more third party enabler subsystems 100j-1001) may be operated by any suitable third party enabler (“TPE”) that may be operative to enable at least partially any suitable operation provided by the PESP, such as a third party application or service provider that may be operative to process or provide any suitable subject matter (e.g., financial institutions that may provide any suitable financial information or credit scores or transmit or receive payments of any suitable party, social networks that may provide any suitable connection information between various parties or characteristic data of one or more parties, government agencies/regulators, licensing bodies, third party advertisers, owners of relevant data, sellers of relevant goods/materials, software providers (e.g., a provider of project management, accounting/invoicing, and/or enterprise resource planning (“ERP”) software), trade associations, and/or any other suitable third party service provider distinct from a PSP and PES subsystem 10). For example, a TPE may be referred to herein as a “third party specialist,” which may be a consultant that may review renovation plans to ensure that they abide by code standards (e.g., a Structural Engineer, HVAC (Heating, Venting, Air Conditioning) Engineer, MEP (Mechanical, Electrical, Plumbing) Engineer, etc.). At least one property designer subsystem of system 1 (e.g., each one of the one or more property designer subsystems 100m-100o) may be operated by any suitable property designer (“PD”) that may be operative to enable at least partially any suitable operation provided by the PESP, such as an application or service provider that may be operative to design a renovation or construction of a property for a PM. Throughout this document the term “designer” or “architect” may be used to generically refer to a PD of the PESP (e.g., an entity that may be a designer or architect who may design a renovation, which may include scope and materials based on a homeowner's objectives).

Each subsystem 100 of system 1 (e.g., each one of subsystems 100a-100o) may be operated by any suitable entity for interacting in any suitable way with PES subsystem 10 (e.g., via network 50) for deriving value from and/or adding value to a service of the PESP of PES subsystem 10. For example, a particular subsystem 100 may be a server operated by a client/partner entity that may receive any suitable data from PES subsystem 10 related to any suitable property enhancement of the PESP provided by PES subsystem 10 (e.g., via network 50). Additionally or alternatively, a particular subsystem 100 may be a server operated by a client/partner entity that may upload or otherwise provide any suitable data to PES subsystem 10 related to any suitable property enhancement service of the PESP provided by PES subsystem 10 (e.g., via network 50).

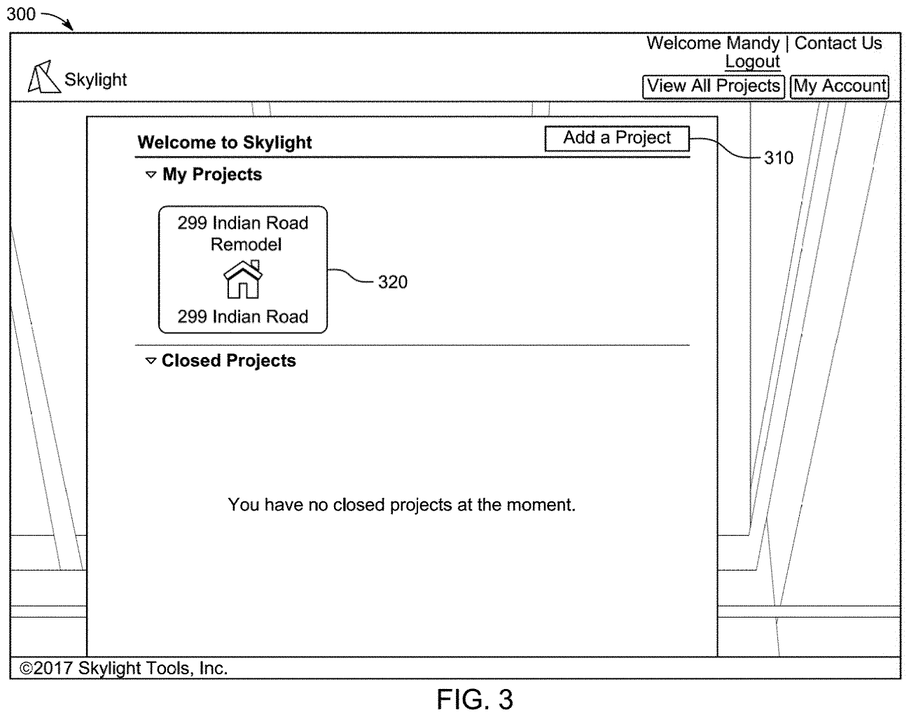

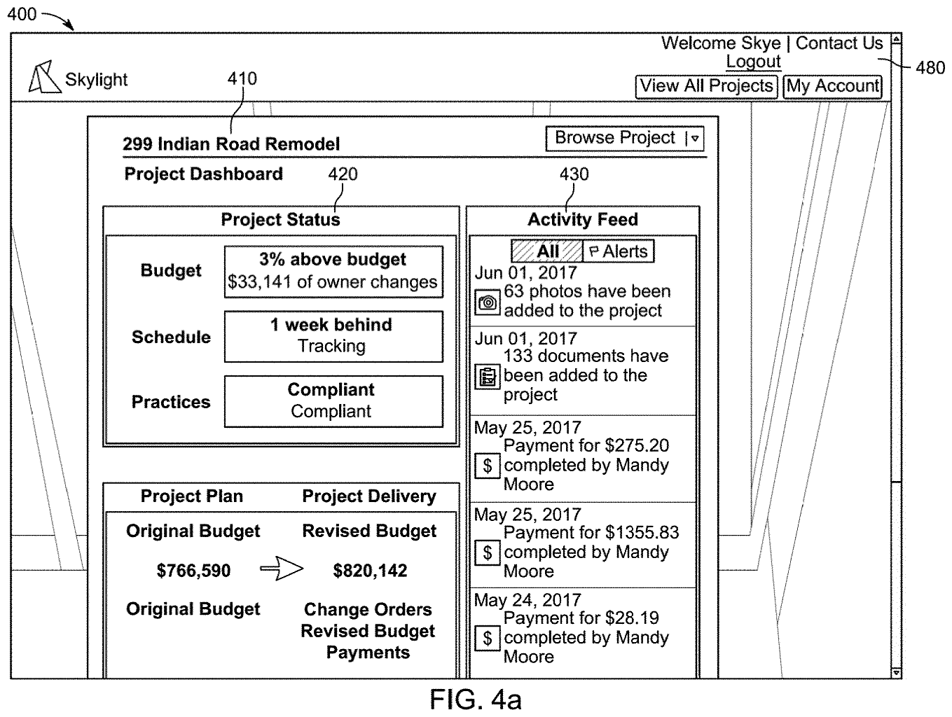

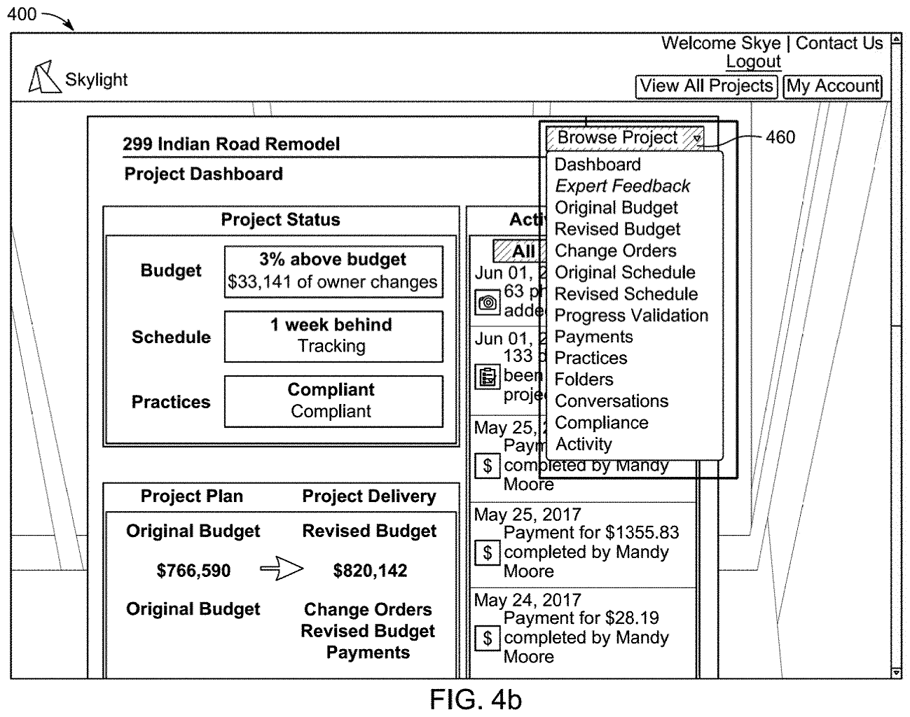

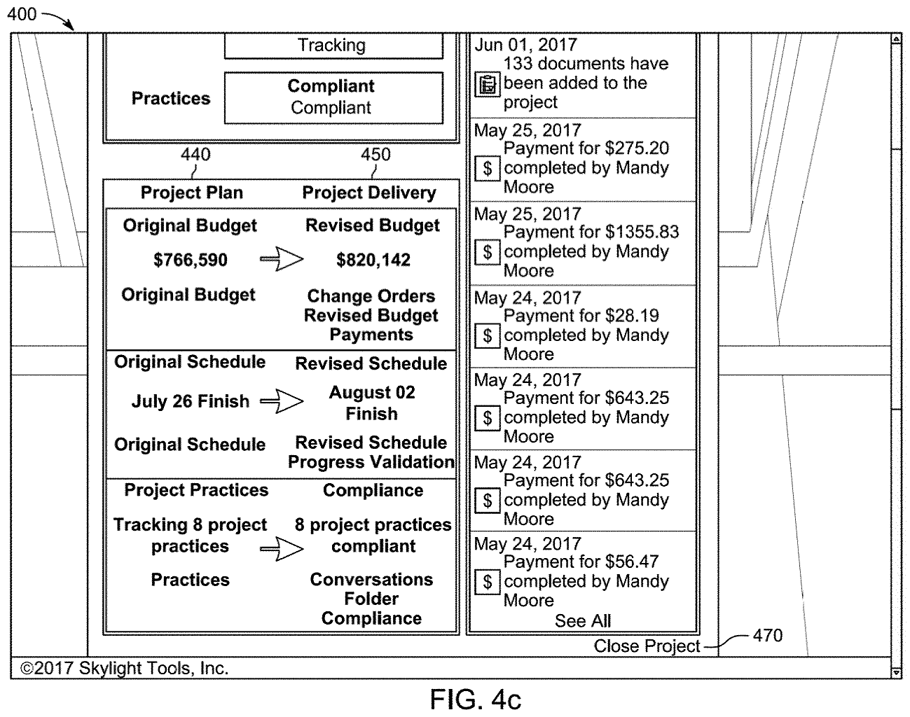

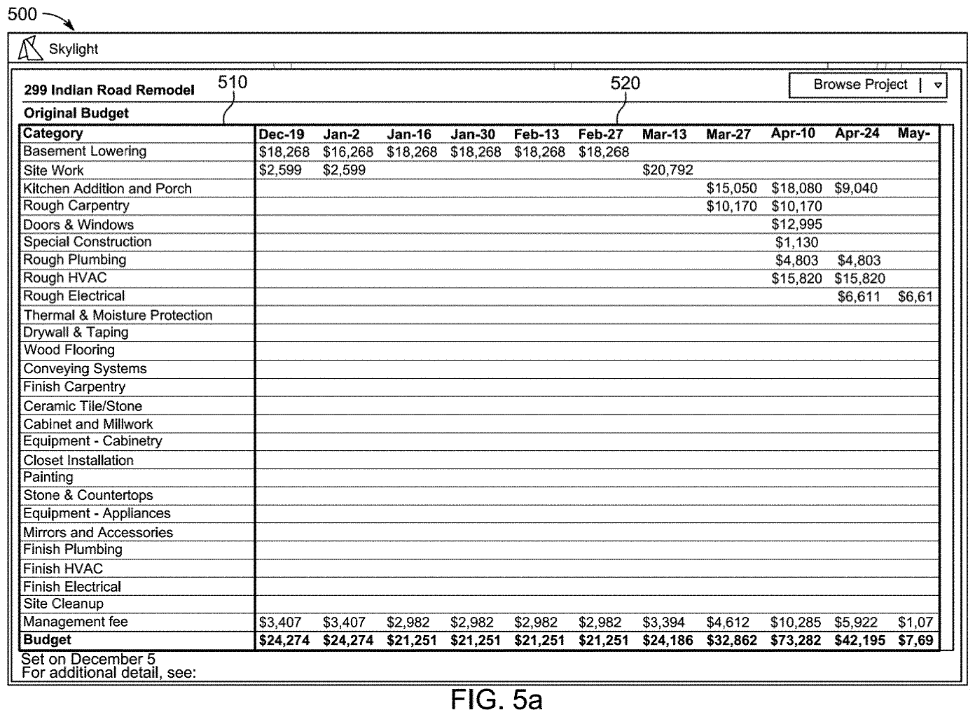

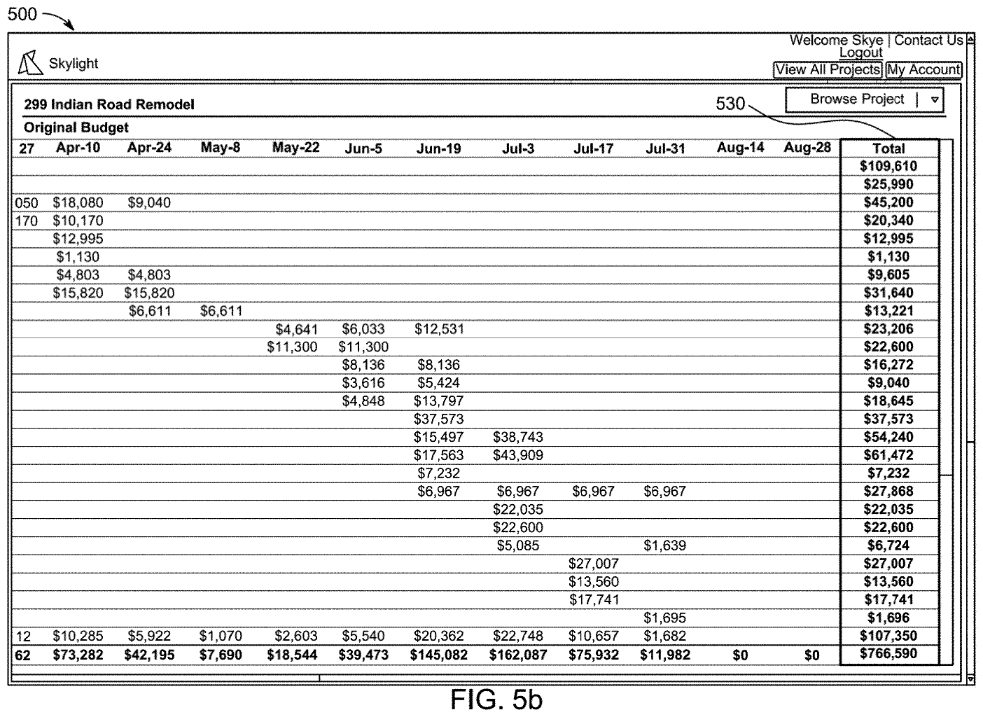

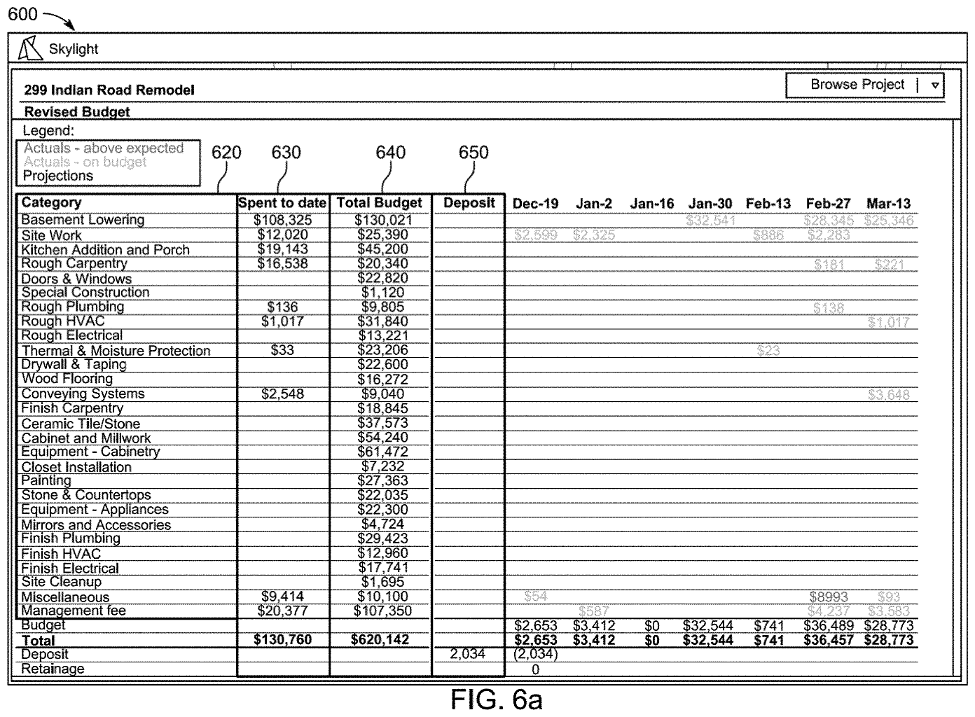

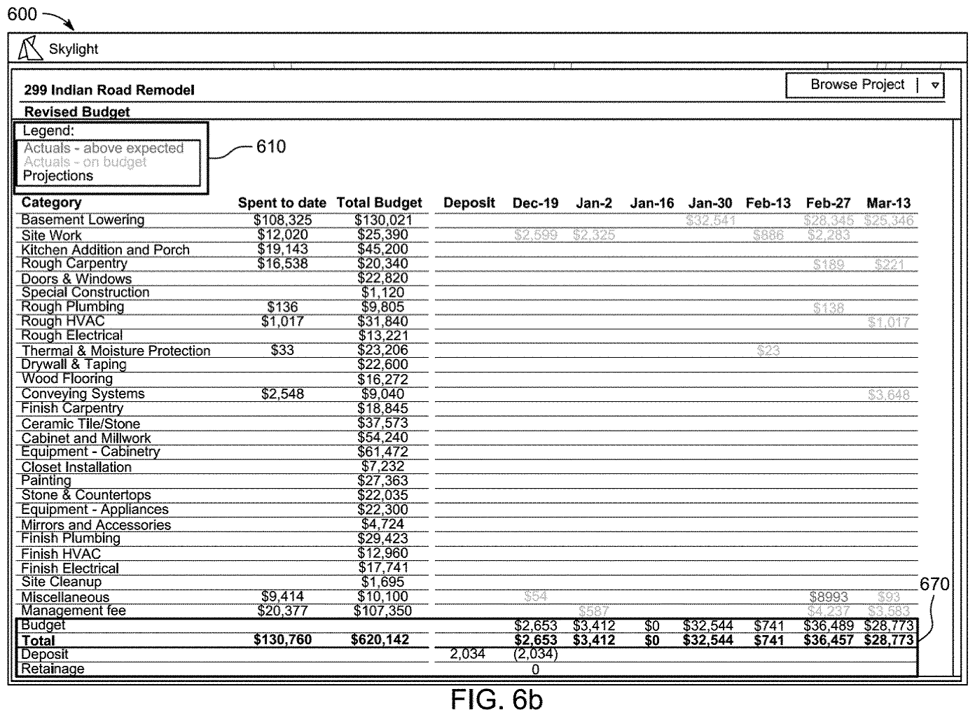

### Description of FIGS. 3-57

PESP system 1 may help the homeowner manage their home renovation project and helps to keep the project on budget and on schedule.

Some of the many features that may be enabled or otherwise facilitated by the PESP of system 1 may include, but are not limited to, the following:
Full budget and schedule down to the cost category is laid out at the beginning of the project
Every cost that is incurred on a project is tracked and compared to the original budget
Any costs that are new are documented and approved only if they are appropriate cost increases
All invoices are reconciled
All progress phases are tracked and approved when work is complete
   Additional features as follows (not exhaustive list) provide the homeowner additional support on their home renovation project:
Document and photo repository
Archive of SMS and email conversations
Easy access to project status
Log of all Skylight project activity
Record of compliance agreement with contractor
Payment functionality
Full payment history

FIGS. 3-57 show illustrative screen shots that may presented to users of PESP system 1 (e.g., on a graphical user interface of any suitable output component of any suitable user subsystem 100).

FIG. 3 shows an illustrative user interface of my projects 300. The “My Projects” page displays all of a user's active and inactive projects. By selecting a project from this page, the user navigates to the dashboard of the selected project. Add a project button 310 can redirect the user to the “Contact Us” page. Each project element 320 can display a unique project's name and address. Clicking on the square redirects the user to that project's dashboard.

FIGS. 4a through 4c show an illustrative user interface of project dashboard 400. The “Project Dashboard” page displays an overview of a project's current status. At the top left corner of this page, the user's project name 410 appears. Project dashboard 400 includes windows 420, 430, 440, and 450 that provide information about the user's project. “Project Status” window 420 displays an updated summary of the user's budget overrun, schedule overrun, and whether or not the general contractor is in compliance with 8 (or any other suitable number of) predefined (and agreed to) best practices. The color of the squares toggles between Green, Yellow and Red to indicate “on track,” “mild problems,” and “serious problems,” respectively. “Activity Feed” window 430 displays all recent activity by date, activity type and action. The “All” button toggles the display of all recent activity, and the “Alerts” button toggles the display of only activity that has been flagged on a separate page. “Project Plan” window 440 displays the budget and schedule from the initial project estimate. It also shows how many project practices (of 8) have been agreed to by the general contractor and the homeowner. “Project Delivery” window 450 displays an updated forecast for the budget and schedule based on current project progress data. It also displays how many project practices are being followed.

Project dashboard 400 also includes buttons 460, 470, and 480. The “Browse Project” button 460 is a drop down box that allows the user to toggle between the pages of their project on the web application. At the bottom right corner on the page, the “Close Project” button 470 redirects users to the Contact Us page. At the top right corner of the page, buttons 480 redirect the user to different pages. Buttons 480 can include a “Logout” button that logs the user out and redirects the user to the homepage, a “Contact Us” button that redirects the user to another page with Skylight contact information, a “View All Projects” button that redirects the user to the “My Projects” page, and a “My Account” button that redirects the user to their account information.

FIGS. 5a and 5b show an illustrative user interface of original budget 500. The “Original Budget” page displays a granular breakout of a project's original budget estimate. Expected spending per category is broken out into invoice periods from the beginning to the end of the project. Spending estimates are then displayed in a Gantt chart format. Left hand column 510 itemizes and describes a category of work to be completed over the course of the project. Middle column 520 displays invoice periods with the amount of spending expected for each category in each time period shown. These values are summed at the bottom of the column for the invoice period. Right hand column 530 adds up and reflects the total expected category spend over the course of the project.

FIGS. 6a through 6c show an illustrative user interface of revised budget 600. The “Revised Budget” page actively displays actual project cash flows, which includes dollars spent per category in each invoice period that has passed and forecasts for future invoice periods. As the project progresses, forecasts are updated to reflect actuals. Legend 610 at the top of the page explains the color coding system to the user, with red reflecting actuals above expected, green reflecting actuals on budget, and grey reflecting projections. Revised budget 600 includes columns 620, 630, 640, 650, and 660. Left hand column 620 itemizes and describes a category of work to be completed over the course of the project, which are the exact same categories reflected in original budget column 510. “Spend to date” column 630 displays the sum of all actual dollars spent on the project for each category to date. “Total Budget” column 640 displays the total dollar amount allocated to each category per the original budget. “Deposit” column 650 displays the dollar amount (if any) paid as a deposit in the beginning of the project. At the far right, “Total” column 660 displays the total dollar amount allocated to each category per the original budget. In some embodiments, dark grey vertical lines are used to indicate the current period. Bottom rows 670 reflect the sum of the actuals/projects for each invoice period. They also keep track of cash flows such as deposit made and retainage.

FIG. 7 shows an illustrative user interface of change orders 700. The “Change Orders” page, which includes chart 710 and 720, displays the details of change orders submitted over the course of the project. This page sums the total value of change order costs and records by whom the change order was initiated. Chart 710 is a summary of changes, which sums the total dollar value of the change orders submitted on the project to date. Chart 720 includes a more detailed description of the change orders with columns reflecting the change order number, status, cost impact, schedule impact, cause, and description of the change order. The “Change Order” column displays the assigned number for identification purposes. The “Status” column displays whether the submitted change order has been accepted by the receiving party. The “Cost Impact” column displays the increase in cost that will occur if and when the change order work occurs. The “Schedule Impact” column displays the total delay in time that will occur if and when the change order work occurs. The “Cause” column displays the party that initiated the change order. For example, a change order is “homeowner driven” if the work is related to a homeowner design decision. The change order is “contractor driven” if the work is related to an unforeseen site condition. The “Description” column displays a short description of the work to be completed per the change order.

FIG. 8 shows an illustrative user interface of original schedule 800. The “Original Schedule” page displays a projection for which category of work will be completed during which invoice period(s), mapped to the same cost categories of the budget. The full project schedule is displayed in a Gantt chart format. Left hand column 810 itemizes and describes a category of work to be completed over the course of the project, which are the same categories reflected in original budget column 510. Right hand column 820 displays an invoice period with the grey bars below indicating what work will be completed during that period. The category of work corresponds to the left-hand column.

FIG. 9 shows an illustrative user interface of revised schedule 900. The “Revised Schedule” page actively displays when work is complete on the project and a forward looking schedule for work that is remaining. Left hand column 910 itemizes and describes a category of work to be completed over the course of the project, which are the same categories reflected in original budget column 510. As in the original schedule, right hand column 920 displays an invoice period with dark grey vertical lines used to indicate the current period. Dark Green indicates work that was completed on schedule. Dark red indicates work that has exceeded the original time estimate. Light green and red bars are forecasts for when the remaining work will be completed. For example, work on basement lowering began on January 16^{th}, was continued to April 24^{th}, and is expected to finish by May 8^{th}.

FIG. 10 shows an illustrative user interface of progress validation 1000. The “Progress Validation” page breaks the user's project into phases. Each phase includes a list of tasks to be completed for that phase, photos of the work in progress, and a sign-off for the contractor and homeowner to confirm that work has been completed and reviewed. The name of the phase is shown at the top with columns 1010, 1020, and 1030 shown below. “Task” column 1010 displays tasks to be completed, which are categorized as materials, labor or other. “Photo and Files” column 1020 displays uploaded photos as a thumbnail with a short description. A Skylight operator uses the photos to validate that work has been completed. This prevents fraud and ensures that homeowners only pay for work that has been completed. “Review” column 1030 displays the status of the phase review. For example, the contractor “Ron Smith” has signed-off that Phase 1 of this project has been completed properly. It is to be understood that Skylight may be interchangeably used with the PESP or an operator of the PESP as a term generally referring to the system or platform and underlying technology (e.g., as operated by an operator of PES subsystem 10).

FIGS. 11a through 11c show an illustrative user interface of payment history and schedule 1100. The “Payments History and Schedule” page displays all transactions and cash flows sent from the project payer to the project payee. In addition to the payment details, copies of relevant documents (invoices, lien waivers etc.) are accessible under each line item. Payment history and schedule 1100 includes chart 1110 which displays information regarding each transaction. The “Title” column displays a short description of the payment (e.g. Invoice 2912), the “Payment Schedule” column displays the date when the payment was made, the “Current Budget” column displays the amount of cash being transferred, and the “Payment Status” column displays the dollar amount that has been transferred. When a payment line is fully displayed, as shown in expanded line 1120, additional sections displayed include uploaded documents, comments, and a full description of the transaction. At the bottom of chart 1110, sum 1130 is shown, which reflects the sum of cash paid to date. Also shown below sum 1130 is remaining payment 1140, which reflects payments requested minus payments made.

Payment history and schedule 1100 also includes button 1150 and link 1160. “Edit Payment Schedule” button 1150 reconfigures the page to allow users to edit payment details. The “Add more scheduled payments” link 1160 redirects the user to a page that allows them to input new payment lines. At the bottom of the page, “Make a payment” button 1170 allows homeowners to make payments. Payments are facilitated for homeowners to contractors through a 3rd party.

FIG. 12 shows an illustrative user interface of project practices 1200. The “Project Practices” page outlines eight best practices for ensuring a successful project defined by Skylight and includes an approval flow to capture the agreement made by both parties. This page displays which of the practices have been agreed to by both the Homeowner and the Contractor.

FIG. 13 shows an illustrative user interface of my project folder 1300. The “My Project Folder” page displays all files uploaded to the project. Files are grouped into folders that correspond to tags that the files are given when uploaded. Tags can be added or removed at any time, and a variety of file types are accepted, including JPG, PDF, DOC and video files. My project folder 1300 also includes “Upload files” button 1310, which opens a window that can be used to upload files, and “Reorder folders” link 1320, which toggles the configuration of the page to allow or not allow reordering of the folders.

FIGS. 14a through 14b show an illustrative user interface of conversations 1400. The “My Conversations” page displays all communication between parties with access to the project. Conversations 1400 includes SMS conversations 1410, which is a unique SMS “channel” (unique phone number) that is set up to be like a group chat for the project. The group chat always includes a Skylight operator. The group chat can be used to submit photos and documents, ask questions, or just have a discussion about the project. All SMS conversations are logged and archived to be displayed on the website. A user may only see the log on the website if they have been a participant in the SMS group chat. For example, if the group chat was just between the homeowner and the Skylight operator, it would not be visible to the contractor.

Conversations 1400 also includes Email conversations 1420. Similar to the SMS “channel”, there is a unique project email address setup for each project. Participants on the project (homeowner, contractor, architect, etc.) carbon copy (“CC”) the project email address as they do their regular email exchanges for the project. All emails with the project email address CC'ed are logged, archived and displayed on the website. The Skylight operator will also see all emails in their own inbox and has the ability to reply to all participants, so the project email address can be used to ask the operator questions and submit documents/photos/change orders. A user can only see emails on the web site for which they have been copied. For example, an email from homeowner to architect with the project email address CC'ed, will not be visible to the contractor.

FIG. 15 shows an illustrative user interface of chatbot 1500. The “Chatbot” page allows the operator to create new group SMS messages and access previously created SMS channels between parties with access to a project.

FIG. 16 shows an illustrative user interface of compliance 1600. The “Compliance” page displays whether or not the agreed upon practices (outlined on the “project practices” page) are being followed. Chart 1610 includes a “Practice” column with a short description of the practice and a “Compliance” column where green indicates compliance and yellow indicates non-compliance.

FIG. 17 shows an illustrative user interface of activity feed 1700. The “Activity Feed” page displays the same activity items as on the dashboard. Types of activity include file uploads (photos, invoices, change orders, etc.), updates to payment information (new payments, completed payments, etc.), conversations (new messages, file uploads, etc.), schedule updates and compliance updates. As shown in activity list 1710, each item corresponds to an activity on the project, and includes the type of activity, the magnitude of the activity, and who has completed the activity. Activity list 1710 can be filtered by filter 1720, a filtering tool that allows users to alter what type of activity is displayed on the right.

FIG. 18 shows an illustrative user interface of contact us 1800. The “Contact Us” page displays a phone number, an embedded email system, and social media accounts that can be used to contact a Skylight operator. Contact us 1800 also includes a “Find Contractors” button 1810 that redirects user to a web form to assist with looking for a general contractor or subcontractors.

FIG. 19 shows an illustrative user interface of my account information 1900. The “My Account Information” page displays the user's inputted information and gives them the option to edit it at any time.

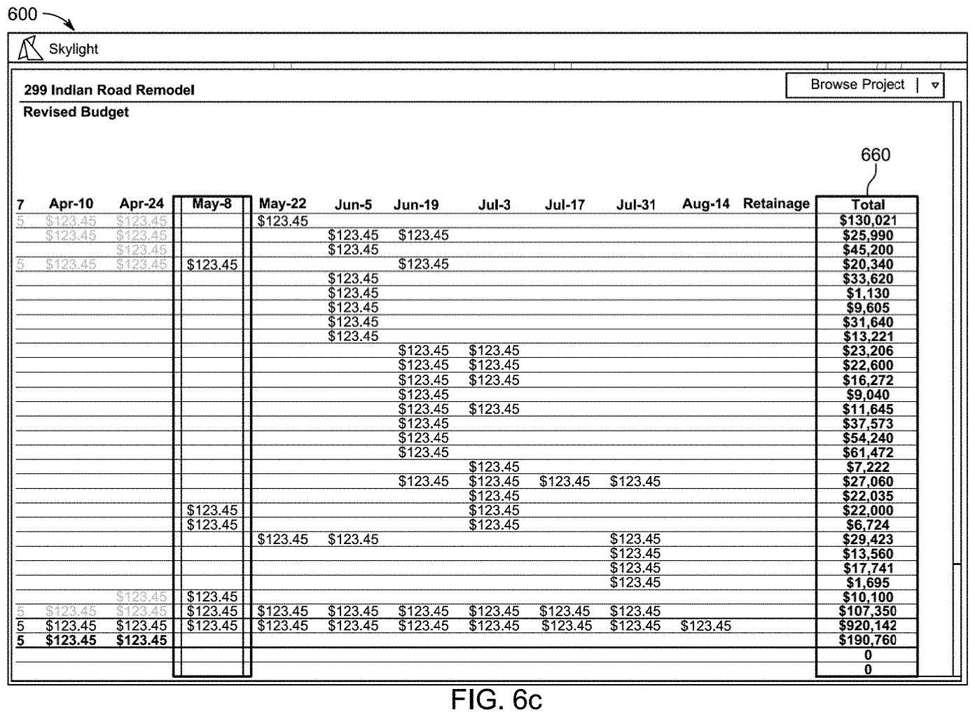

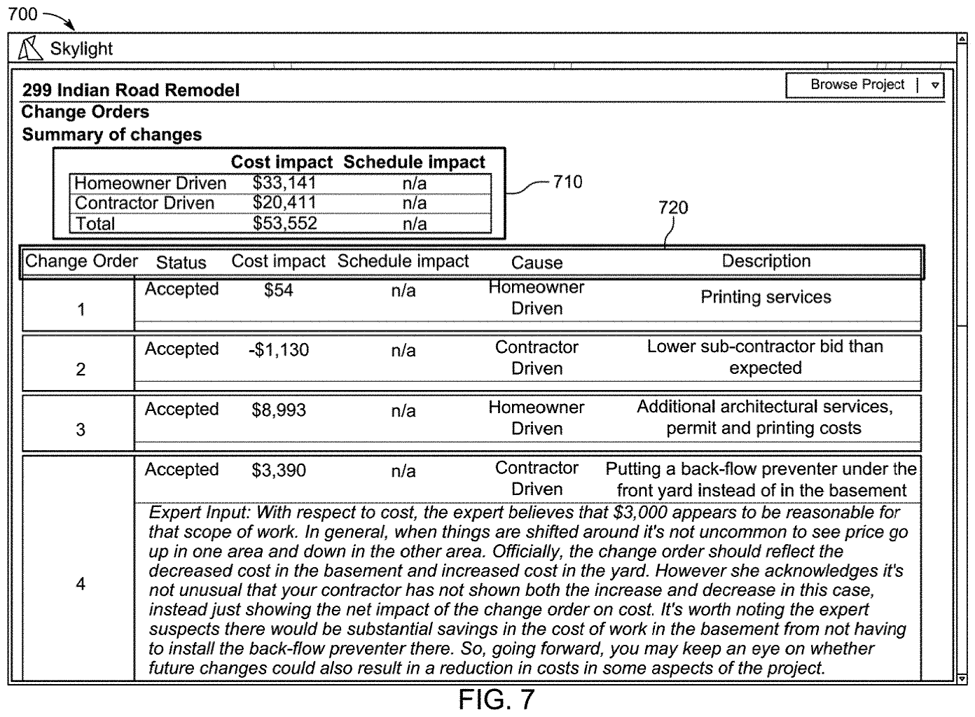

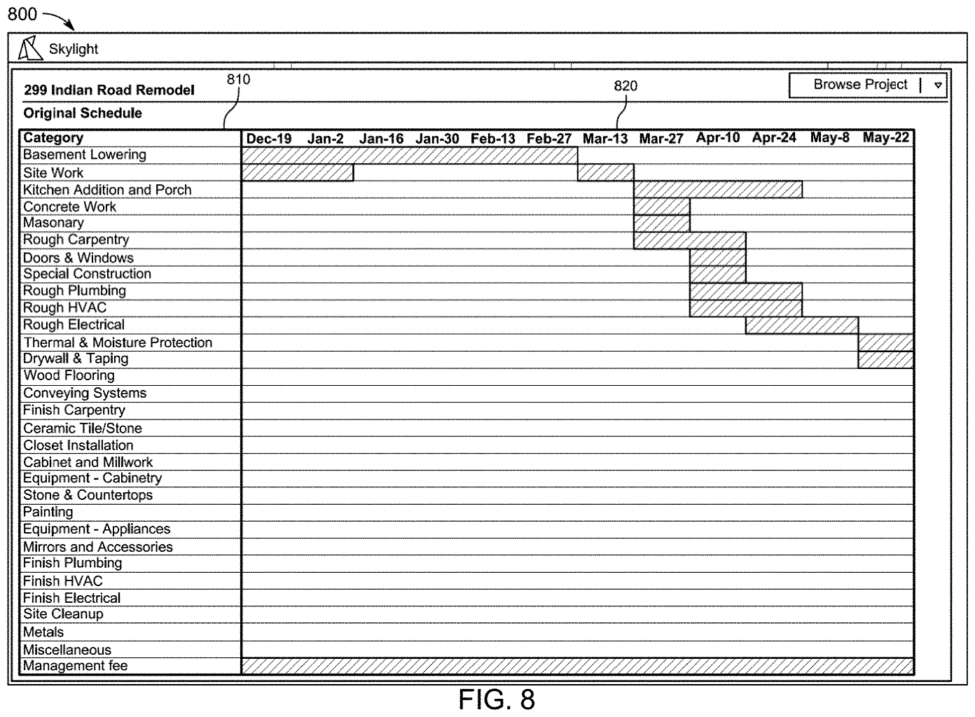

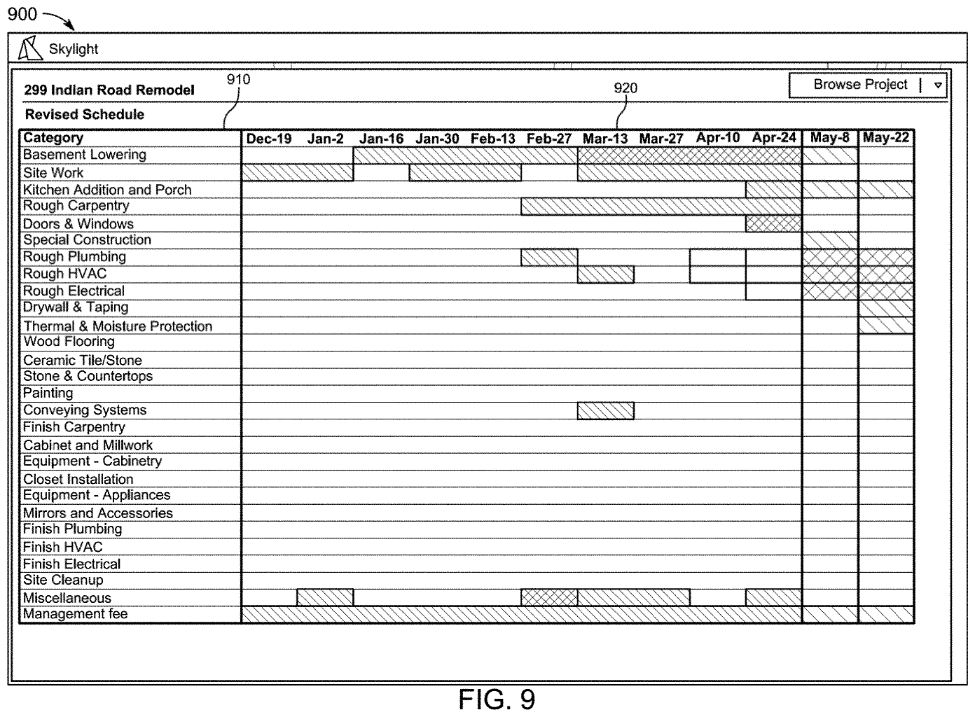

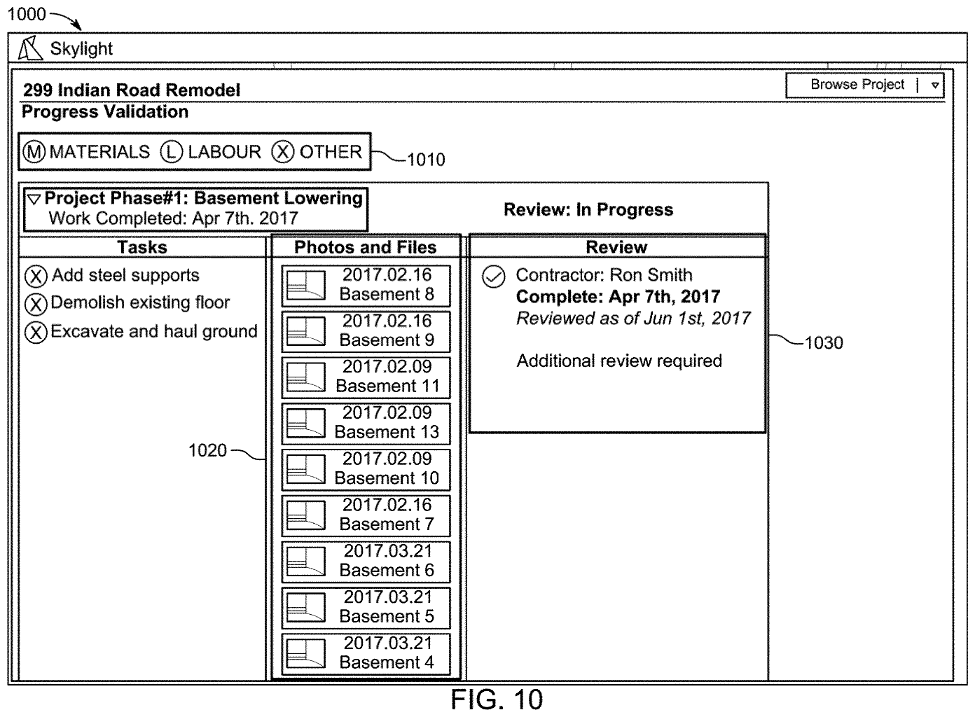

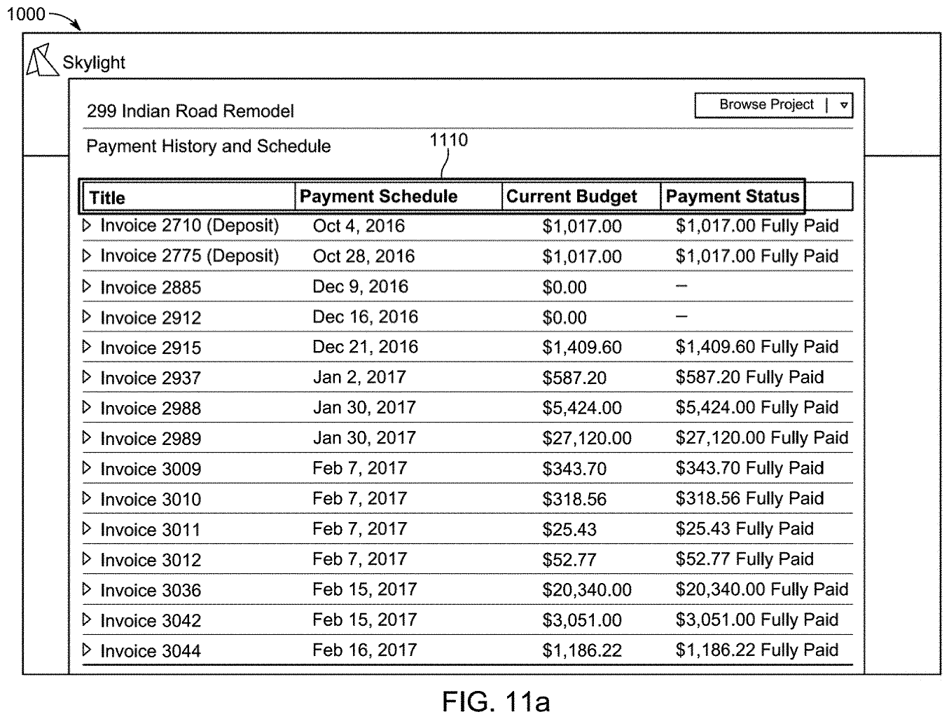

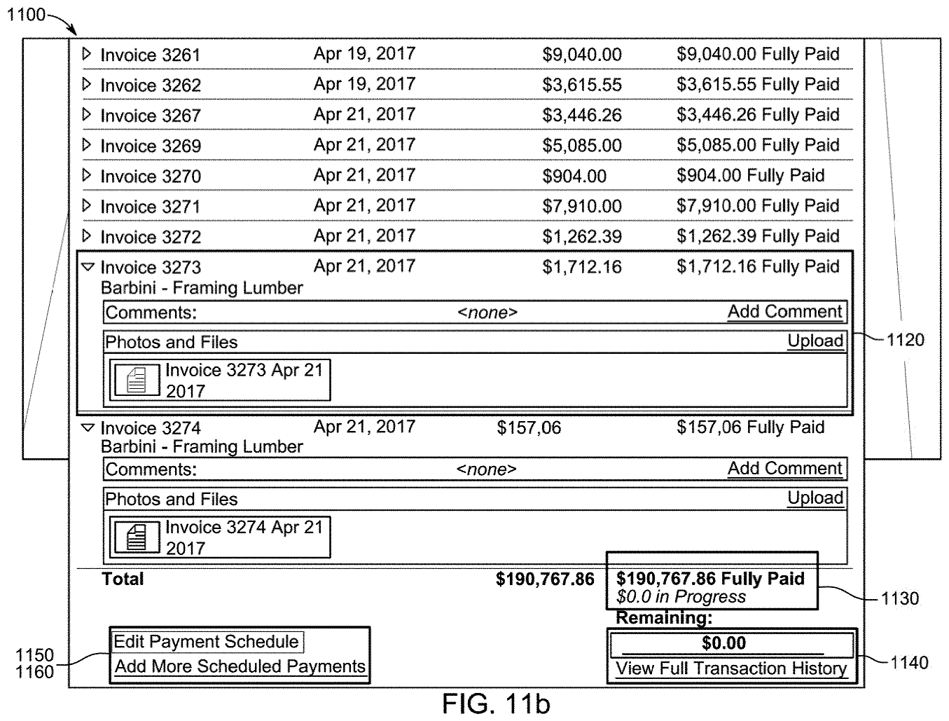

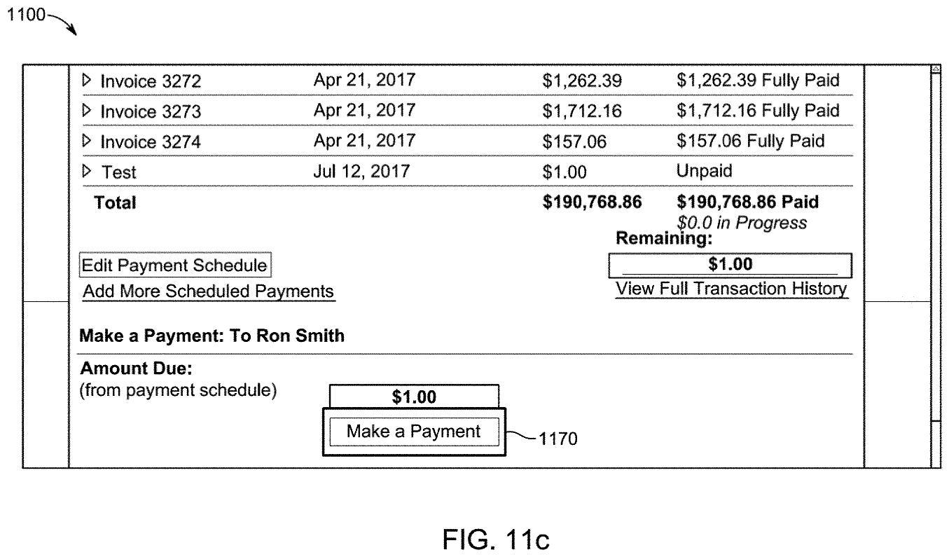

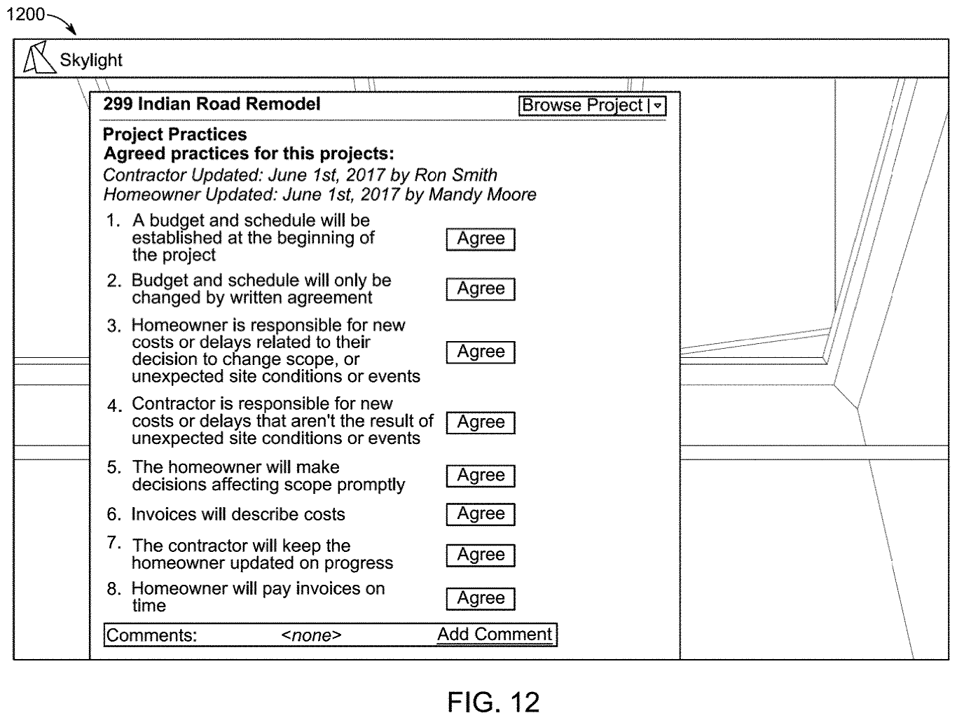

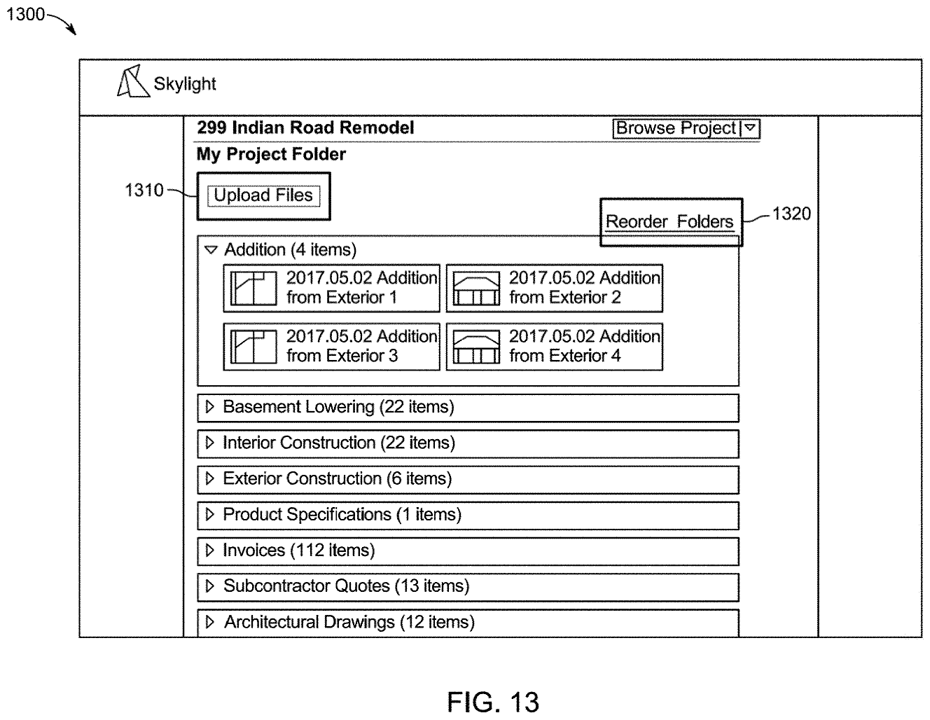

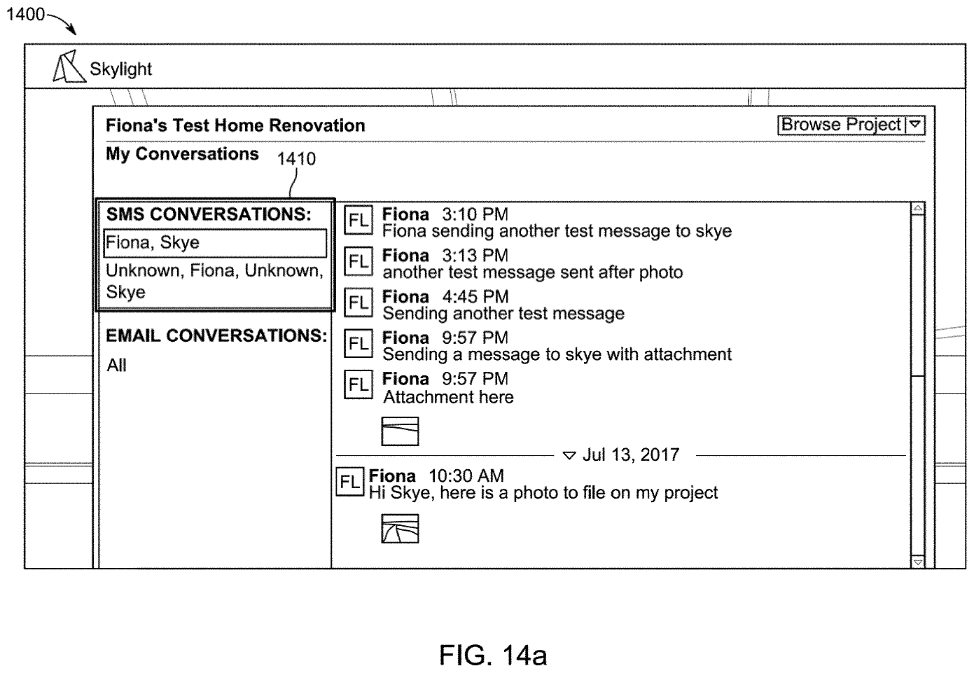

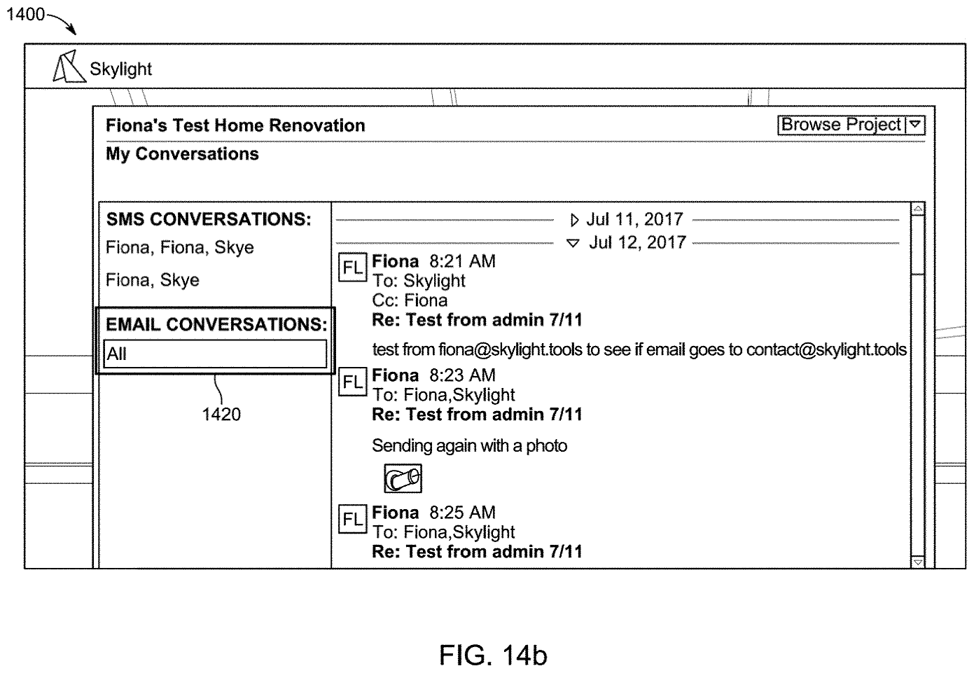

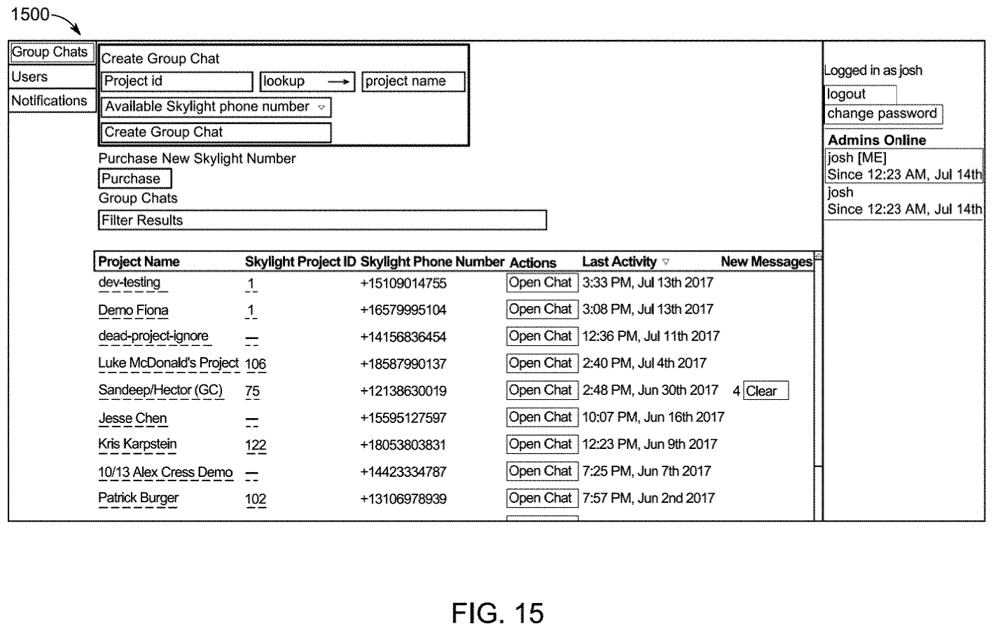

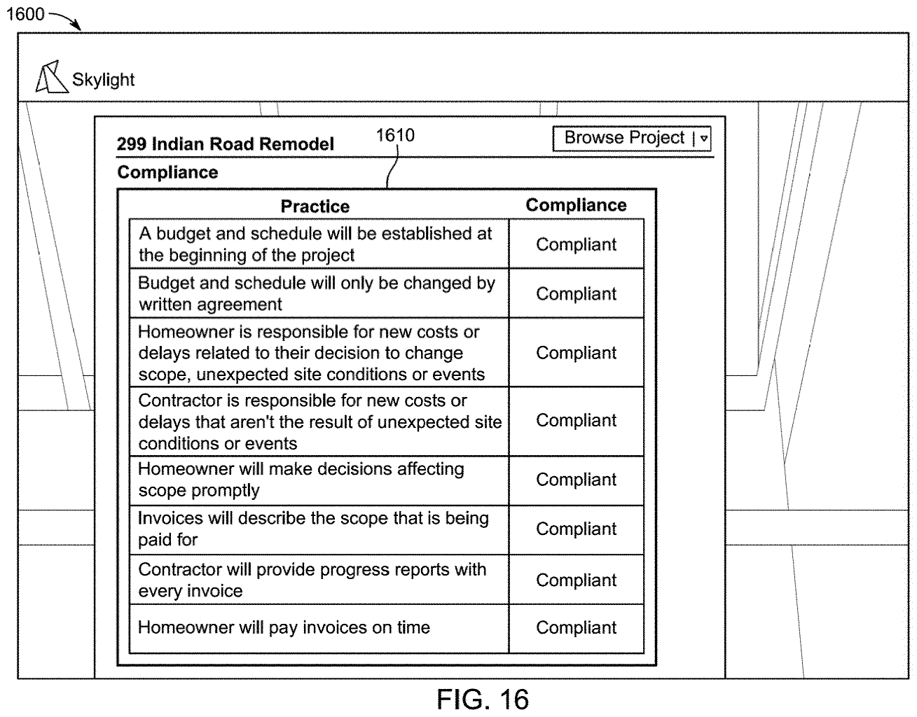

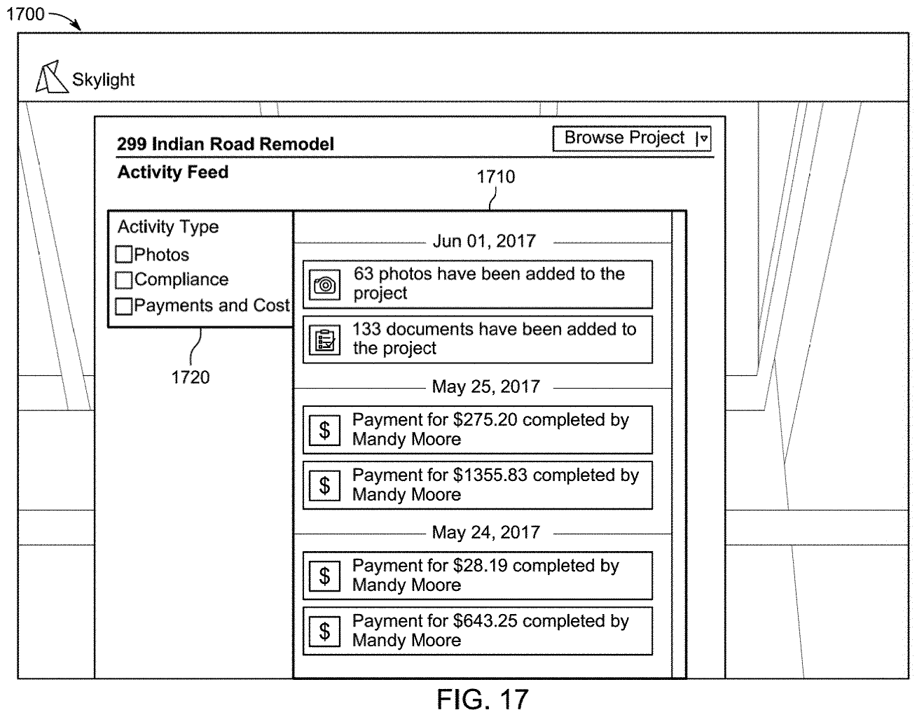

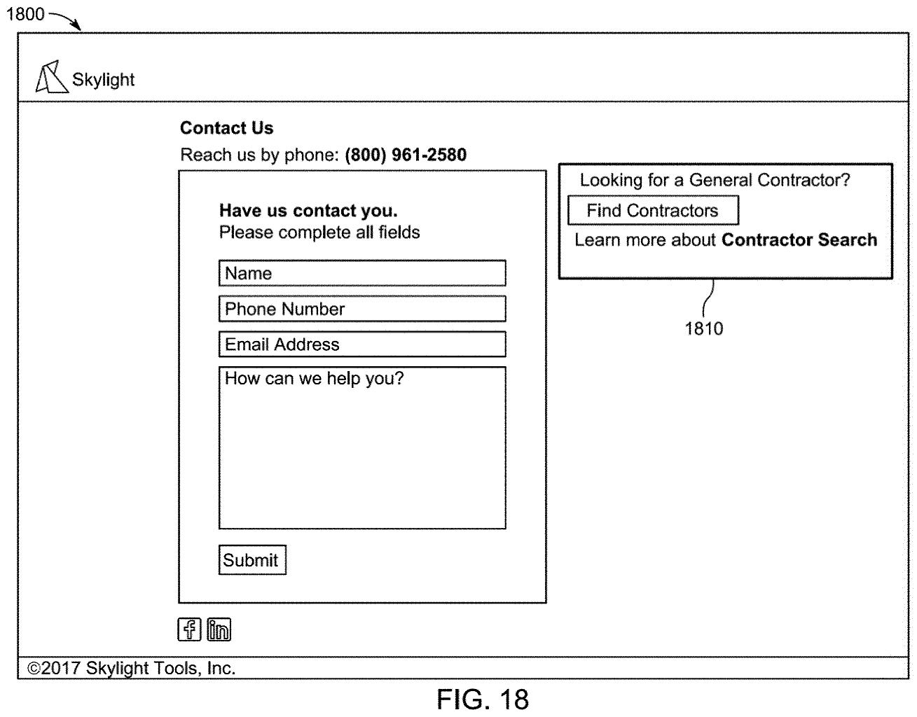

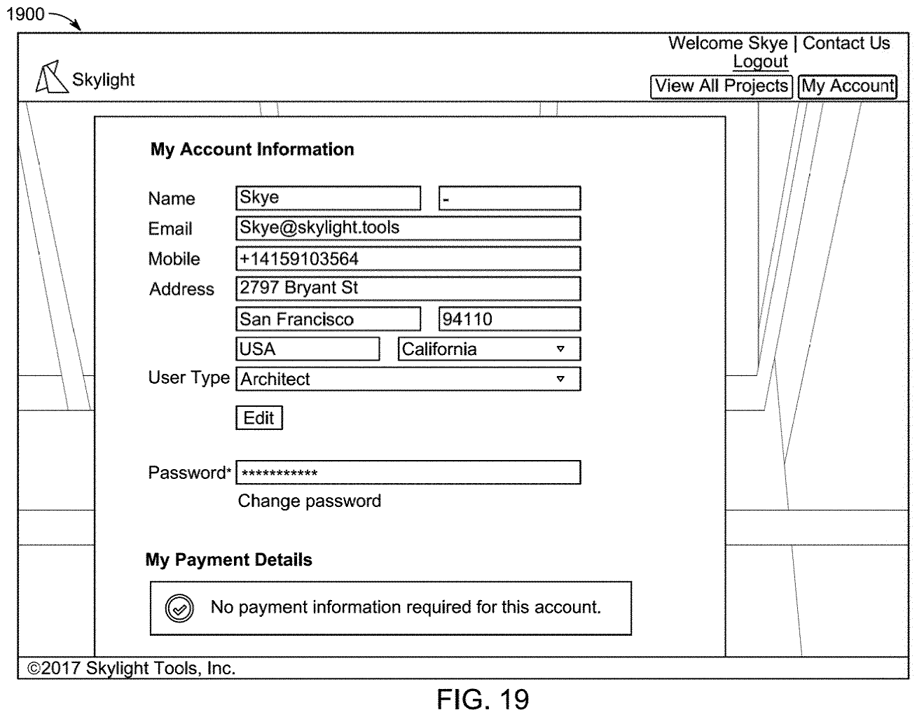

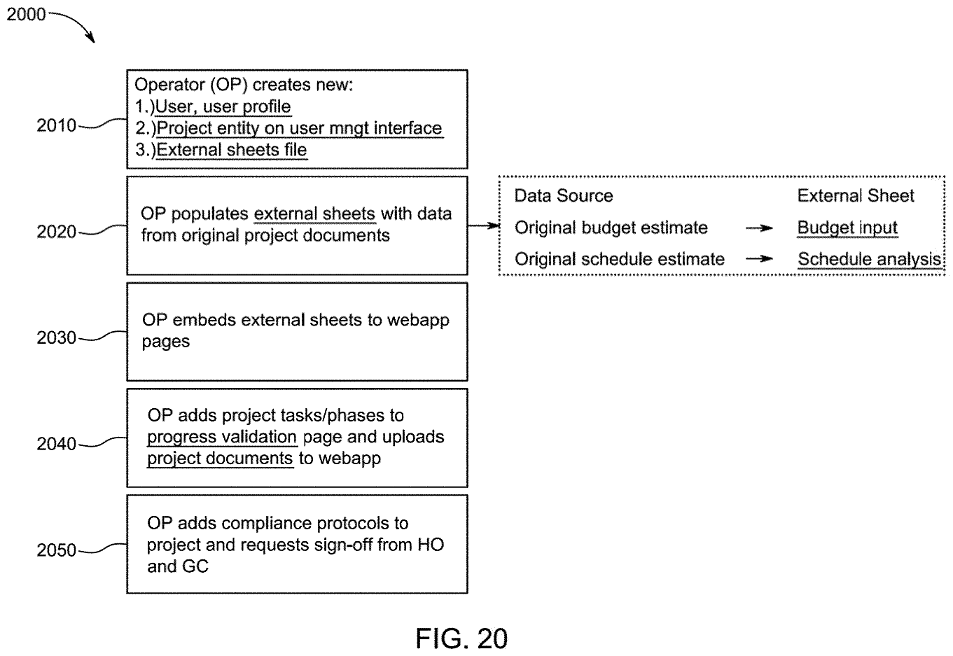

An Operator is responsible or initial project setup and project updates. In a project setup, once initial project documents have been received, the operator initiates the project setup process and notifies the homeowner once it is complete. The project setup process flow is shown in FIG. 20. As a project begins, Homeowners forward the operator invoices, change orders and photos of work in progress. These documents are analyzed by the operator who then takes the appropriate action given the nature of the document. Photos are uploaded to the progress validation page and tagged to the appropriate project phase. Invoices and change orders are reviewed by the operator. The operator flags documents that appear unusual and alerts the Homeowner. After the documents have been reviewed, the budget input, change order inputs and schedule analysis sheets are updated to reflect the new payment/budget information. Once the appropriate sheets are up to date, the documents are uploaded to the project and tagged to the appropriate project payment

FIG. 20 shows an illustrative high-level operator process 2000 for project setup according to an embodiment. After project documents are received, the operator initiates the project setup process which involves 5 major operations. In first operation 2010, the operator creates a new user and user profile, a new project entity on the user management interface, and a new external sheets file. In second operation 2020, the operator populates external sheets with data from original project documents. In third operation 2030, the operator embeds external sheets to web application pages. In fourth operation 2040, the operator adds project tasks and phases to progress validation page and uploads project documents to web application. In fifth operation 2050, the operator adds compliance protocols to project and requests sign-off from homeowner and general contractor.

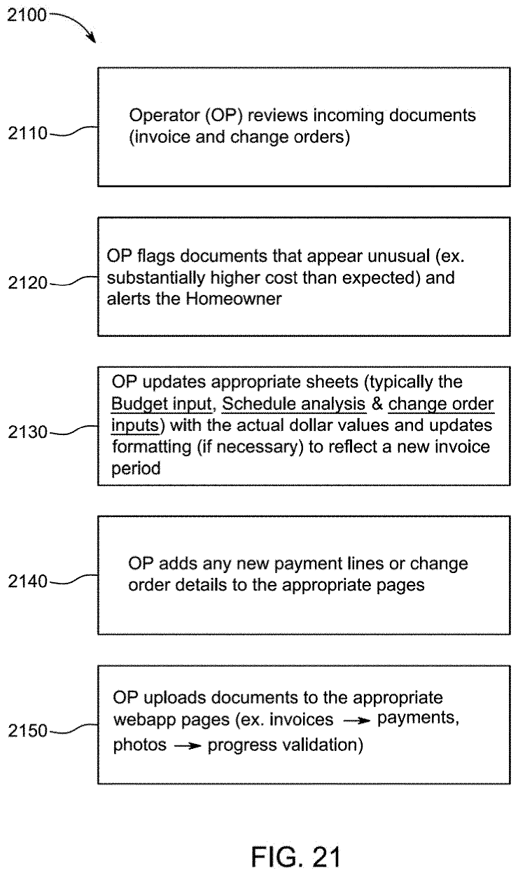

FIG. 21 shows an illustrative high-level operator process 2100 for project updates according to an embodiment. In first operation 2110, the operator reviews incoming documents (invoice and change orders). In second operation 2120, the operator flags documents that appear unusual (e.g. substantially higher cost than expected) and alerts the homeowner. In third operation 2130, the operator updates appropriate sheets (typically the budget input, schedule analysis, and change order inputs) with the actual dollar values and updates formatting (if necessary) to reflect a new invoice period. In fourth operation 2140, the operator adds any new payment lines or change order details to the appropriate pages. In fifth operation 2150, the operator uploads documents to the appropriate web application pages.

FIG. 22 shows an illustrative operator interface of Skylight user management home 2200. The “Skylight user management” system is the operator's primary interface. From the home page 2200, the operator has access to the back-end of every web page. In some cases, this is where information is inputted for the web page, in others, this is a record all of information through web interface. Home page 2200 includes windows 2210 and 2220. Window 2210 includes various features for the operator to access and edit information. The features can include the following: (1) Accounts Application, which gives the operator access to edit user web application login information and create web application login tokens; (2) Activities, which empowers the operator to edit activity information on the web application; (3) Attachments, which allows the operator to edit all files uploaded to the project; (4) Email Conversations, which is a set of features that gives the operator access to add/delete or edit emails sent via the platform; (5) Payments Application, which is a set of features that allows the operator to add/delete or edit the details of payments sent via the embedded platform payment system (wepay); and (6) Projects Application, which is a set of features used by the operator to create new projects and link the external pages that power the web application. Window 2220 displays a list of all recent actions taken on the backend interface.

FIG. 23 shows an illustrative operator interface of accounts application 2300. The “Accounts Application” is a set of features that gives the operator access to edit user web application login information and create web application login tokens. This feature is used to create new users during project setup.

FIG. 24 shows an illustrative operator interface of activities 2400. “Activities” is a set of features that gives the operator access to add/delete or edit the items of the activity feed on the web application.

FIG. 25 shows an illustrative operator interface of attachments 2500. “Attachments” is a feature that gives the operator access to add/delete or edit all files uploaded to any given project.

FIG. 26 shows an illustrative operator interface of email conversations 2600. “Email Conversations” is a set of features, including feature 2610, 2620, and 2630, that gives the operator access to add/delete or edit emails sent through the project-specific email address (as displayed in “My Conversations” on the web application). “Email threads” feature 2610 displays all emails sent via the platform grouped into threads. “Emails” feature 2620 displays the history of all individual emails sent via the platform. “Send Email” feature 2630 is used by the operator to send emails to users.

FIG. 27 shows an illustrative operator interface of send emails 2700. “Send emails” is a feature that is used by the operator to send emails to users and allows the operator to initiate a project email thread with participants with a project-specific email address.

FIG. 28 shows an illustrative operator interface of payments application 2800. The “Payments application” is a set of features, including feature 2810, 2820, and 2830, that allows the operator to add/delete or edit the details of payments sent via the embedded platform payment system (wepay). “Payments” feature 2810 displays the details of all payment lines added to projects, including transactions that occur off the platform. “Transaction history” feature 2820 displays every payment attempted and completed via the platform (3rd party payment provider) mapped to each project. “Transactions” feature 2830 displays all attempted and completed transactions on the platform (through the 3rd party payment provider).

FIG. 29 shows an illustrative operator interface of payments 2900. The “Payments” page displays the details of all payment lines added to projects, including transactions that occur off the platform.

FIG. 30 shows an illustrative operator interface of transactions 3000. The “Transactions” page displays all attempted and completed transactions on the platform (through the 3rd party payment provider).

FIG. 31 shows an illustrative operator interface of transaction history 3100. The “Transaction History” page displays every payment attempted and completed via the platform (3rd party payment provider) mapped to each project.

FIG. 32 shows an illustrative operator interface of projects application 3200. The “Projects Application” is a set of features used by the operator to create new projects and link the external pages that power the web application.

FIG. 33 shows an illustrative operator interface of change orders 3300. The “Change orders” page displays the details of every change order submitted to a project on the web application.

FIG. 34 shows an illustrative operator interface of comments 3400. The “Comments” page displays all additional information added to a project's payments, phases or practices.

FIG. 35 shows an illustrative operator interface of conversations 3500. The “Conversations” page displays a list of SMS channels, and a record of messages sent between homeowners, the operator and contractors is logged here.

FIG. 36 shows an illustrative operator interface of external pages 3600. The “External pages” page displays all external data sheets that are linked to active projects and embedded in the web site experience. Left hand column 3610 displays the identification number assigned to an external page for identification purposes. Right hand column 3620 displays which project the page is linked to, and each line corresponds to a different external page. External page 3600 also includes “Add External Page” button 3630, which creates a new backend entity and allows the operator to link external pages (via URL) to an active project.

FIG. 37 shows an illustrative operator interface of participants 3700. The “Participants” page displays all users that have been added to a project and the capacity in which they are participating (e.g. payer, payee, none).

FIG. 38 shows an illustrative operator interface of practices 3800. The “Practices” page displays a list of pre-determined best practices to ensure a successful project and reflects whether the practice has been approved by the project participants.

FIG. 39 shows an illustrative operator interface of project phases 3900. Skylight projects are broken into groups of tasks called “phases.” The “Project Phases” page displays the details of all phases for every active project.

FIG. 40 shows an illustrative operator interface of projects 4000. The “Projects” page is a set of features used by the operator to create new projects and link the external pages that power the web application. The primary section of the projects page displays a list of all active projects. Selecting a project name from the list redirects the operator to the project's backend interface. Projects 4000 also includes “Add Project” button 4010, which is a feature that redirects the operator to the project page where every field is blank and a new project entity can be created.

FIG. 41 shows an illustrative operator interface of reviews 4100. The “Reviews” page displays the details of every instance where a contractor reviewed the progress of a phase for a particular project.

FIG. 42 shows an illustrative operator interface of tags 4200. The “Tags” page displays all of the tags used to categorize files into folders that have been uploaded to the web application.

FIG. 43 shows an illustrative operator interface of tasks 4300. A Skylight project phase is broken up into “tasks.” The “Tasks” page displays a list of every task that has been added to a project phase on the web application.

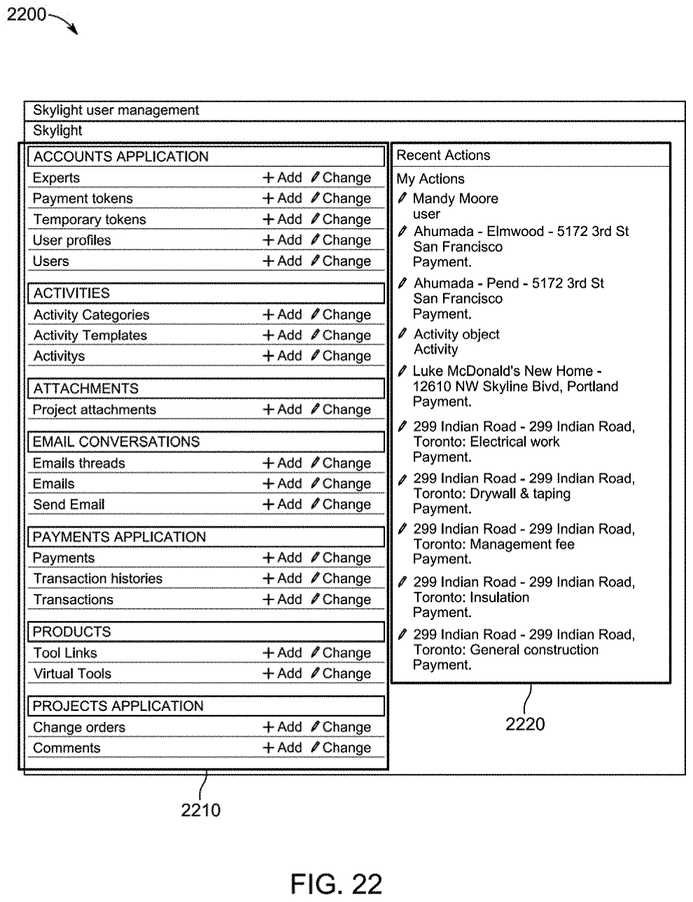

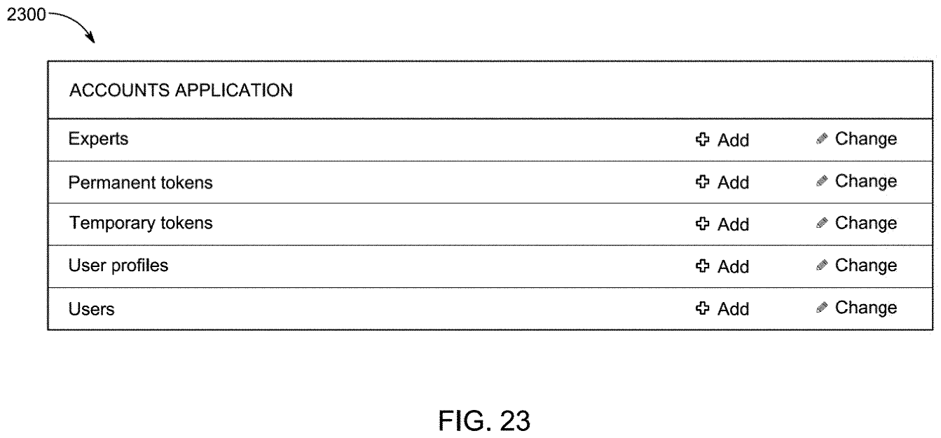

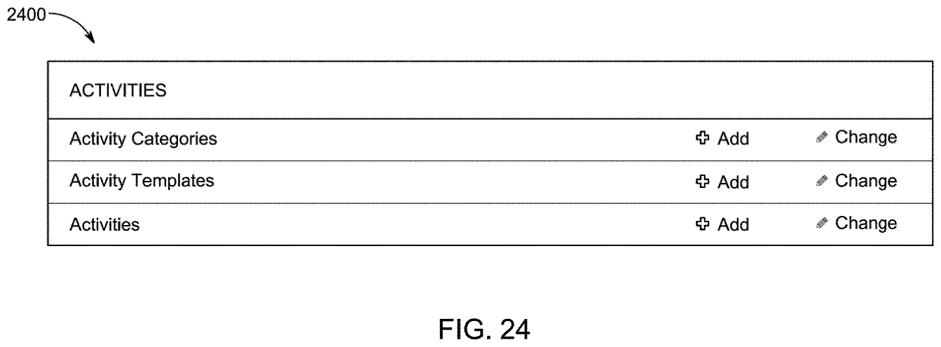

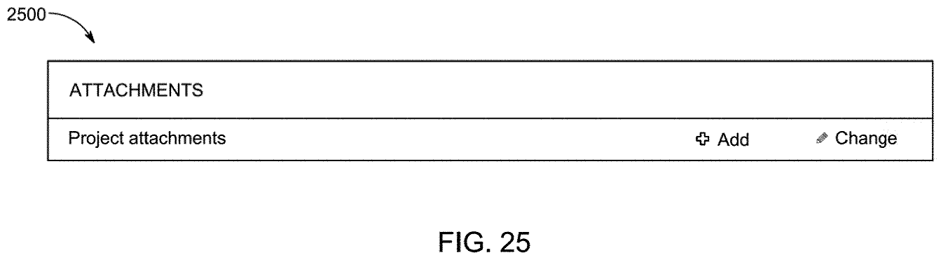

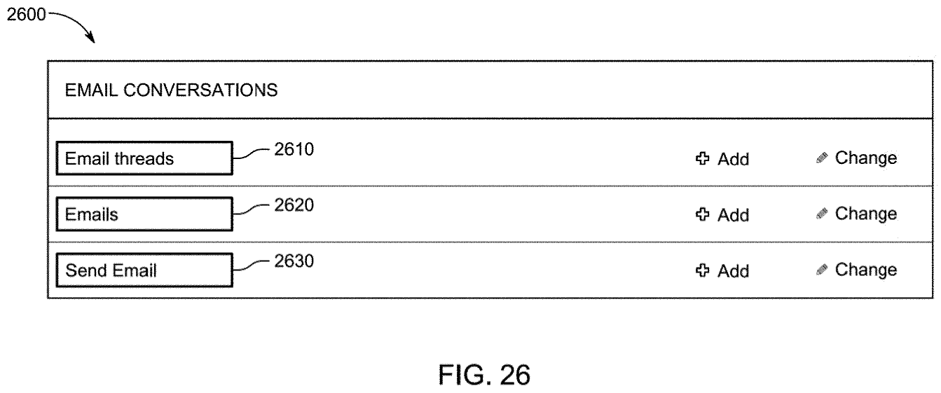

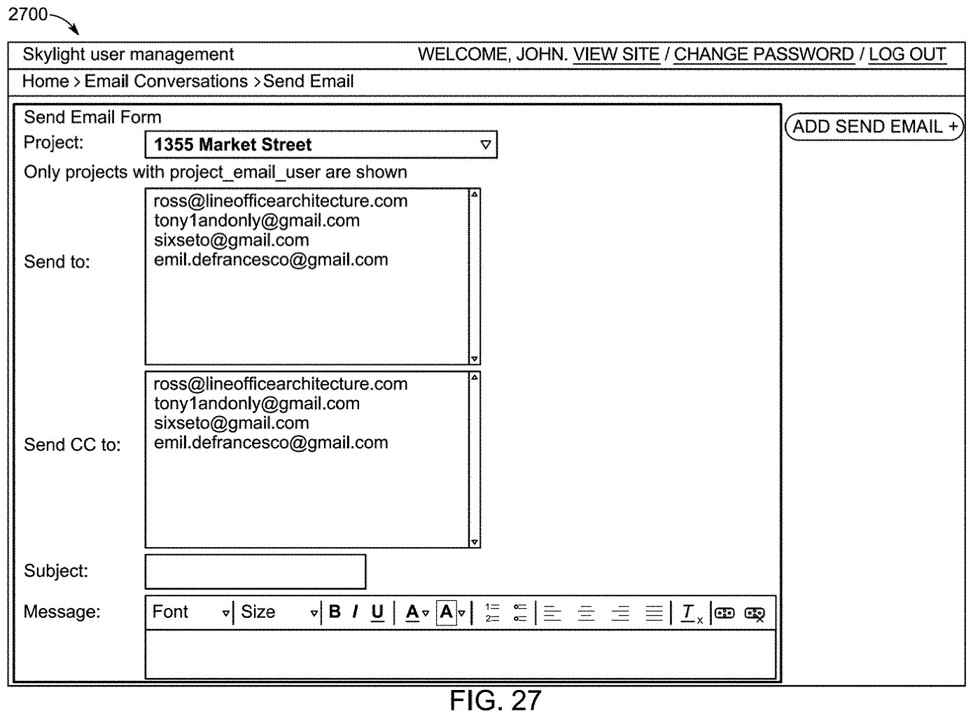

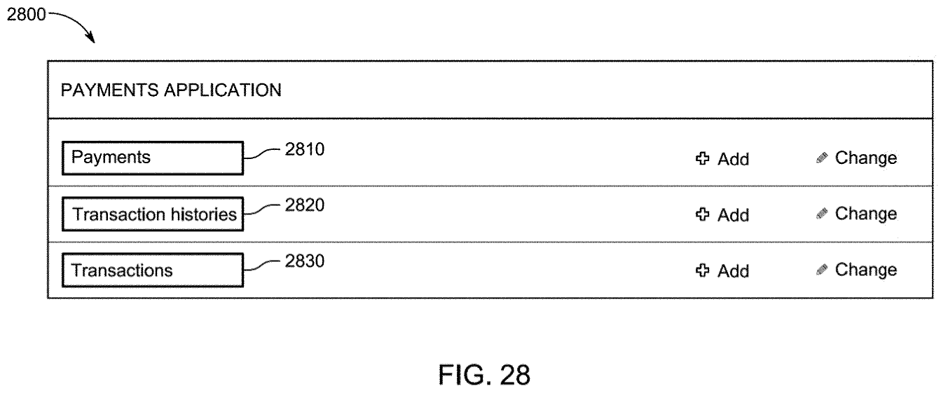

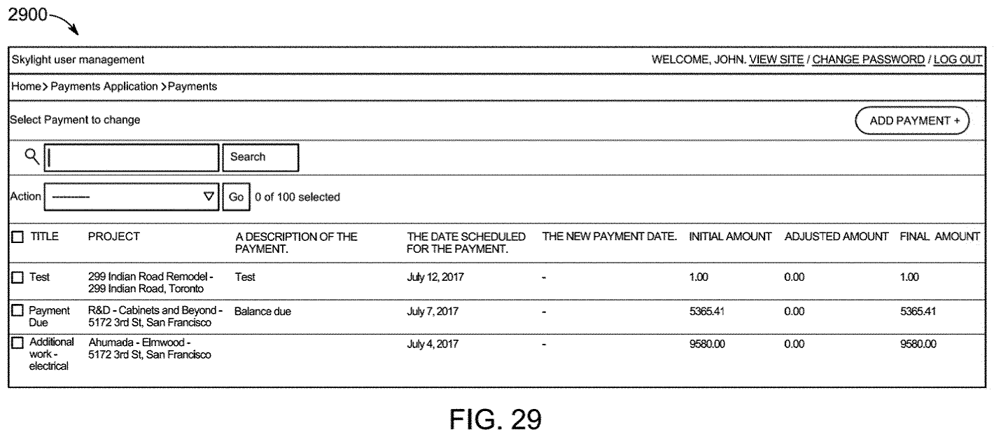

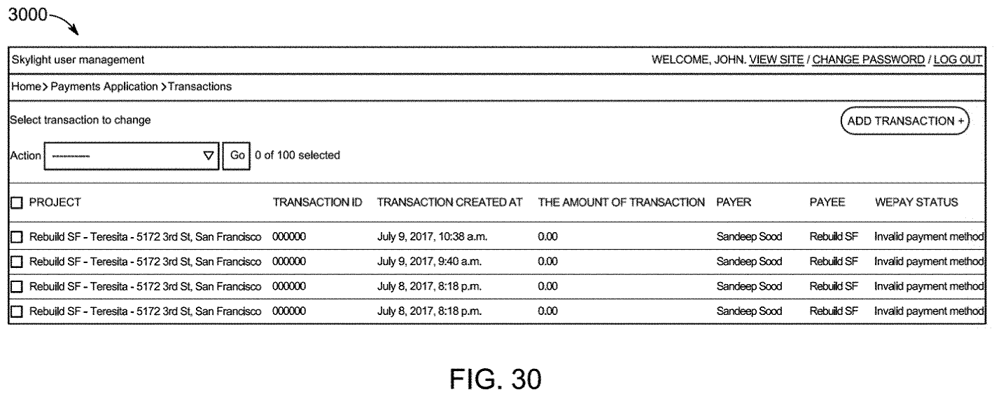

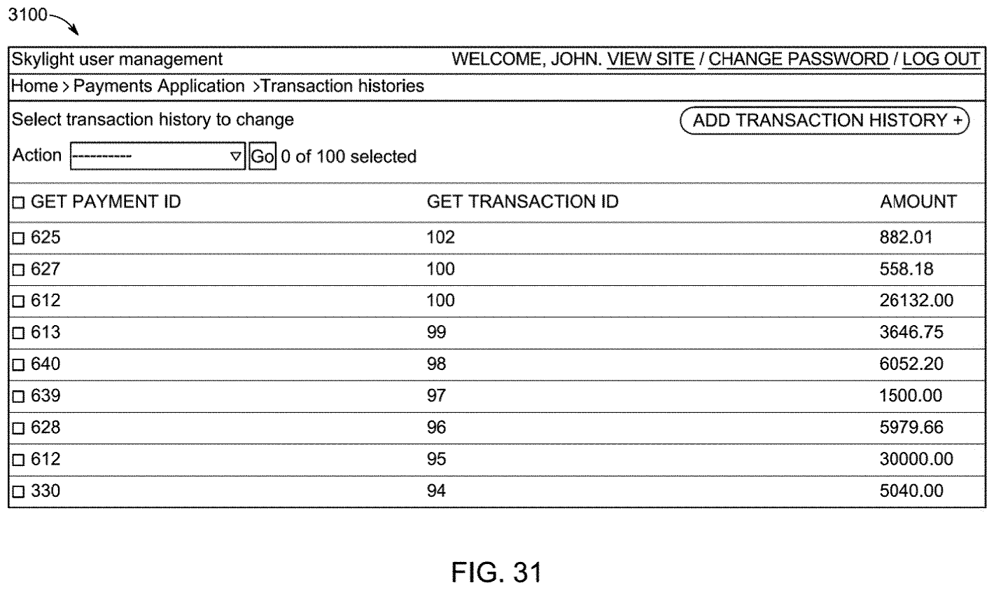

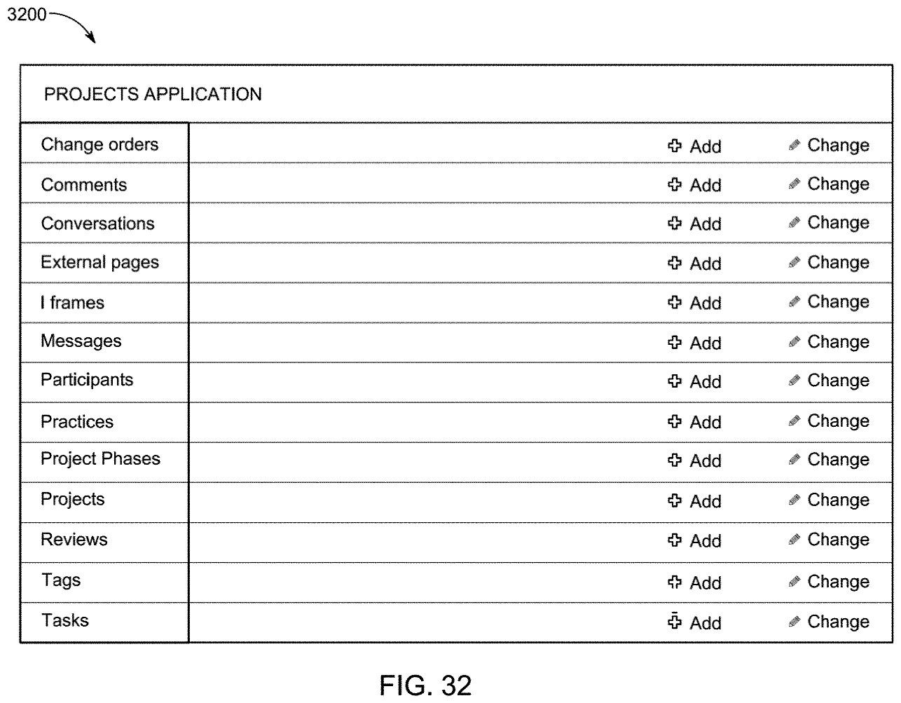

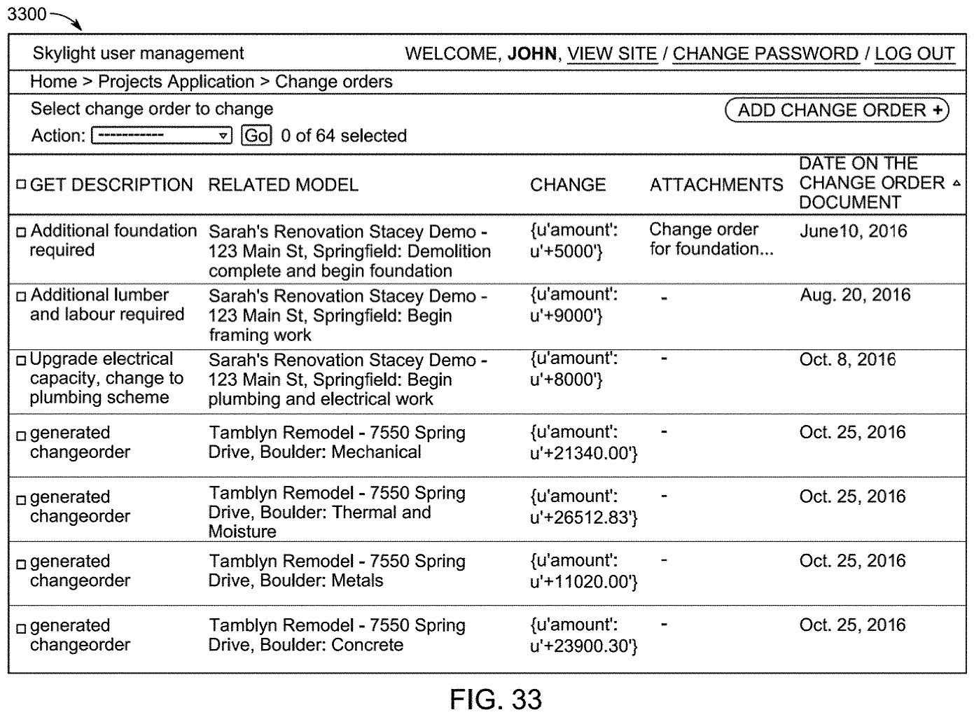

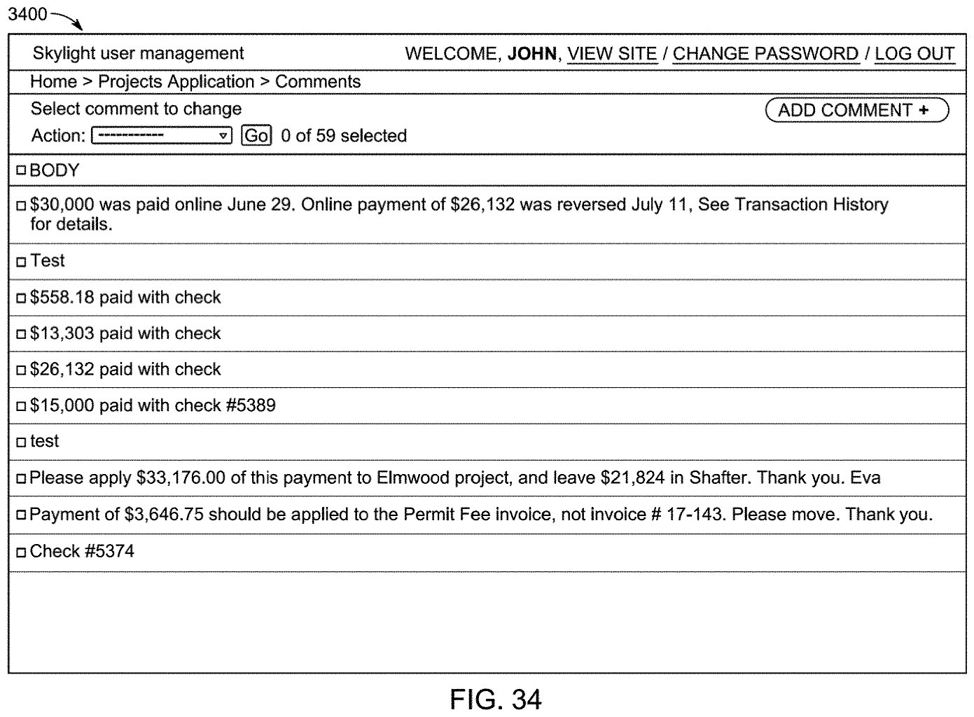

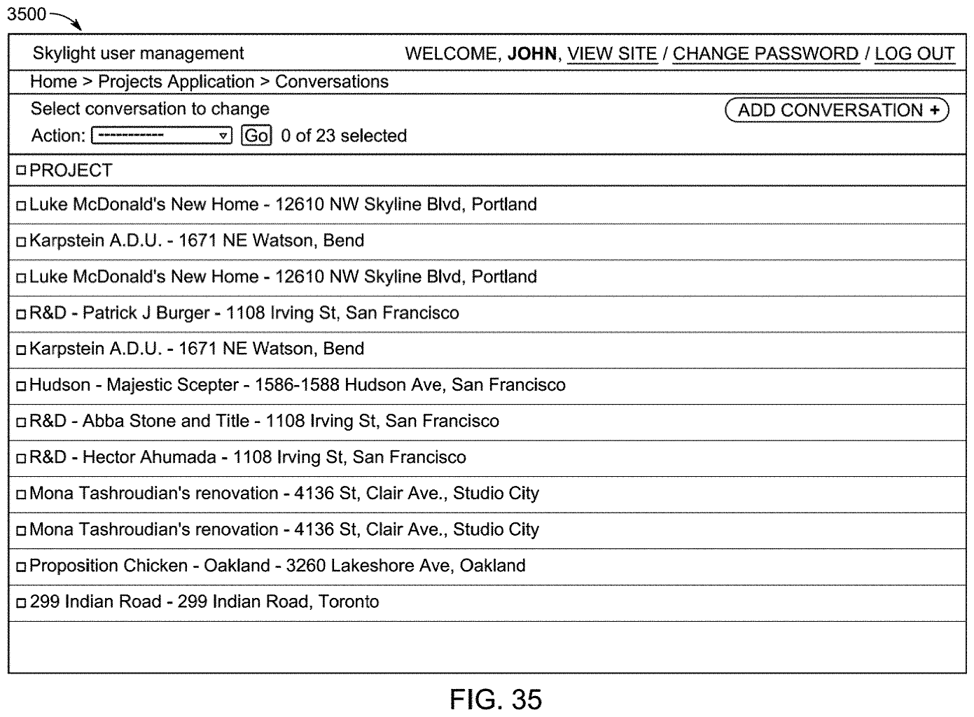

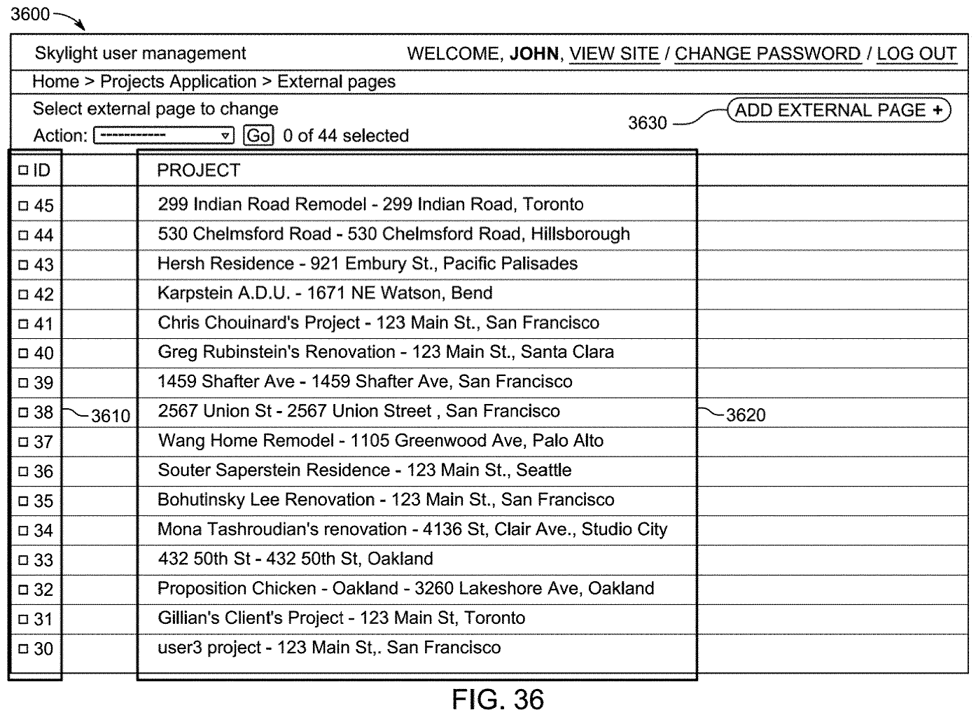

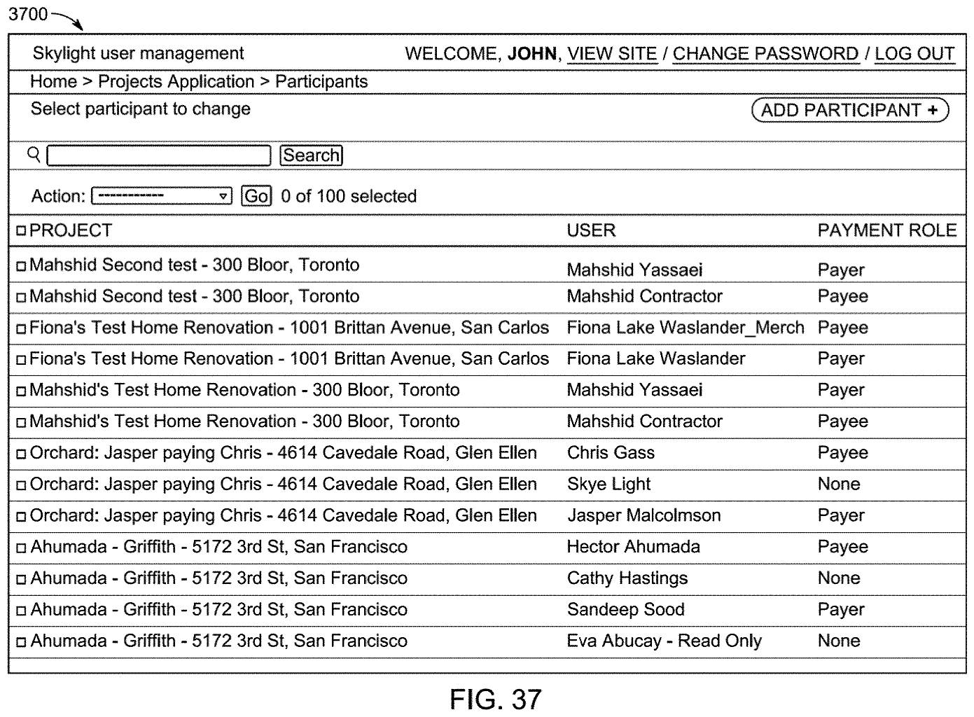

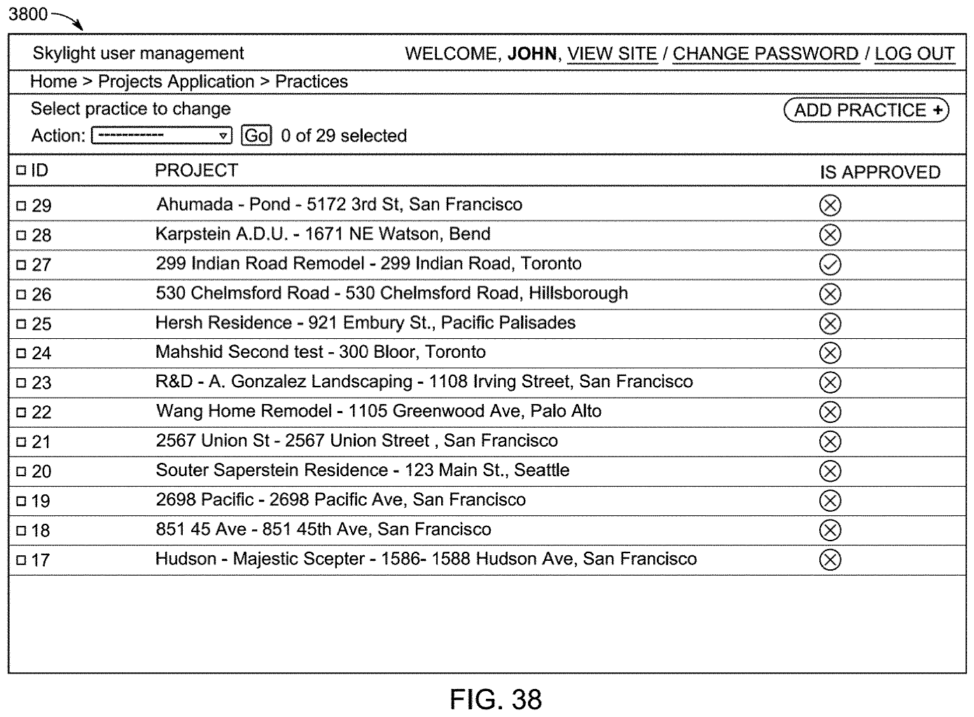

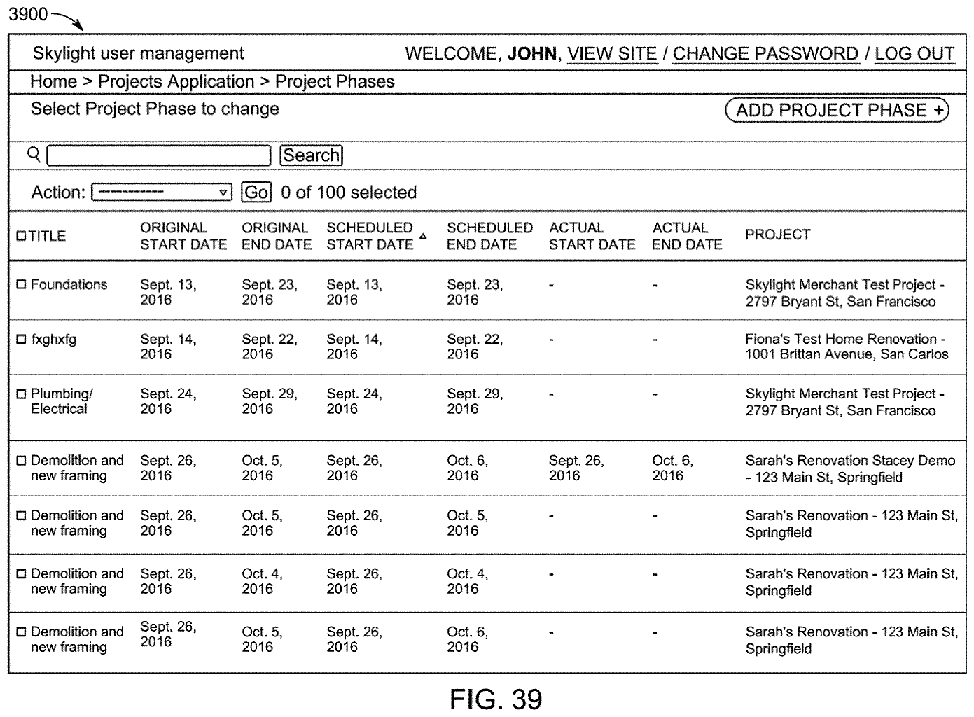

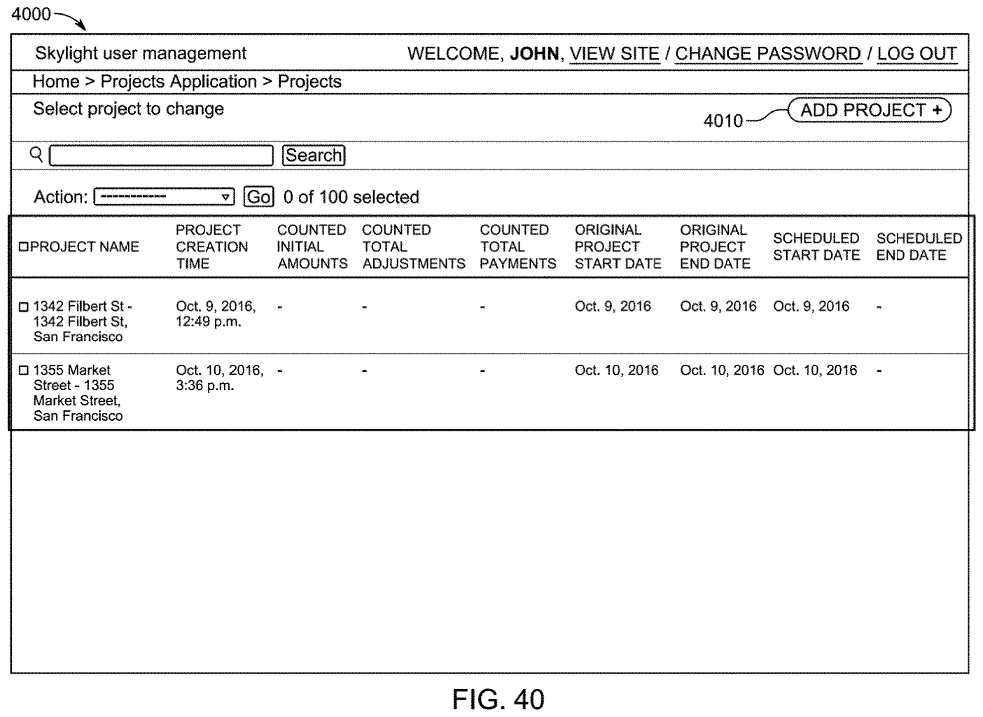

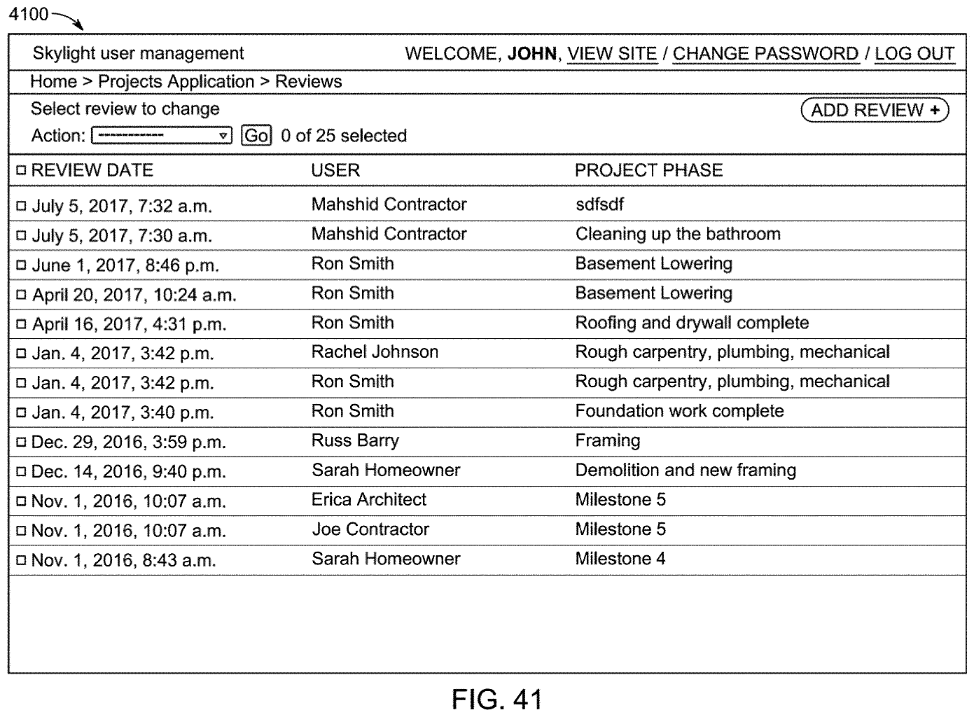

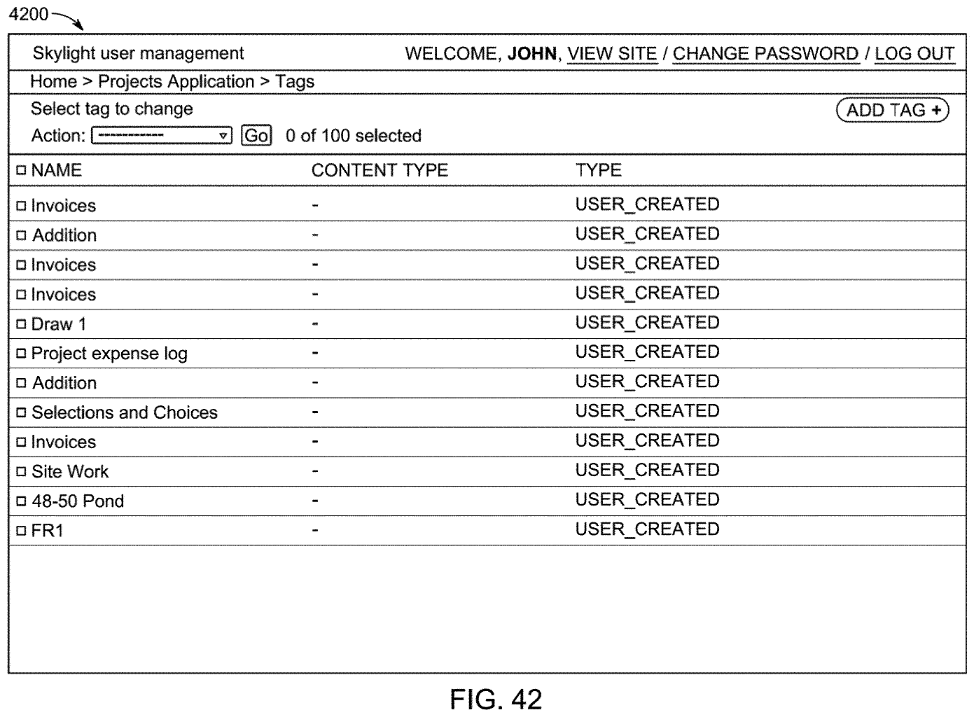

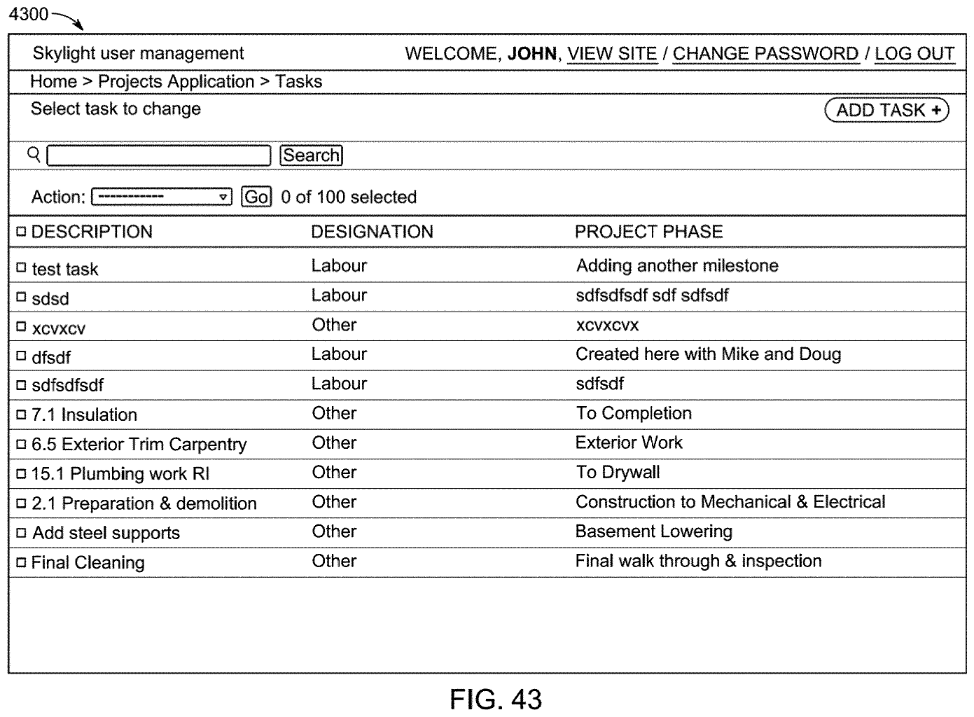

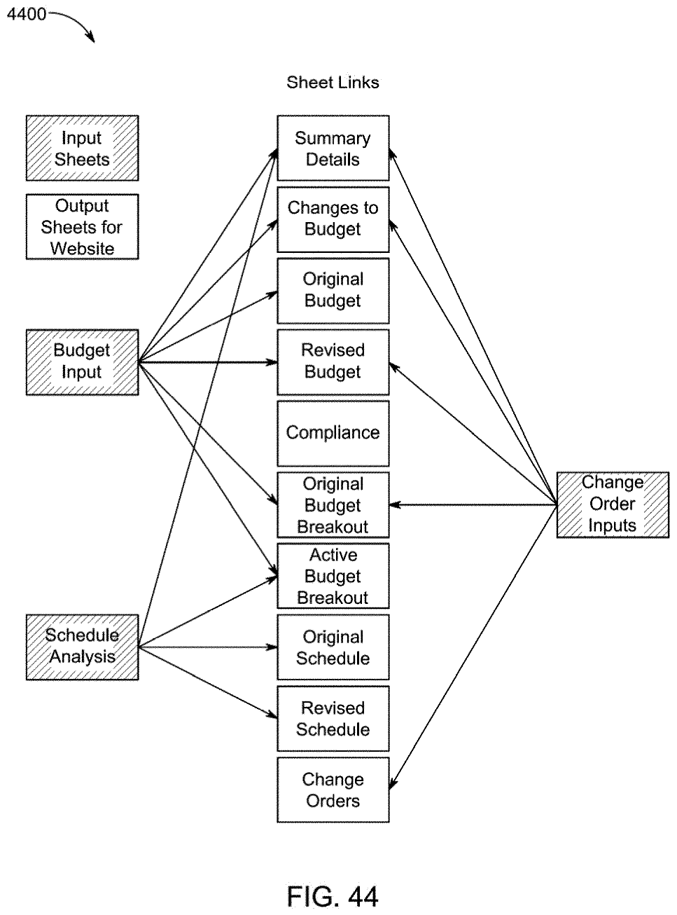

FIG. 44 shows an illustrative sheet links process 4400.

FIGS. 45a and 45b show an illustrative operator interface of change order inputs sheet 4500. The “Change Order Inputs” sheet is used by the operator to input the details of change orders that have been submitted to a project.

FIG. 46 shows an illustrative operator interface of budget input sheet 4600. The “Budget Input” sheet is used by the operator to define the categories and subcategories of a project, input budget estimates and actual dollars spent, record new scope items as change orders are submitted, and define the invoice periods for the project. The “Original Cost” column reflects budget estimates, and the invoice period columns reflect budget actuals.

FIGS. 47a through 47d show an illustrative operator interface of schedule analysis sheet 4700. The “Schedule Analysis” sheet is used by the operator to input the estimated percentage of total budget that will be spent per category over the course of the project, input the start date and approximate end date of the project, and update the actual percentage of the total budget that is spent per invoice period.

FIG. 48 shows an illustrative operator interface of original budget sheet 4800. The “Original Budget” sheet sums a list of project categories and their respective budget estimates.

FIG. 49 shows an illustrative operator interface of original budget breakout sheet 4900. The “Original Budget Breakout” sheet displays the estimated spending per category, per invoice period over the course of a project. This sheet is linked to the Original Budget web application page and is displayed to users.

FIG. 50 shows an illustrative operator interface of revised budget sheet 5000. The “Revised Budget” sheet displays the original budget plus cost increases due to change orders.

FIG. 51 shows an illustrative operator interface of active budget breakout sheet 5100. The “Active Budget Breakout” sheet breaks out actual dollars spent per category in each invoice period that has passed and forecasts for future invoice periods. As the project progresses, forecasts are updated to reflect actuals. This sheet is linked to the Revised Budget web application page and is displayed to users.

FIG. 52 shows an illustrative operator interface of original schedule sheet 5200. The “Original Schedule” sheet estimates which category of work will be completed during which invoice period(s). This sheet is linked to the “Original Schedule” page on the web application and is displayed to users.

FIG. 53 shows an illustrative operator interface of revised schedule sheet 5300. The “Revised Schedule” sheet actively displays when work is completed on the project and a forward looking schedule for work that is remaining. This sheet is linked to the “Revised Schedule” page on the web application and is displayed to users.

FIG. 54 shows an illustrative operator interface of changes to budget sheet 5400. The “Changes to Budget” sheet compares the original budget to the revised budget and actively calculates increases per project category. Gradient conditional formatting is used to indicate the severity of the budget increase.

FIG. 55 shows an illustrative operator interface of change orders sheet 5500. The “Change Orders” sheet displays a summary of all change order details. This sheet is linked to the “Change Orders” page on the web application and is displayed to users.

FIG. 56 shows an illustrative operator interface of compliance sheet 5600. The “Compliance” sheet displays a summary of all project practices and whether they are being followed by project participants. This sheet is linked to the “Compliance” page on the web application and is displayed to users.

FIG. 57 shows an illustrative operator interface of summary details sheet 5700. The “Django output” sheet displays a summary of the project's original and revised budget, the project's original and revised schedule, and the project's expected and actual compliance. This sheet connects to the “Dashboard” page on the web application to display the project status to users.

PESP system 1 can guarantee to a homeowner that their project will stay within the original budget, or PESP system 1 will cover the overage (exception: homeowner design decisions). PESP system 1 can charge the homeowner a fee to offer this protection. Typically, there are three causes for a project to go over budget. These can include:
1. Contractor rule violations and default;
2. Unforeseen site conditions; and
3. Homeowner design decisions.

PESP system 1 can manage each of these causes. The Contractor rule violations and default is now discussed. PESP system 1 can effectively a rule detection engine for a home renovation project. At the start of the project, PESP system 1 can work with the homeowner and contractor to establish the scope and the rules of engagement for the project. All of the features that may exist in a current live product may help to ensure that the industry standard rules are followed for the project. For example, if the contractor mis-estimated a sub-contractor cost and the sub-contractor ends up charging more than is budgeted, PESP system 1 can detect that cost increase and ensure that the contractor takes responsibility for that cost, and does not try to pass it on to the homeowner. Another example is that PESP system 1 ensures that the work has been completed prior to any invoice being paid. PESP system 1 can do this by tracking the completion of project tasks and phases and examining photo evidence of work complete. PESP system 1 may be able to eliminate cost overruns due to rule violations.

The occurrence of default from a contractor is very rare, but can occur. PESP system 1 can reduce the frequency of contractor default occurring by detailed screening of the contractors. This can be done by only accepting contractors with a proven record of good business flow. Because PESP system 1 can facilitate electronic payments between homeowner and contractor, the contractor should get paid faster than the traditional exchange of paper checks. With the collection of more funds faster, the contractors are less likely to go into default. In the case that the contractor does default, then PESP system 1 can cover the cost of replacement.

Unforeseen site conditions are now discussed. Unforeseen site conditions (USC) are previously unknown physical conditions that differ materially from those ordinarily encountered and not reasonably contemplated by the parties as being within the scope of the contract. An example of an unforeseen site condition may be the discovery of mold in a wall when the wall was being opened up for another issue.

PESP system 1 can use an unforeseen site conditions risk prediction model. The model can incorporate historical data from renovation projects to analyze the frequency and the magnitude of unforeseen site conditions based on a variety of factors. Data can be collected from all projects on PESP system 1 and used as inputs into this model. Machine learning can be leveraged to develop a predictive algorithm for the likelihood of a USC on a particular project. This may enable management of the risk of offering a guarantee to homeowners for cost overages due to unforeseen site conditions. Pricing can be refined and risk associations for each project can be determined for each project based on this forecast.

Homeowner decisions are now discussed. PESP system 1 can identify cost increases that are the result of homeowner design decisions during the course of the project. For example, a homeowner may decide that they want different flooring than planned which causes additional cost. PESP system 1 can record and track cost increases due to design decisions, but may not cover design decisions as part of the budget guarantee.

Several operational processes can support the product experience for homeowners. The operational processes can include before project, during project, after project, and outside of project processes. The before project process operations can include, but are not limited to, one, some, or each of the following:
1. an explanation of the process and defining expectations of the project
   a. customer support may perform this role
2. project risk assessment
   a. define details of the project and provide inputs to the risk assessment model to determine likelihood of a USC
      i. customer support may perform this role
3. setup the project and plan by defining budget, schedule, scope
   a. map out the full project by cost category
4. secure homeowner agreement to the terms
5. ensure completeness of scope and review contract
   a. an operator and/or expert may perform this role
6. establish connection with a draftsperson
   a. a draftsman may be involved in this operation
7. identify general contractors that can participate in project
   a. evaluate homeowner needs and match general contractors
   b. ask relevant contractors to bid
8. perform bidding process
9. review contract and scope, and lock in price.

The during project process operations can include, but are not limited to, one, some, or each of the following:
1. update project status, documents, and activities
   a. update budget and schedule in response to receipt of invoices and documents
2. invoice submission and review
3. review photos for completeness
4. change order submission and review
   a. evaluate each change order and determine appropriate cost increase and who is responsible for the cost
5. dispute resolution for change order or inappropriate invoice
6. payment experience an operation, including payout
   a. facilitate payments between homeowner and contractor
7. remove underperforming or non-performing contractors
8. perform site visit to review change order claim
9. manage design decision disputes
10. update general contractor ranking
   a. input data into the general contractor rating system that scores contractors based on performance and adherence to procedures.

The after project process operations can include, but are not limited to, one, some, or each of the following:
1. feed project data into learning model for project risk and contractor performance
2. obtain signatures from relevant parties to confirm project is complete.

The outside project process operations can include, but are not limited to, one, some, or each of the following:
1. acquire and screen general contractors
2. identify sources of risky projects
   a. risk may be city based
3. architect outreach.

The operations may be performed by different parties, including operators, experts, salesperson, managers, local runner, general contractors, homeowner, arbitrator, and/or the like.

The homeowner experience provided by PESP system 1 can include, but is not limited to, one, some, or each of the following:
1. Overarching experience
   a. General site static content
   b. Learning portal with tutorials
   c. Articles/SEO content
   d. Website look feel, and design
2. Project Onboarding
   a. User onboarding—automate, show workflow and operations
   b. Homeowner agreement to terms
   c. General contractor marketplace and matching
   d. General contractor bidding and selection
3. Project Set-up
   a. Project schedule, budget, payment schedule, progress phases via web and email
4. Project Execution
   a. Project status and activity view (dashboard)
   b. Notification system and status for changes/activity feed
   c. Change order submission, approval an update flow
   d. Payments, payment history, and fee history
   e. Insurance payout process
   f. SMS channels/email channels and conversation archive
   g. Document repository
5. Project Completion
   a. Project sign off process
   b. Final project report.

The contractor experience provided by PESP system 1 can include, but is not limited to, one, some, or each of the following:
1. General Contractor Onboarding
   a. GC agreement to terms
   b. GC automated boarding
2. Project Onboarding
   a. GC dashboard to view/access interested homeowners; tracking bidding by showing workflow and operations
   b. Bidding process
3. Project execution
   a. Same as Homeowner (as described above)
   b. Incentive system
   c. Online and email communications
4. Project completion
   a. Same as Homeowner (as described above)

The operator experience provided by PESP system 1 can include, but is not limited to, one, some, or each of the following:
1. Project Onboarding
   a. Candidate project risk review
   b. Project scope review
   c. GC marketplace matching
   d. GC bidding/selection
   e. Project confirmation and creation
2. Project Set-up
   a. Project budget lock-in, setup budget and schedule, progress phases, and payment schedule
3. Project Execution
   a. Receive documents, invoices, photos, and update project files
   b. Invoice review; progress review; and photo review
   c. Notification system for status changes; activity feed
   d. Automated email reports
   e. Change order review
   f. SMS channels/email channels and conversation archive
   g. Document repository
4. Project completion
   a. Project sign off process
   b. Project data compilation
   c. GC scoring

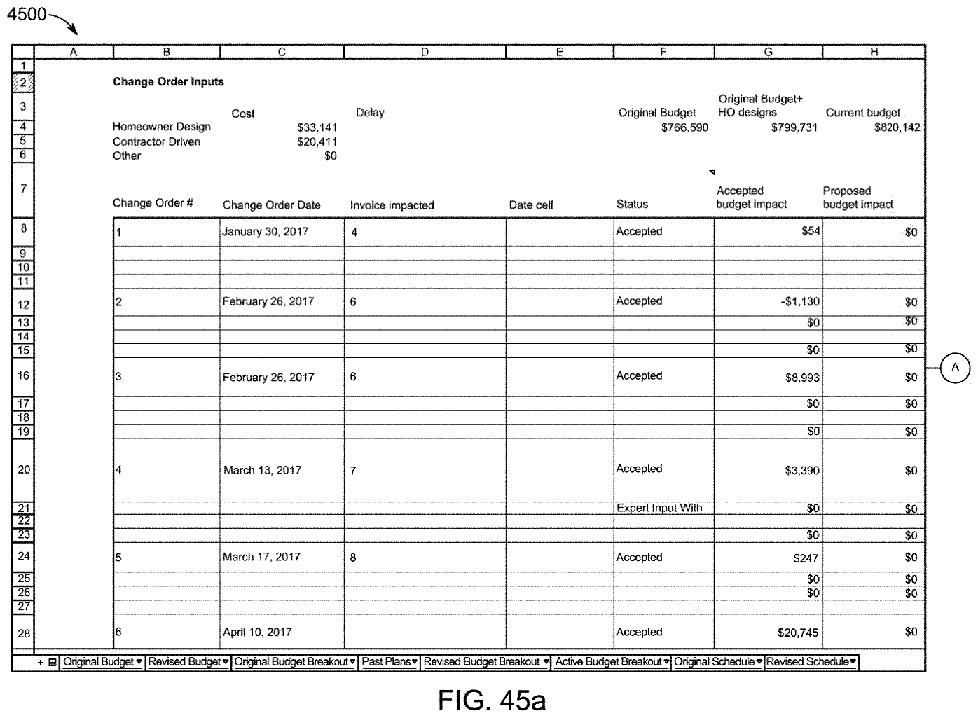

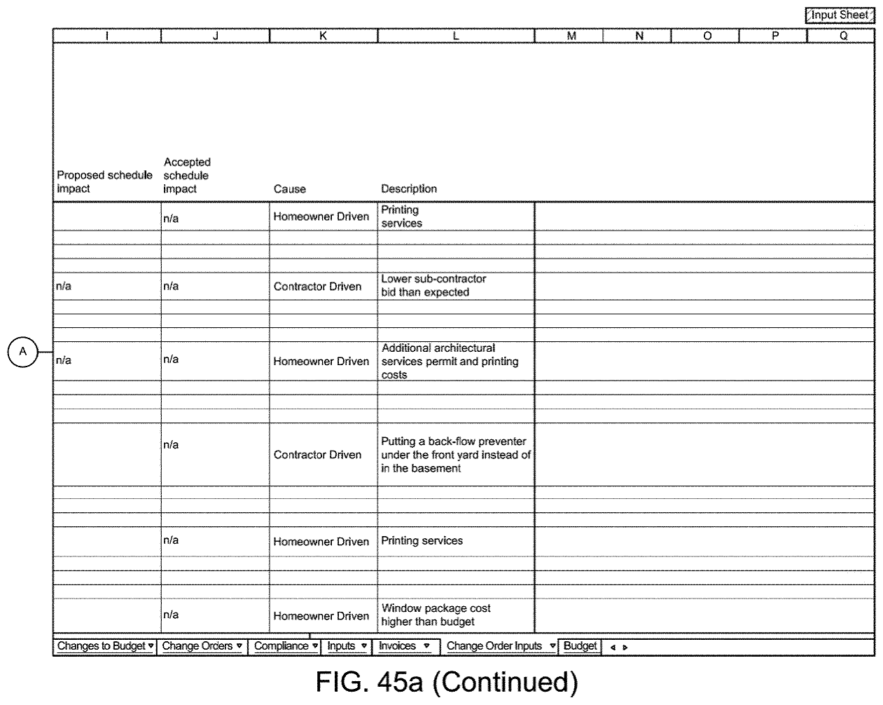

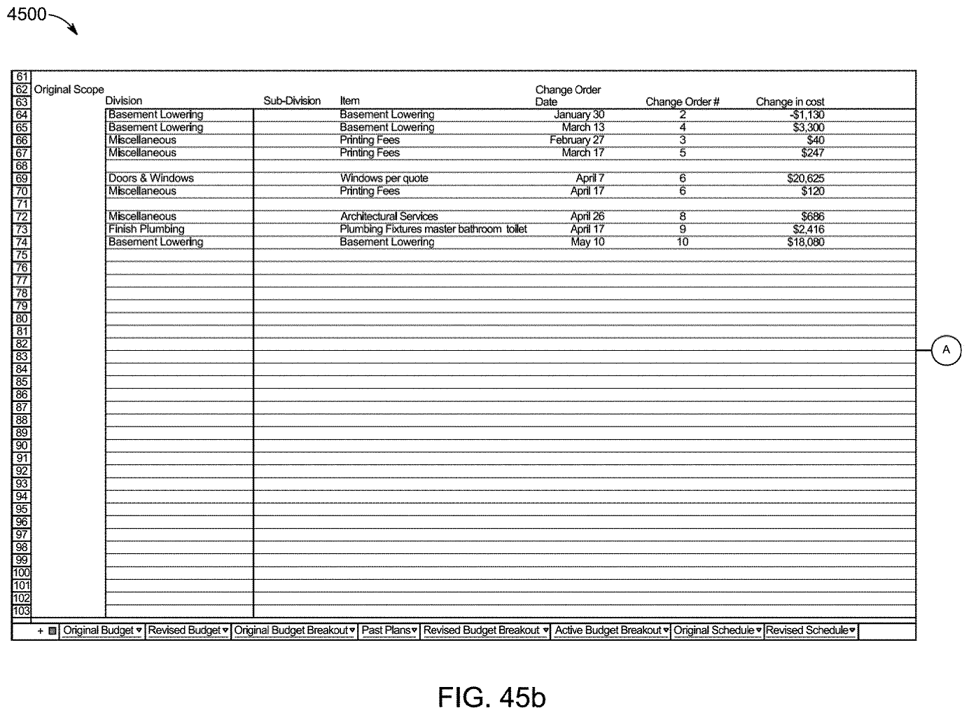

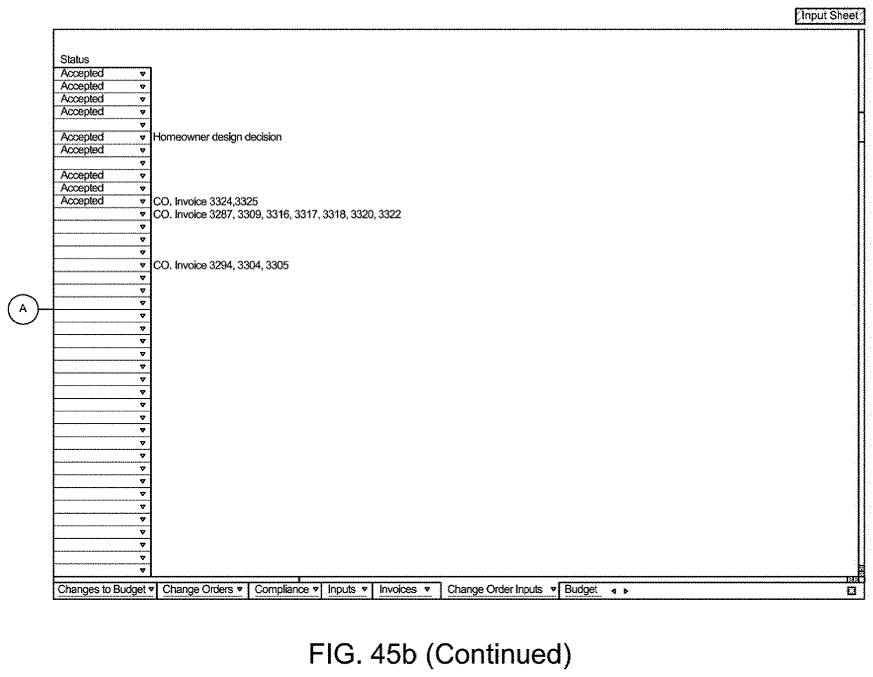

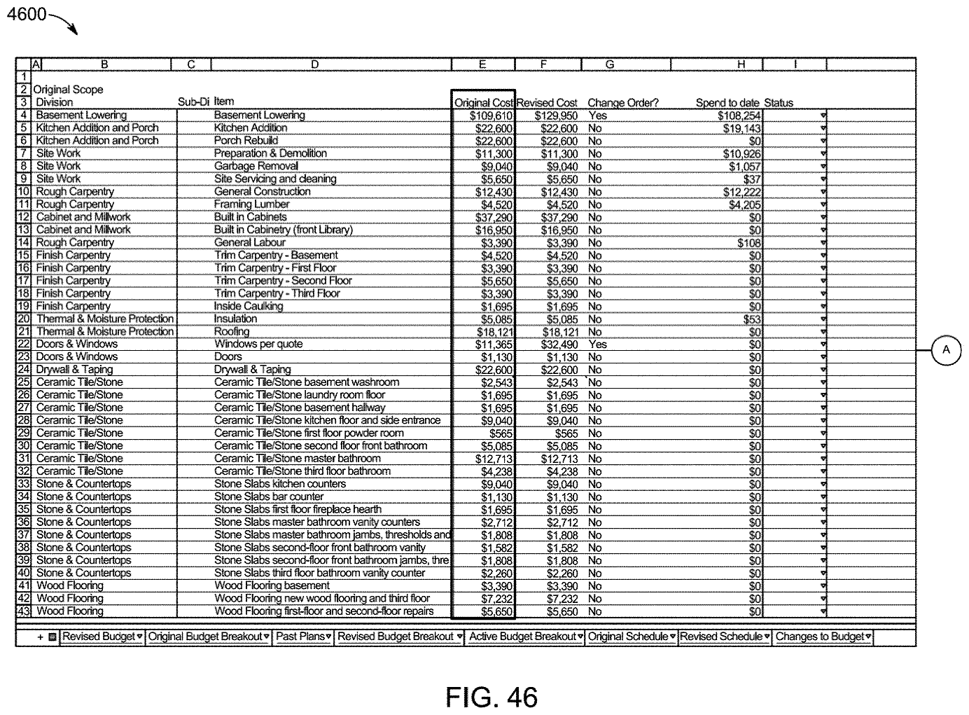

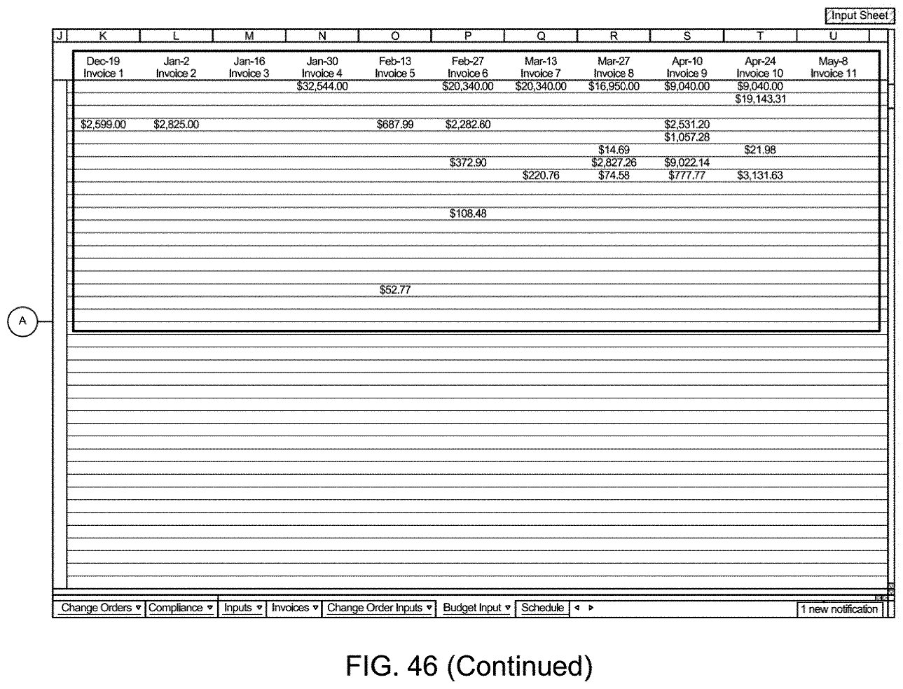

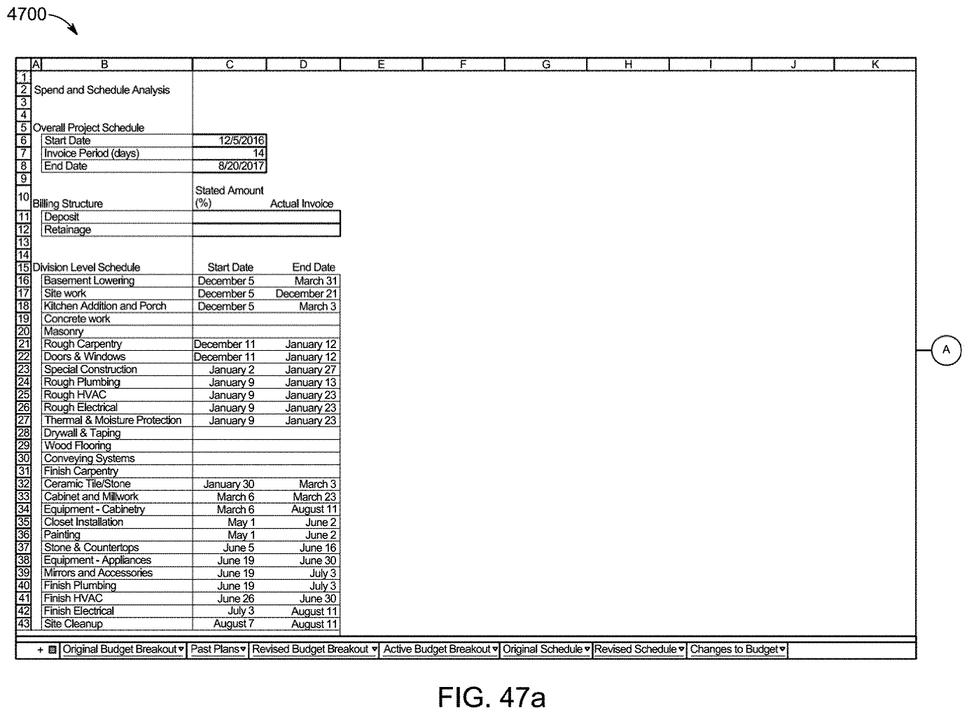

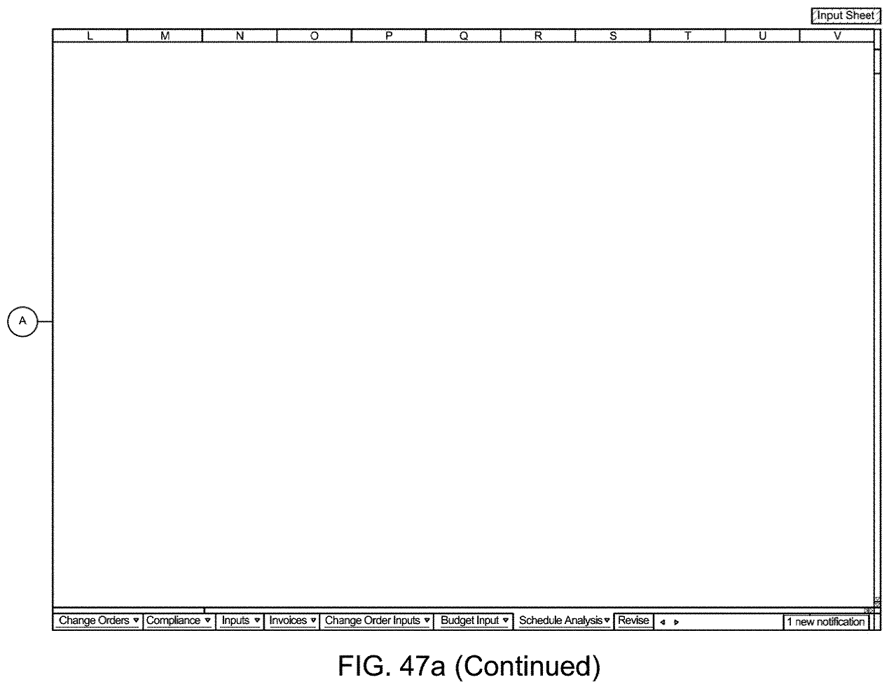

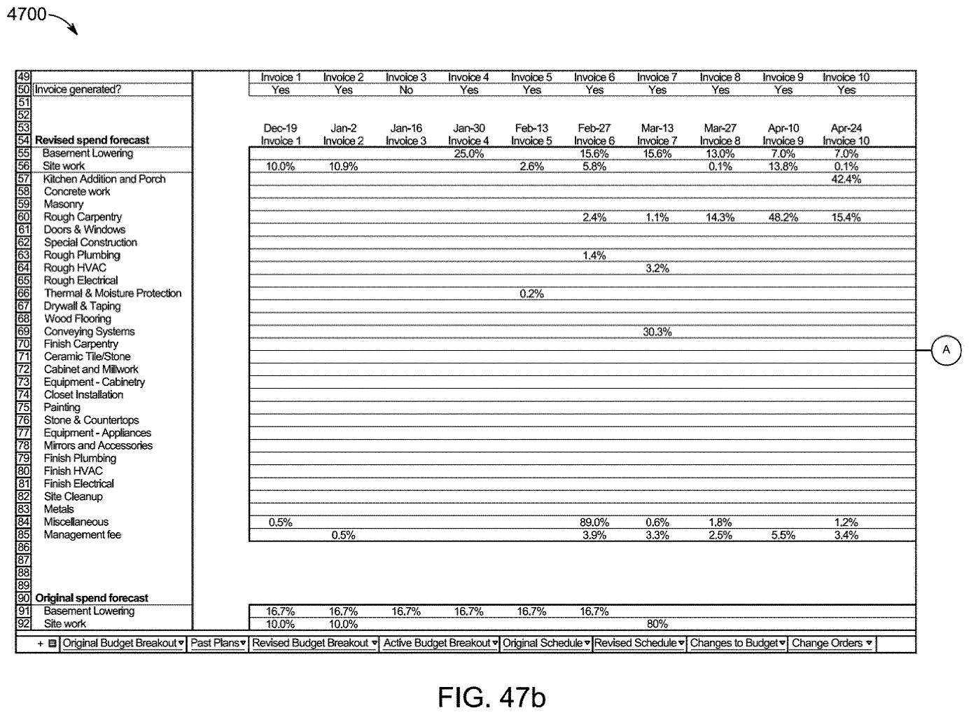

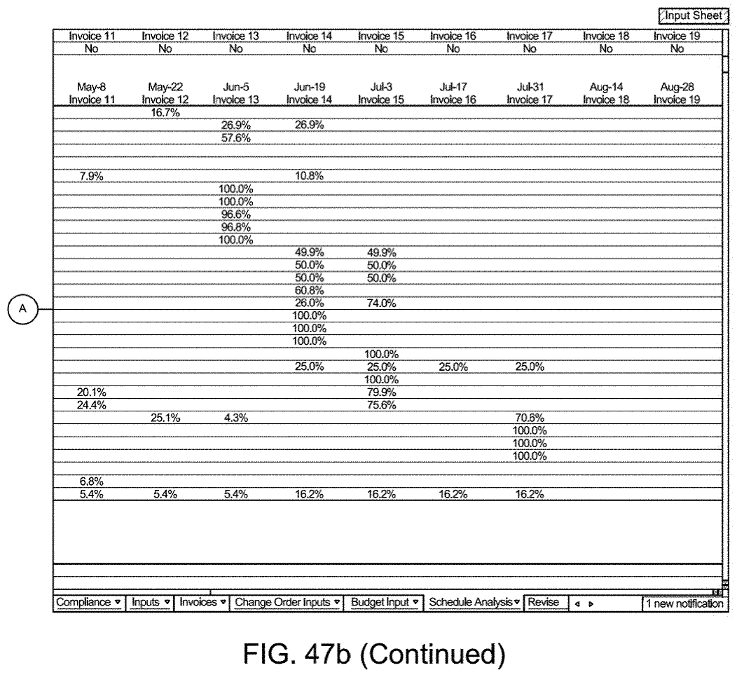

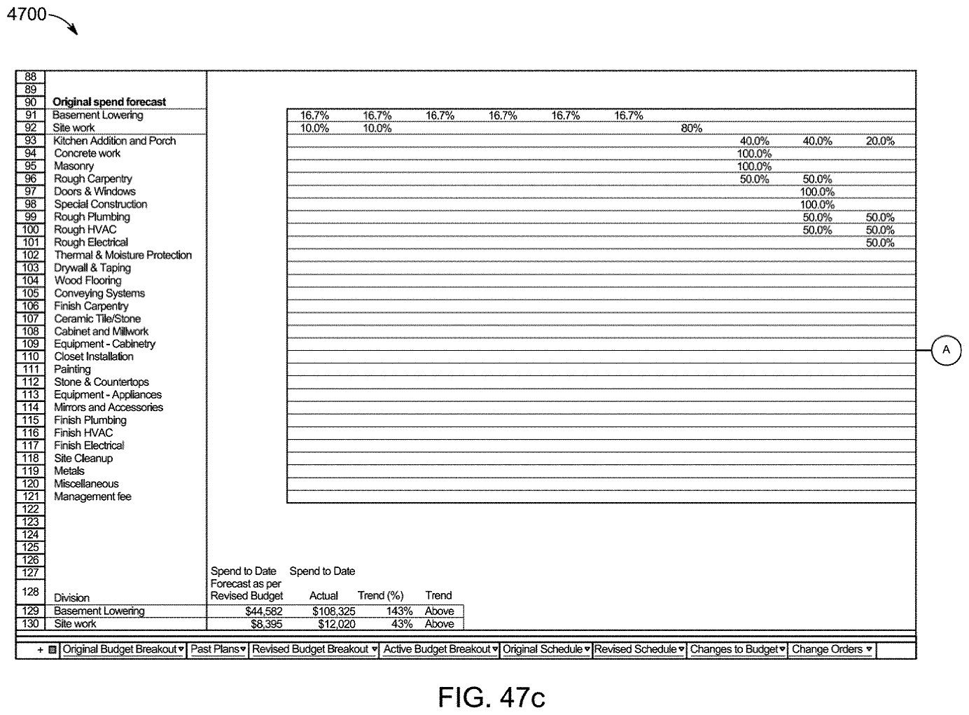

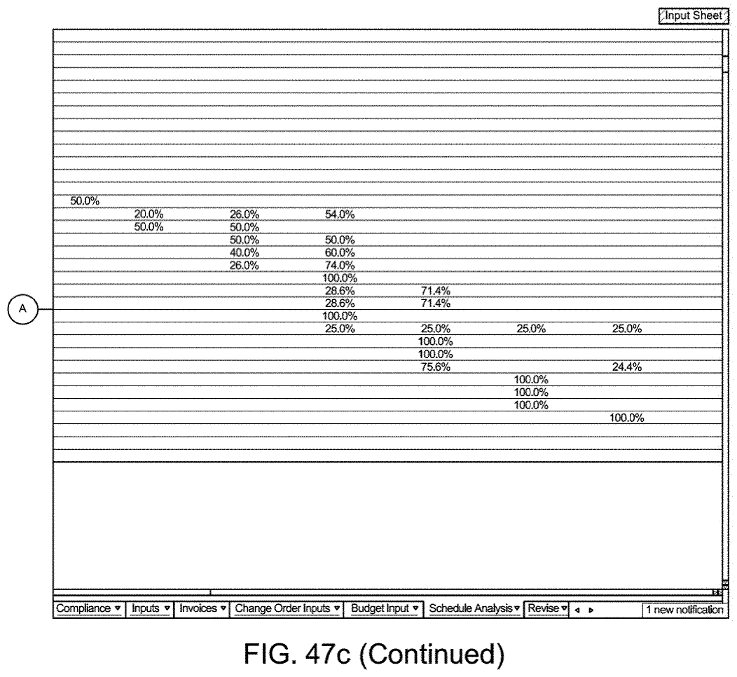

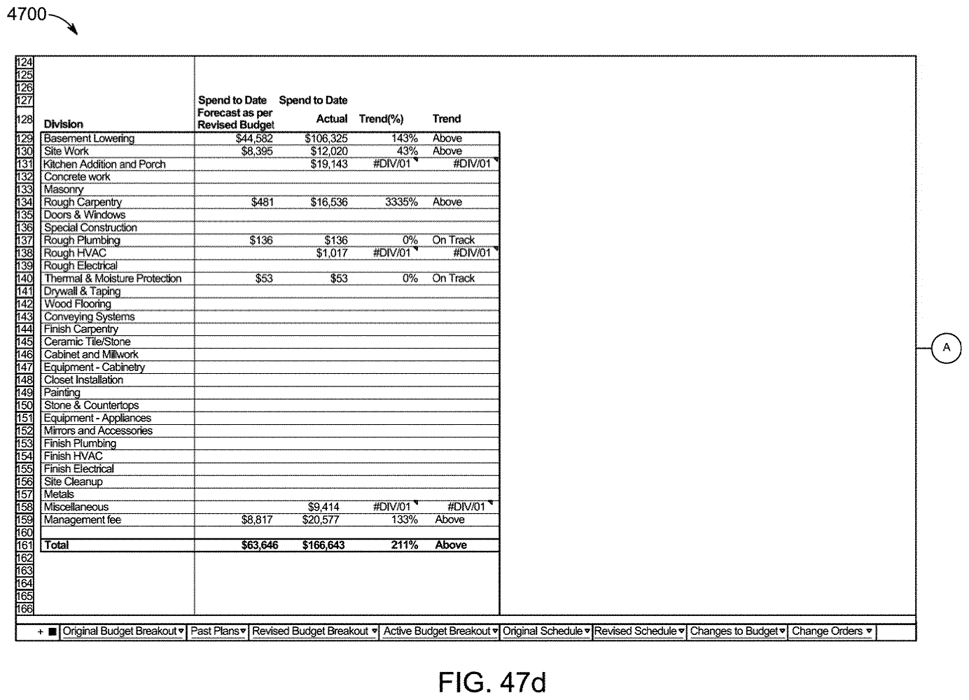

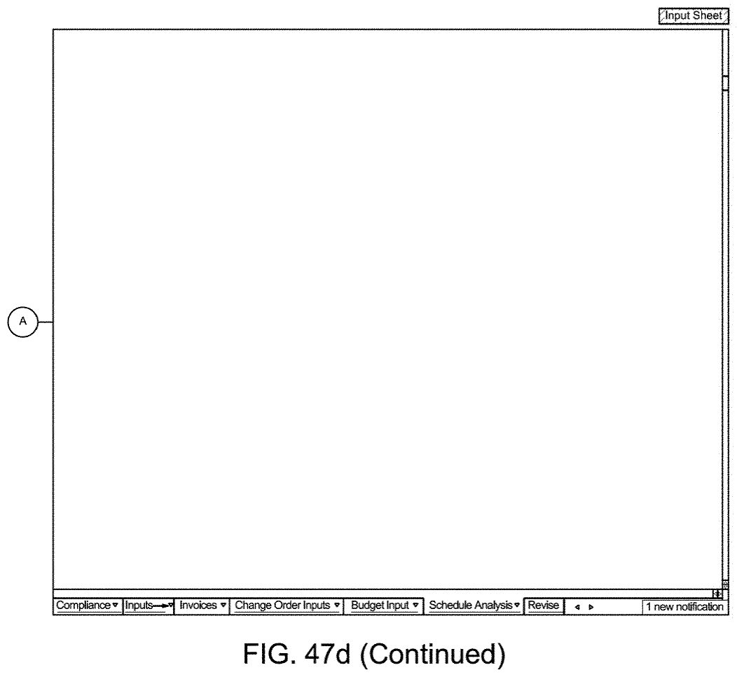

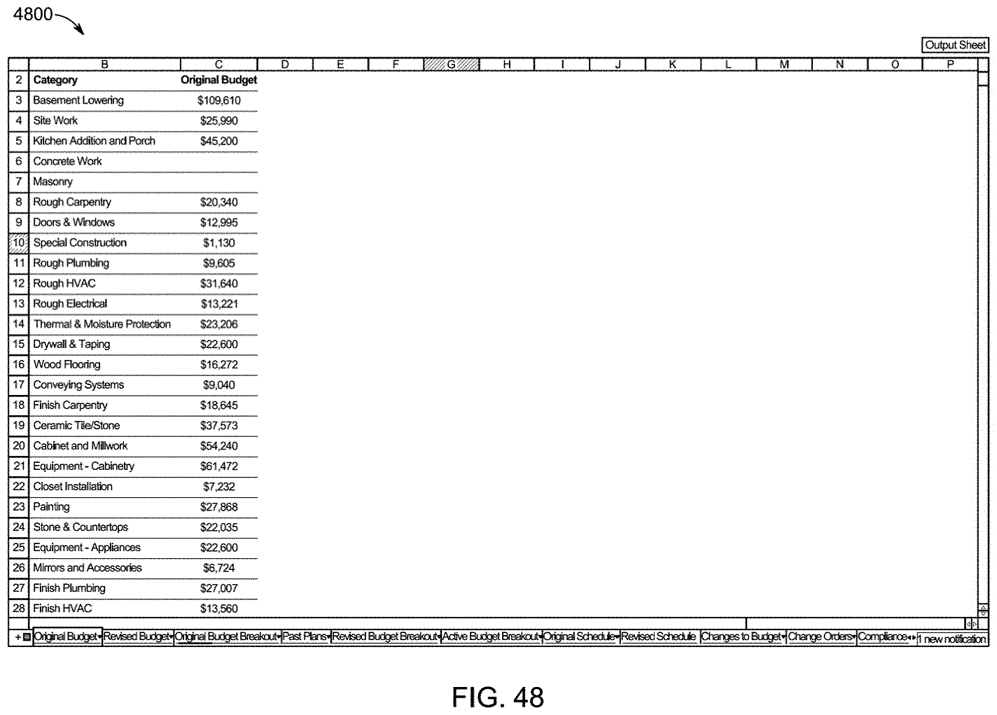

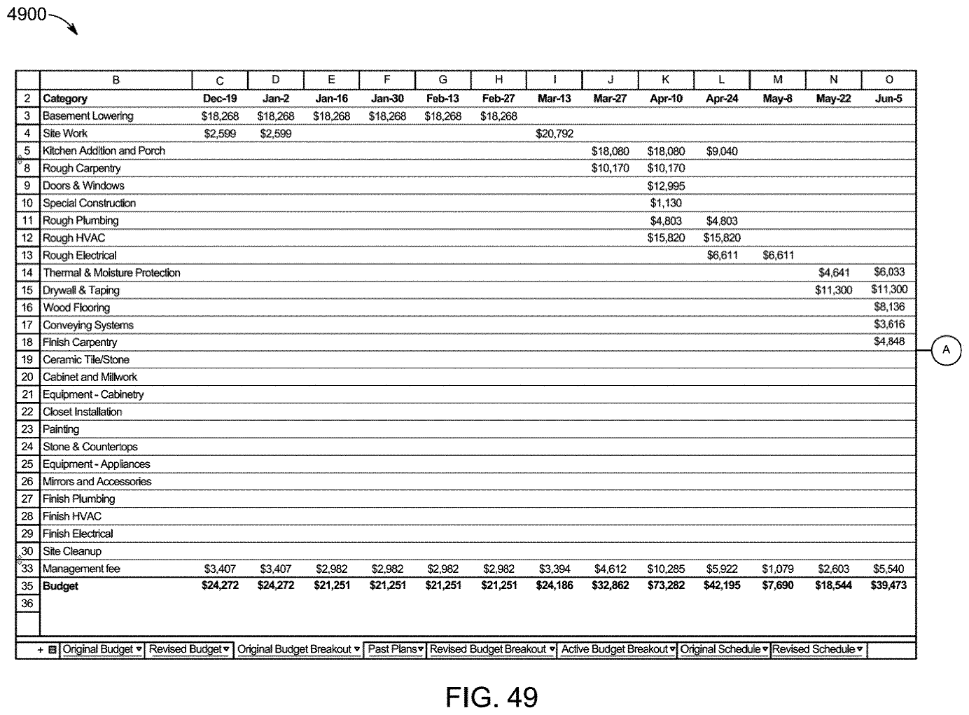

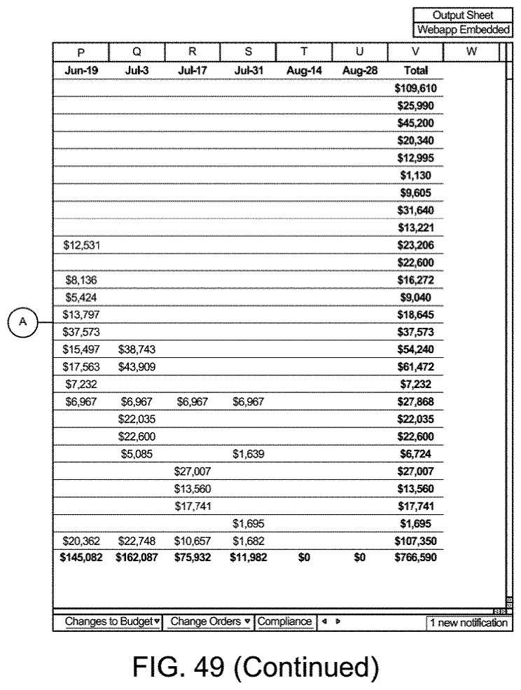

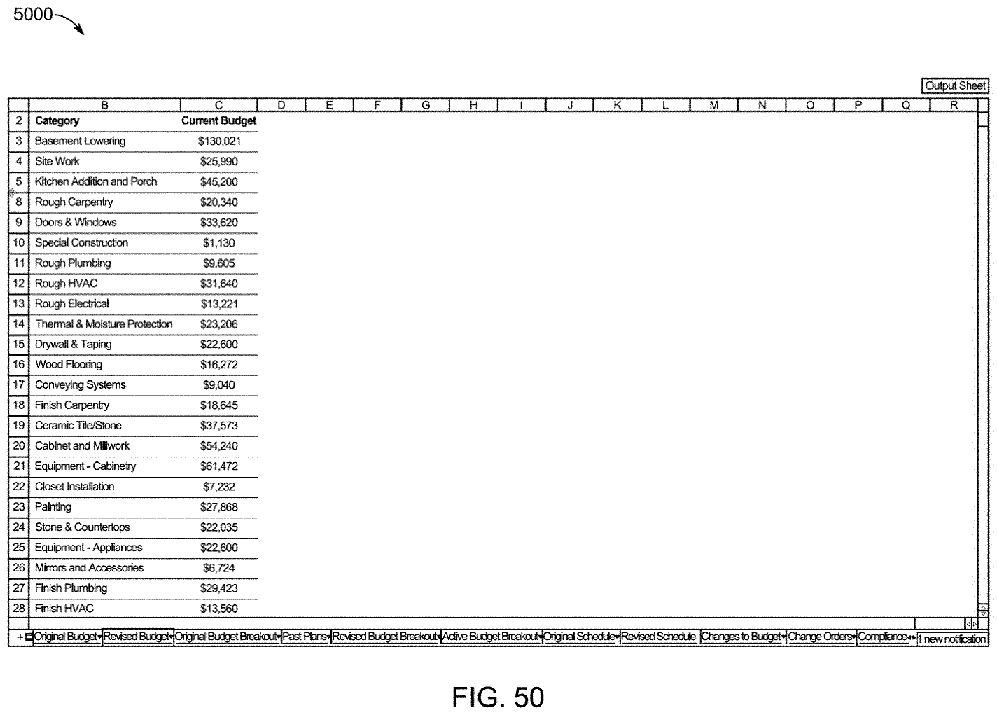

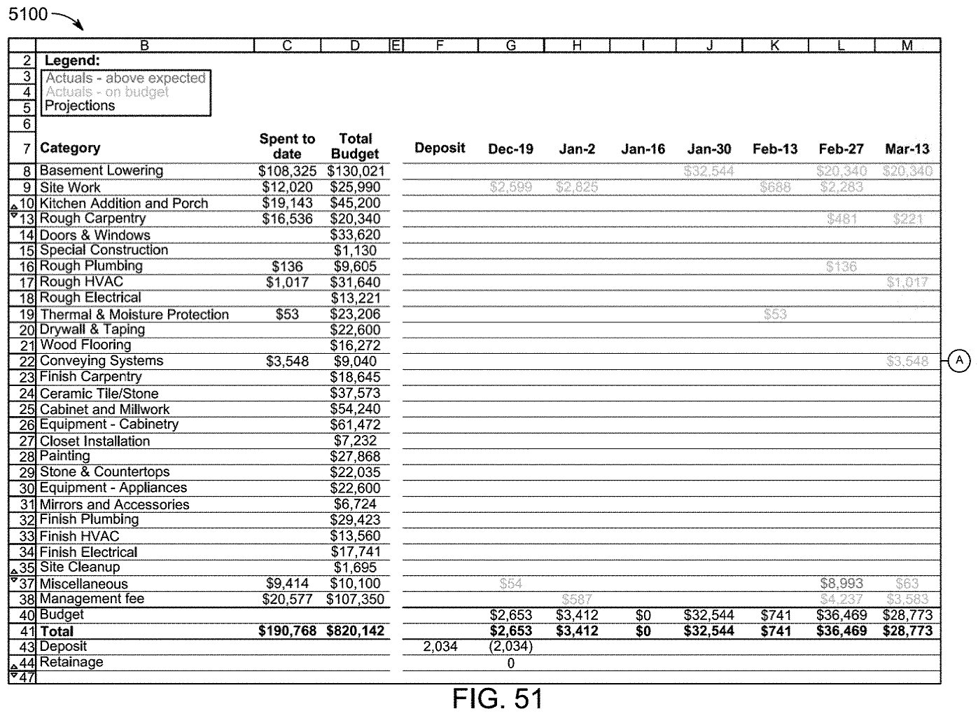

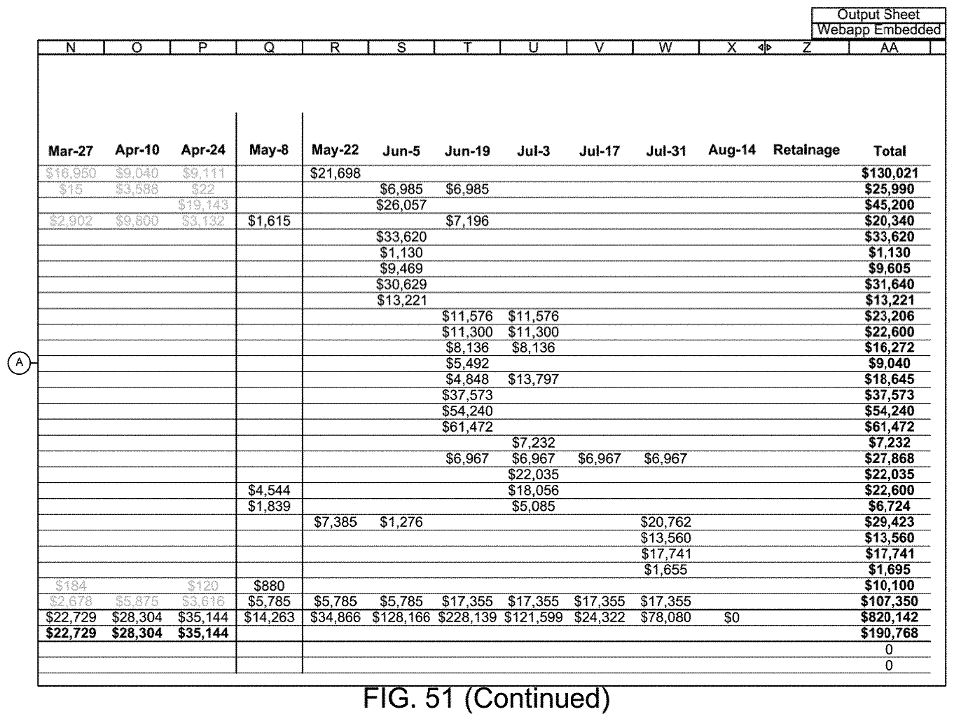

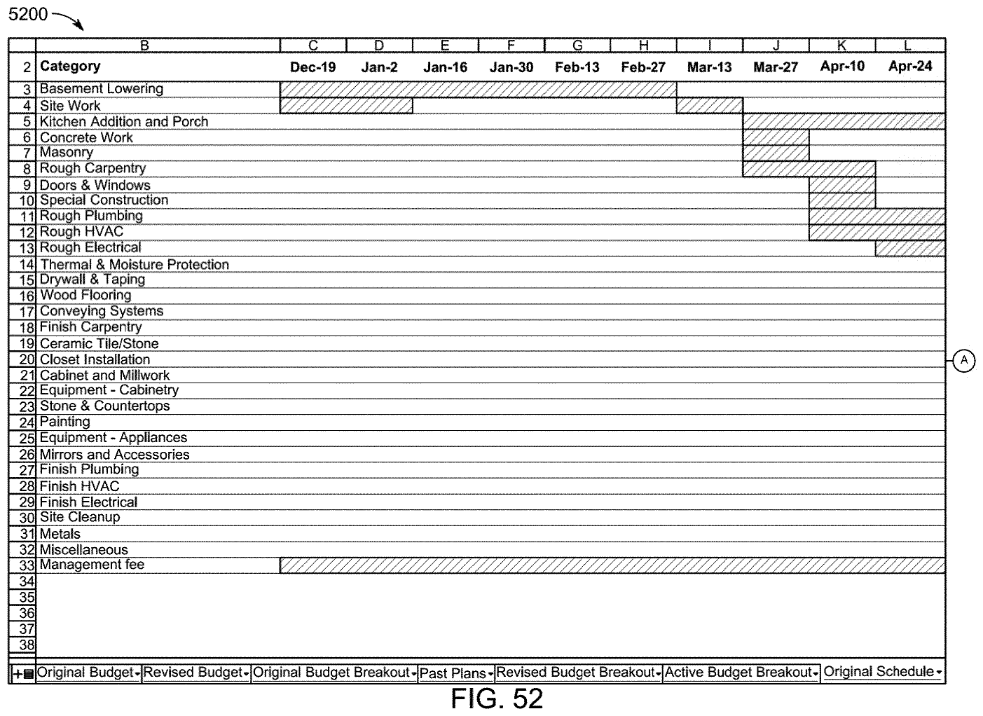

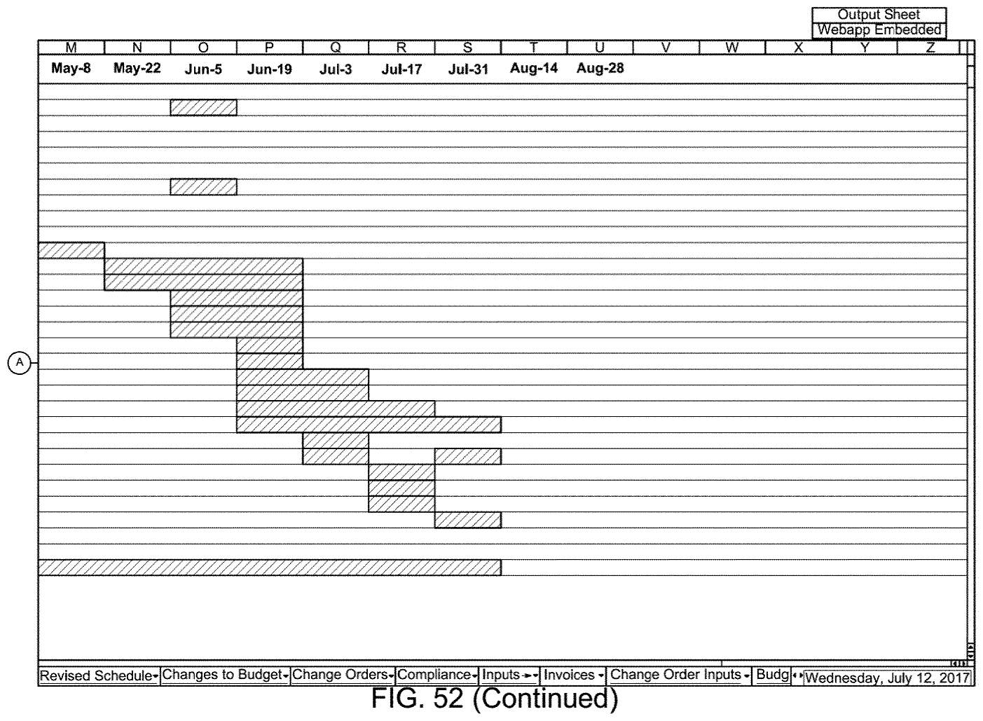

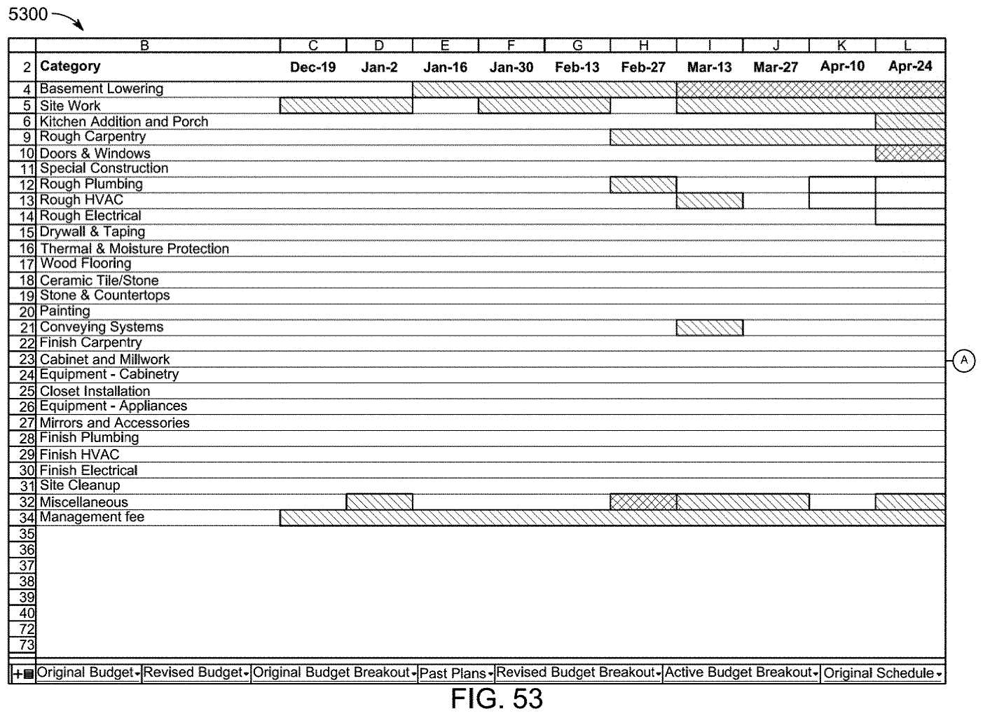

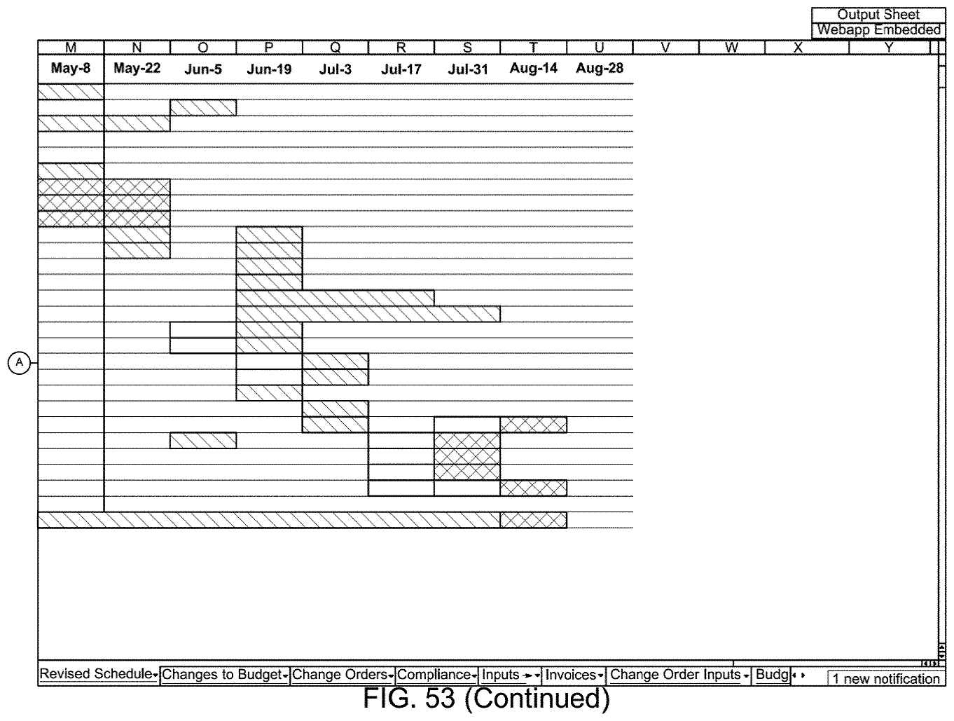

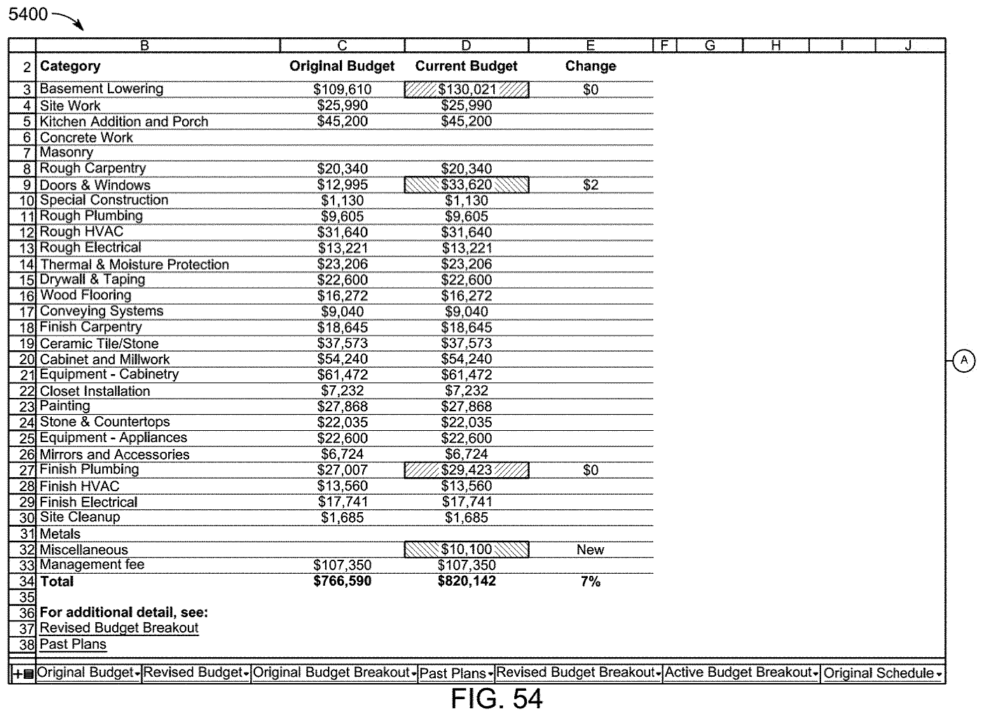

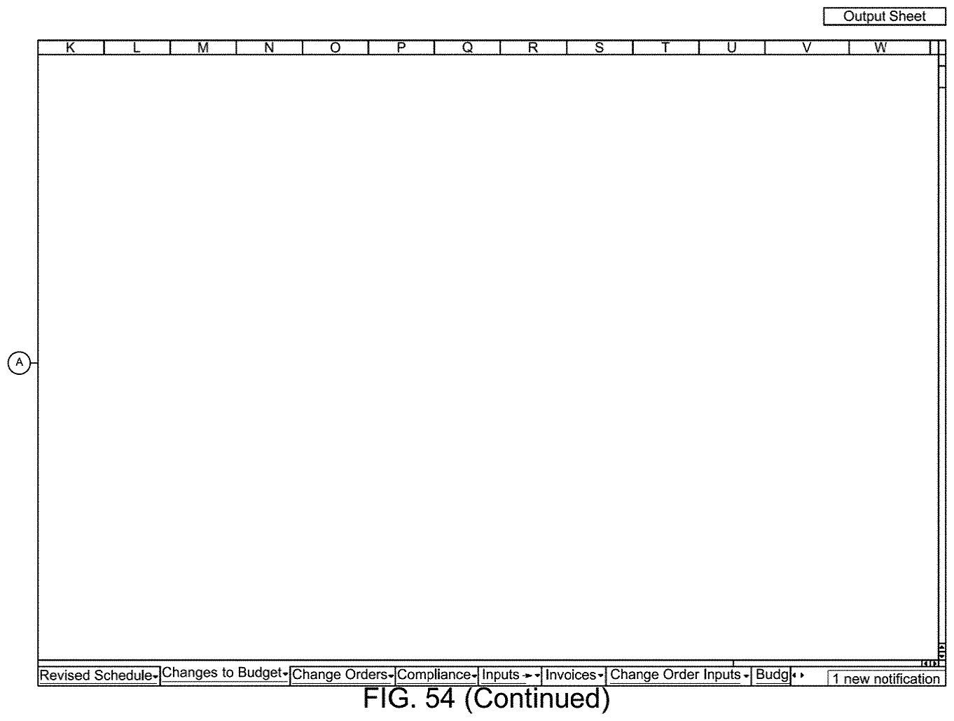

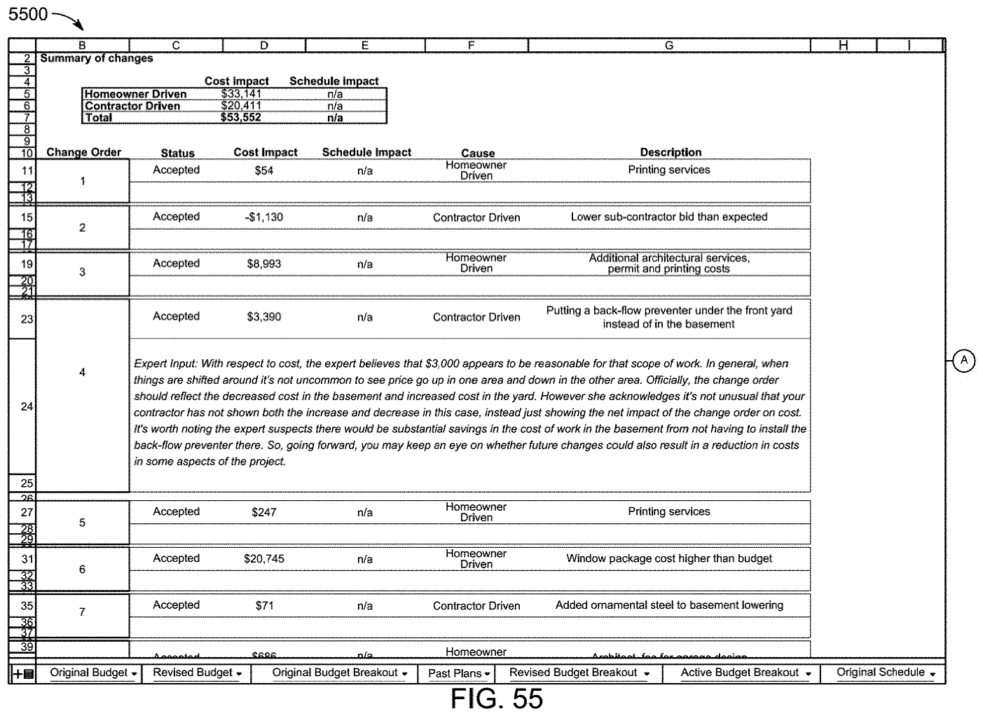

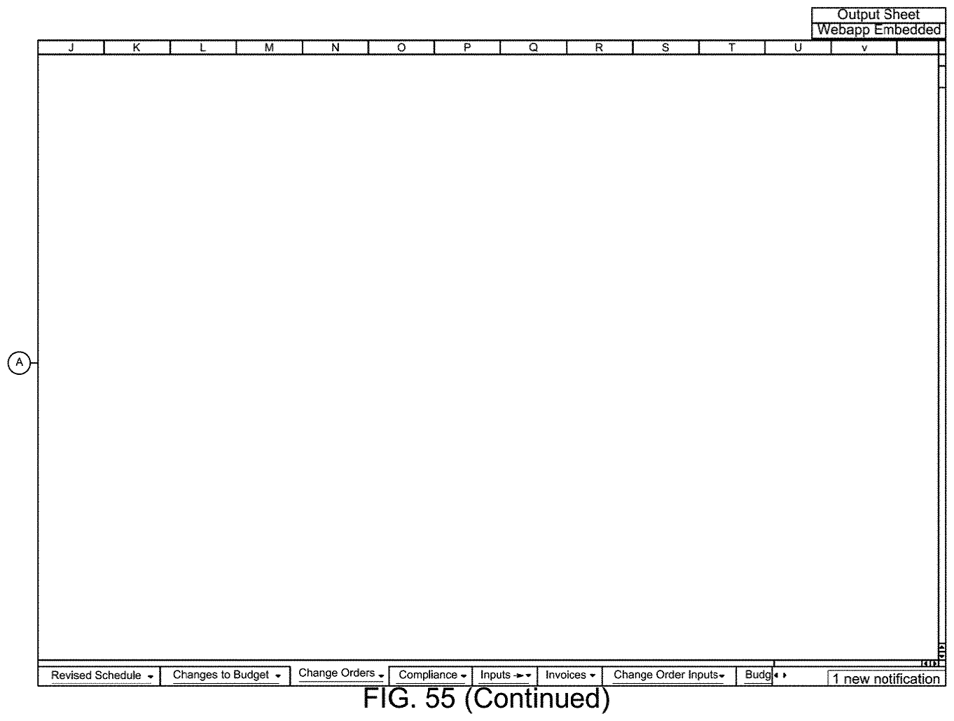

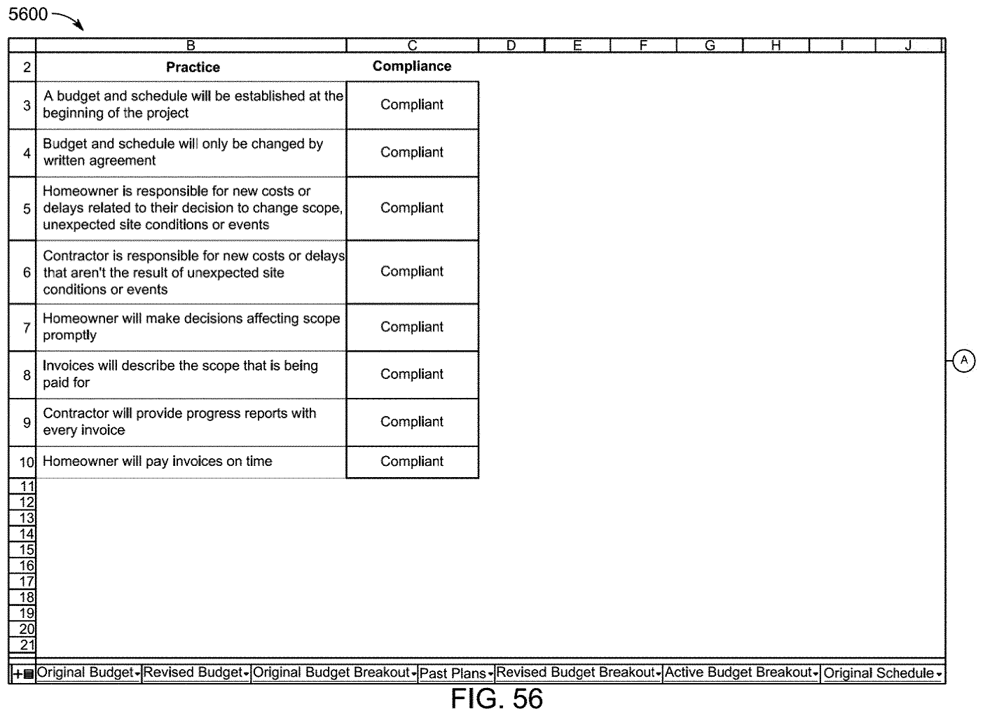

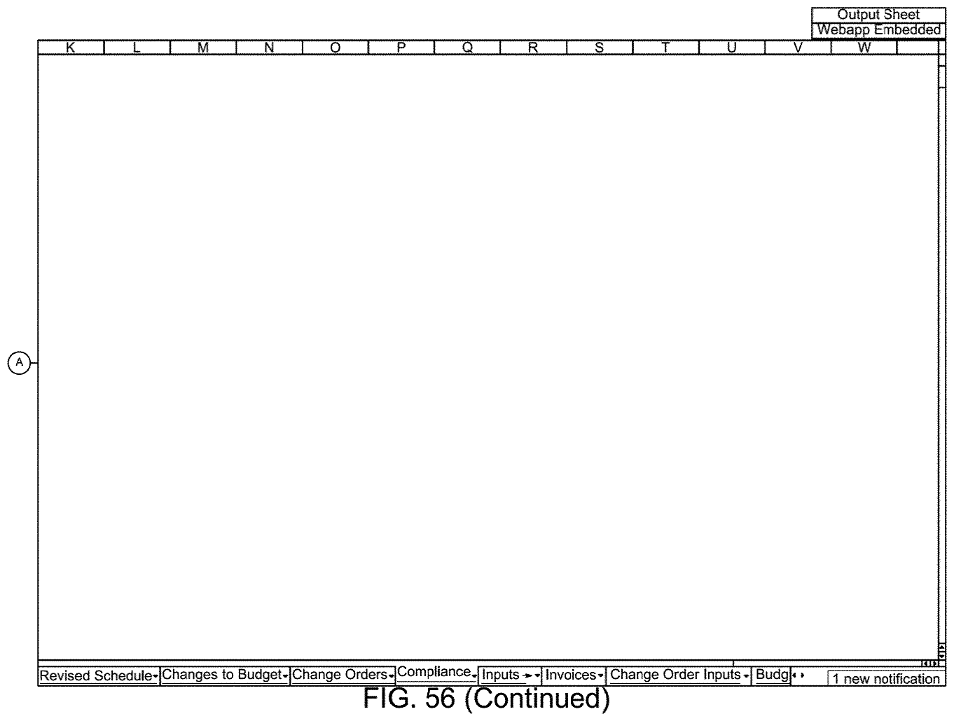

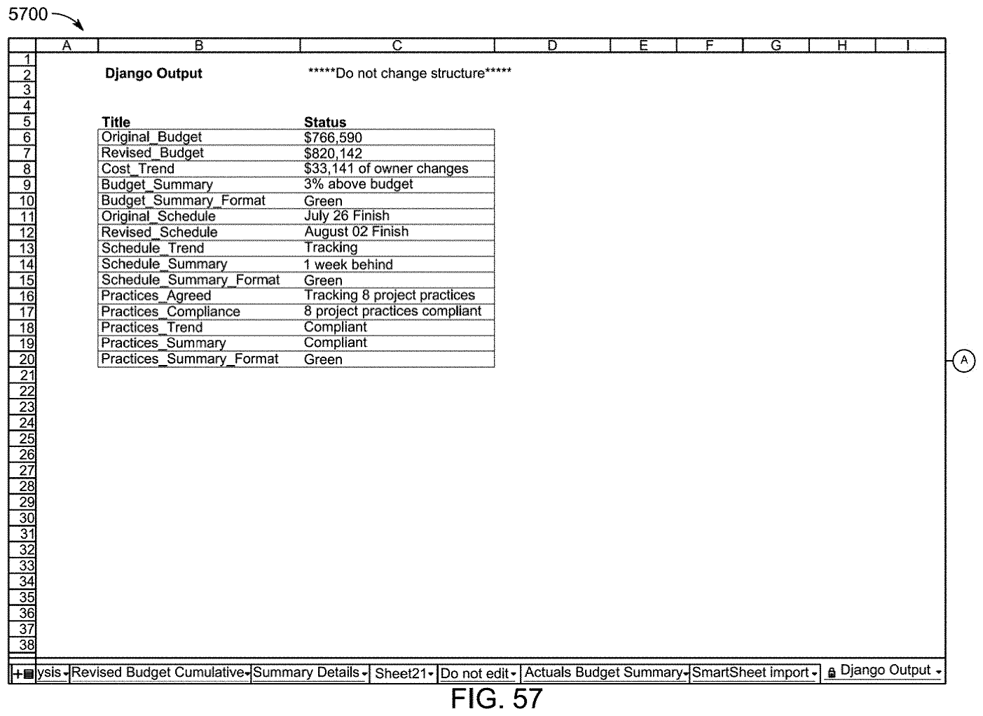

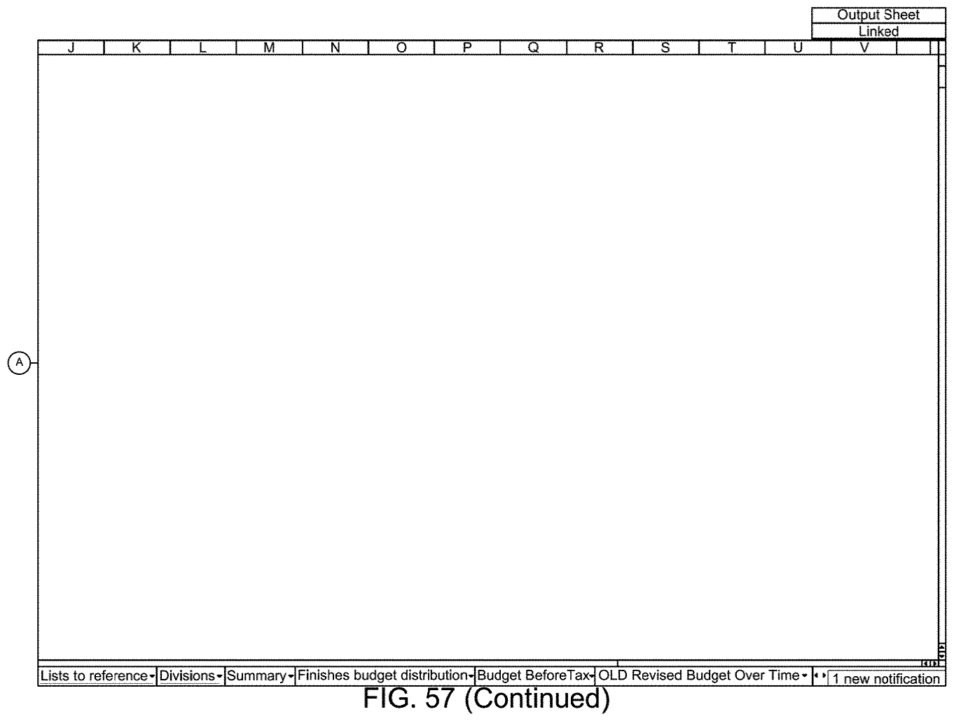

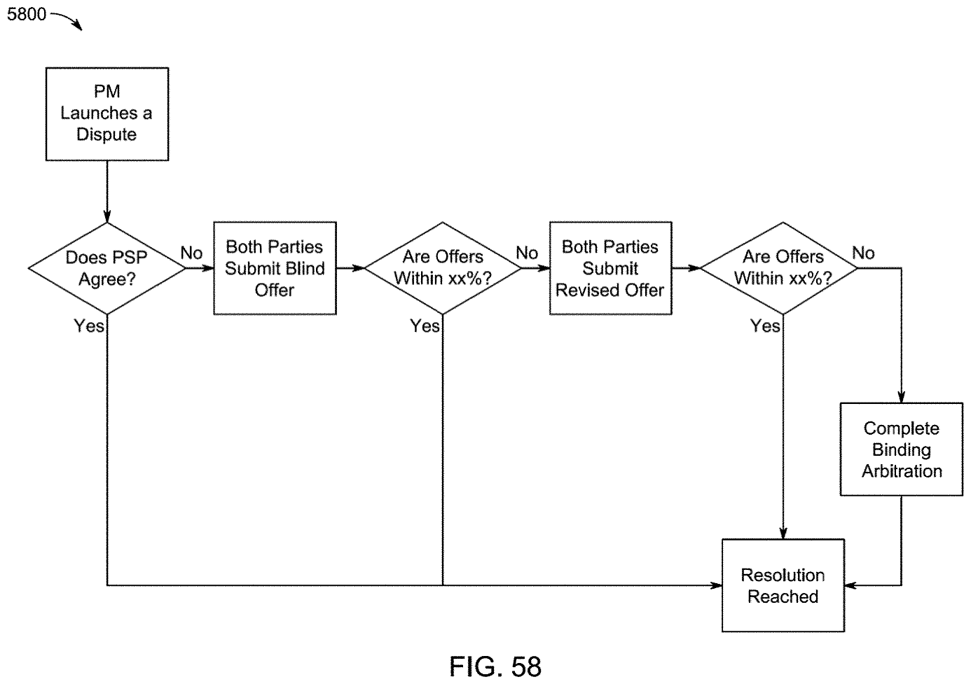

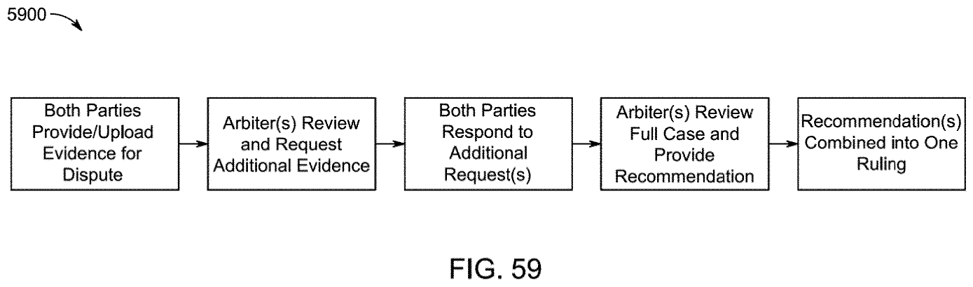

Some of the many features that may be enabled or otherwise facilitated by the PESP of system 1 may include, but are not limited to, one, some, or each of the following:
1. Brand marketing and browse (e.g., a landing page for each one of a PM and PSP)
   a. There may be a non-logged in experience on the “front door” or landing page of the PESP (e.g., website or app interface). Users may go to this page via a link from any suitable marketing or may go to the page directly based on referral or an offline ad. Users to this page could be a PM or a PSP.
   b. In an experience to entice a PM user or PSP user to sign-in or sign-up for the PESP, the PESP may provide a limited set of listings to expose some of the functionality of the service. The set of listings may be selected based on intelligence of information associated with the particular user (e.g., as may be gathered through IP identification, cookies from previous visits, and/or other electronic indicators). This may be combined with a “contractor score” or “PSP score” (e.g., as described in detail below).
   c. The PESP may ask structured questions to be able to refine the set of listings for the user.
   d. The PESP may also be an interactive demonstration of how the platform works from initial project creation right through home renovation job completion.
   e. The PESP may also provide a home renovation job price/time calculator for standard home renovation projects (e.g., on the landing page or elsewhere). Any suitable data (e.g., PESP generated data and/or data from previous projects of the PESP and/or any other suitable third party industry data) may be processed to provide standard pricing and standard project lengths for different types and scopes of projects (e.g., a bathroom renovation with a bathroom size of 50 square feet with tub and shower would cost $X and take Y weeks) and may be done with variable granularity to be specific for different characteristics (e.g., by ZIP code, by time of year, etc.).
2. Setup of PESP for User
   a. PM (e.g., Homeowner) sign up/login
      i. The user may be able to create an account to access the logged in experience of the PESP including everything below. Minimum requirements to sign up may be name, email address, and zip code and/or the like.
      ii. A PSP may be able to send a “sign up now” link to others including PMs, colleagues, and/or other entities (e.g., sub-contractors, etc.).
      iii. A PM or other party may be able to send a “sign up now” link specific to a PSP onboarding flow. For example, a PM may invite a PSP to join the platform, which may include a link to a specific project where a PSP may sign up for the platform in order to bid on the project. The PM may use an email from their account (e.g., social media or SMS) or a PESP account to invite the PSP.
   b. PSP onboarding; the PSP onboarding process may include, but is not limited to, one, some, or each of the following:
      i. creating an account to access the PESP.
      ii. providing know your customer (“KYC”), personal, and financial information data collection (e.g., as described in more detail in a Payments section below).
      iii. adding information to the user account for one or more public listings of the PSP (e.g., one or more previous or current or confirmed future jobs) to attract PMs. Data may be displayed on a search listing page and/or a service provider details page.
         1. The information a PSP may be able to add may be structured and may be based on a pre-defined taxonomy of data to its account. Data may include, but is not limited to, the following:
         a. Description of the PSP's business
         b. Job types the PSP covers
         c. Years of experience of the PSP
         d. References the PSP has
         e. Photos or other media of jobs completed by or pending with the PSP
         f. Range of job costs for the PSP
         g. Geographic coverage range of the PSP
         h. Free form text with personal notes (e.g., with a text editor)
         2. The PSP may be able to choose which fields to make public—PM onboarding may be simpler than PSP onboarding because the PESP may only require basic identification of the PM, such as e-mail address and/or telephone number and/or zip code and/or a profile picture and/or the like.
   c. Create new job or project (e.g., PM and/or PSP)
      i. A project in the PESP may be a central object for which other details/objects/actions/progress updates may be appended. It may be unique to a transaction (e.g., one home renovation job) that may be completed through the PESP. A project could be associated with either a PM account, a PSP account, or both. Each project may eventually be mapped to a PSP, scope definition, a set of terms, and/or the like.
      ii. A project object may be required for a PM and/or a PSP to use certain functions of the PESP.
      iii. A PM or a PSP may create a project.
      iv. As part of the process for finding the right PSP, the PM may create a project (e.g., a home improvement project) and may outline the details of the project for which they are sourcing quotes and entering into a relationship.
      v. The PM may already have a PSP in mind, but still may create the project as an object to use the PESP.
      vi. The functionality available to the PM (and/or PSP) related to the creation of the object may include, but is not limited to, the following:
         1. Structured inputs based on the job type to describe the project
         2. Structured inputs on preferences
         3. Free form entry of project details using a text editor
         4. Uploading of photos or other media
         5. Inclusion of references to other existing projects or designs
         6. Selection of level of visibility of the project to others (e.g., to a specific PSPs, a selection of PSPs, any service providers, etc.)
      vii. The record of the project created may be available through an interface, like a dashboard, when a PM or PSP is in a logged-in state to the PESP.
      viii. The dashboard may display stats on views on the projects and may have functionality where PSPs can leave comments or ask questions
      ix. There may also be instances where a PSP may create a project on behalf of a PM with whom he/she is already working
      x. The project may be shareable through e-mail and/or social networks (e.g., a third party enabler subsystem) and/or any communication mechanism that may be solely or at least partially facilitated by the PESP (e.g., PES subsystem 10).
3. Demand generation
   a. Match PMs and PSPs—PM interface
      i. The PESP may include one or more algorithms that may list and/or match one or more PSPs (e.g., in a relevant order) to a PM for one or more particular projects of a property of the PM. The criteria for the search listing order that may be provided by such algorithm(s) may be determined based on any suitable criteria elements, including, but not limited to, one or more of the following:
         1. Demographics of PM
         2. PM preferences (e.g., location, budget, type of work, age and/or condition of property, etc.)
         3. PM search history on the PESP (e.g., how often a PM has been seen in search, how often a PM's profile has been selected, how often someone has contacted a PM through the PESP, etc.)
         4. PM transaction history on the PESP (e.g., how many transactions a PM may have done through the PESP) and/or PM transaction history that may have not been done through the PESP but that may be accessed by the PESP through third party subsystems (e.g., payment processors, permit data sources, other websites, etc.)
         5. PSP performance in search results on other searches (e.g. click through rate)
         6. PSP conversion rate from quote to completed projects
         7. PSP ratings for completed projects, including sentiment analysis on free-form text feedback (e.g., identifying positive or negative language in free text, determining what language may be related to positive or negative reviews, determining what language may be tied to PSPs that do work on time versus not on time, on budget versus not on budget, clean work sites versus not clean work sites, etc.—and then processing such data to provide suitable sentiment analysis on such media for use by any suitable user of the PESP to aid in making a decision or recommendation)
         8. PSP transaction history (e.g., number of jobs, prices for past jobs, etc.)
         9. Statistics for PSP on completed projects (e.g., percentage of projects completed on time, percentage of projects completed on budget, percentage of projects completed without disputes, and/or the like)
         10. Number of photos and other media associated with the PSP and/or the PM and/or a particular project
         11. Whether any of the friends or other associates of a PM connected to the PM in one or more social networks (e.g., social networks distinct from PES subsystem 10 and/or a social network facilitated by the PESP) have used a particular PSP (or vice versa)
      ii. The PESP may use various components of the bullet point list above and potentially other inputs and feed it into any suitable AI/machine learning capabilities to produce an implicit “contractor score” or “PSP score” for a results ranking. The machine learning may also take PM preferences and/or PM history into account so that the PSP score may be personalized to an individual PM.
      iii. The PESP may allow a PM to browse through listings and save lists and favorites for later use
      iv. The PESP may allow a PM to annotate listings for future personal reference
      v. The PESP may facilitate a mechanism for communication between a PM and a PSP using any suitable communication protocol and/or any suitable communication type (e.g., e-mail, voice call, video call, text message, in-person meeting, virtual reality, etc.)
      vi. The PESP may allow a PM to have a dashboard or display where the PM may track some or all communications it has had with one or more PSPs over time with respect to a particular project or multiple projects (e.g., as described in more detail below in a dashboard section)
      vii. The PESP may allow for a PM to select a PSP with whom the PM may want to enter into an agreement and outline scope.
   b. Match PMs and PSPs—PSP interface
      i. Similar to PSP listings, there may be a listing page of projects that have been made public by one or more PMs
      ii. PSPs may be able to browse such a list
      iii. The list may be ordered based on maximum relevancy for the PSP. The criteria for the listing order that may be provided by one or more algorithm(s) of the PESP may be determined based on any suitable criteria elements, including, but not limited to, one or more of the following:
         1. Job type
         2. Geographic location of the PM and/or PSP
         3. Previous quotes published by PMs and which PSP(s) they matched with
         4. Preferences of a PM
         5. Availability of a PSP
         6. Machine analysis of free form text and/or audio and/or video and/or other descriptive media in a PM's profile and/or in a PSP's profile
      iv. The PESP may use various components of the bullet point list above and potentially other inputs and feed it into any suitable AI/machine learning capabilities to produce an implicit “project score” for a results ranking. The machine learning may also take PSP preferences and/or PSP history into account so that the project score may be personalized to an individual PSP.
      v. The PESP may allow a PSP to browse through listings and save lists and favorites for later use
      vi. The PESP may allow a PSP to annotate listings for future personal reference
      vii. The PESP may facilitate a mechanism for communication between a PSP and a PM about one or more particular projects using any suitable communication protocol and/or any suitable communication type (e.g., e-mail, voice call, video call, text message, in-person meeting, virtual reality, etc.)
      viii. The PESP may allow a PSP to have a dashboard or display where the PSP may track some or all communications it has had with one or more PMs over time with respect to a particular project or multiple projects (e.g., as described in more detail below in a dashboard section)
      ix. The PESP may allow for a PSP to select a PM and/or project with whom and/or with which the PSP may want to enter into an agreement and outline scope.
   c. PSP may submit a quote/bid for a particular project (e.g., quotes/bids may include three dimensional modeling or virtual reality capabilities or any other suitable media format—and/or data may be provided by the PESP on a history of a property (e.g., previous renovations, insurance claims, age, work on other properties nearby property of interest, etc.) that may be helpful for a quote/bid)
      i. The PESP may be operative to provide functionality for multiple PSPs to respond to a particular project (e.g., a project associated with a property of a particular PM). It may happen at the level of initial project creation, or it may happen once more detailed scope documentation has been added to the project.
      ii. In a case where a PSP submits a bid:
         1. A PM may update the scope of a project at any time (e.g., based on feedback from one or more PSPs or other entities or otherwise)
         2. The PESP may facilitate the ability of a PSP to ask questions or seek additional information pertaining to a project to enable the PSP to better make a bid/quote. Questions and answers may be shared with all PSPs that may be able to and/or interested in bidding on the project.
         3. The PESP may be configured to enable a process whereby multiple PSPs may bid on a project, either privately with the PM or publicly so other PSPs may see the bid.
         4. In a case where multiple PSPs may be bidding on a project, the PM may request bids to include proposals around specified scope, timeline, milestones, and/or the like and/or the PM may specify any or all of the following and may request PSPs provide their bid with proposals on the unspecified variables, including, but not limited to one or more of scope of work, materials used, timeline, milestones, payment schedule, and/or the like.
4. In-project flow
   a. Create scope and terms of project [PM and PSP]
      i. The scope and terms to which a PM and PSP may agree for completing a successful transaction (e.g., a particular PSP providing a particular service or collection of services with respect to at least one property of a particular PM as a project) may be attached to or otherwise associated with a project object (e.g., as additional details). There may only be one scope documentation and one set of terms related to a project object.
      ii. The PESP may enable a PM and/or PSP to document the planned scope of a project. One or more of the following may be associated with a planned scope:
         1. a standard structure for input of scope
         2. guided scope wizards for some types of projects
         3. sample scope documents available to copy or edit
         4. 3D modelling capabilities and/or virtual reality capabilities and/or any other suitable media capabilities that may potentially integrating floorplans and different potential layouts including appliances, structural changes, and/or the like
         5. areas for free-form text or other media provisioning
      iii. The PESP may have an established taxonomy to help structure the development of a project scope documentation for either or both of the PM and PSP.
      iv. The PESP may allow for the upload of photos, images, videos, drawings, or any other suitable media to accompany the scope documentation
      v. The PESP may enable either a PM and/or a PSP to document the terms of the project. One or more of the following may be associated with a term documentation:
         1. a standard structure or template for terms
         2. guided-terms wizards
         3. sample terms available to copy
         4. areas for free-from text or other media provisioning
      vi. The PESP may have functionality to allow one or both parties to edit the scope and terms documentations and see any changes that the other party has completed
      vii. The PESP may be operative to collect information on prices, timelines, and/or any other suitable factors for different scopes of work and/or may provide common project guidelines (e.g., including price range) to PMs and/or PSPs based on variables including, but not limited to, scope, materials, location, age of building, weather factors, and/or the like. Before a project is confirmed between a PM and PSP, the PESP may provide guidance as to what the expected price range would be based on the project and what all of the standard components would be on the project (e.g., if project is for a roof of X-square feet, the PESP could provide typical price range and project length for such a project and/or the PESP could provide information on typical components of the project including, but not limited to, required weather stripping, air vents, roof slope, shingle layers, drainage components, etc. that may be determined based on other projects of the PESP and/or data obtained from any suitable data source(s) that may be used to supplement or improve a project, and/or the PESP could provide a list of things than may go wrong and/or of unexpected changes a PM might encounter during such a project)
         1. These guidelines may be generated by an artificial intelligence/machine learning program that can determine an appropriate range for price, timeline, and/or any other suitable variables based on past projects, inputs provided by a PM and/or PSP and/or any other suitable sources of data.
         2. These guidelines may be shared with all, some, or no PMs and/or all, some, or no PSPs. For example, they may be offered as a premium service or they may be available to all users for enabling efficient partnerships and/or for arming certain parties with valuable information for use in forming a beneficial partnership
      viii. The PESP may have an embedded text editor for text areas of the scope and terms documentations
      ix. The scope and terms documentations may be convertible and/or downloaded into a printable or save-able format outside of a tool of the PESP.
         1. There could be sharing tools that may enable a PM and/or PSP to easily share the documentation over email or any other suitable communication channels.
      x. There may be live-chat or online help to support the completion of the scope and terms documentations while they are being created
      xi. There may be a documentations check process where the PESP may be operative to check for items that may be missing and give warnings to the PMs and/or PSPs to help them properly complete the documentations
         1. The PESP may be configured to automatically ensure that all the required components are completed, potentially based on a predetermined set of mandatory vs. optional fields (e.g., cost broken down by division of work, length of project, sub-contractor categories to be used, list of materials to be used, potential unseen complications that could add cost or time, proof of insurance, specific sub-contractors to be engaged, specific start date, contractor references, etc.)
         2. An artificial intelligence/machine learning system may be provided by the PESP that may learn over time what input(s) may be required or beneficial from a PM to get an accurate estimate from PSPs and minimize disputes and/or change orders and/or cost escalations and/or delays. It may then provide context specific suggestions to PMs to help them complete their scope documentation effectively
         3. Similarly, an artificial intelligence/machine learning system may be provided to help PSPs identify ways to ensure that their bids can be accurate and avoid disputes and/or cost escalations and/or delays. This could work by identifying common attributes of bids that may be associated with previous projects of the PESP having cost overruns and/or disputes and/or delays, and/or attributes of bids that result in a job being won or lost
      xii. The documentations may be accessible by both the PM and the PSP when they are signed in
         1. Such documentations may be included in the PM's and/or PSP's dashboard
      xiii. A dashboard may display or otherwise present completed status of the scope and terms documentations
      xiv. The PESP may allow two parties (e.g., PM and PSP) to verify that they have reviewed and/or approved the documentations for a project and have that status presented to the other party
   b. Sign an agreement digitally [PM and PSP]
      i. A digital agreement between the PM and PSP may be provided that may bind the parties to payment and dispute resolution terms of the PESP
      ii. PES subsystem 10 (e.g., an entity managing the PESP) may be a third party on the agreement (e.g., to potentially enable the PESP (e.g., a controlling entity of the PESP) to hold one or more other parties liable if an agreement is breached in any suitable manner).
      iii. The agreement could be created once the parties (e.g., PM and PSP) have agreed to engage one another on a project based on the scope and terms documentations that may have been mutually agreed to (e.g., either offline between the parties or as determined on the PESP during a bidding process)
      iv. The agreement may be entirely generated by the PESP
      v. The agreement may include some clauses that may be added or amended by either party, and some standard clauses from the PESP
      vi. Each party may be able to agree to the agreement digitally via the PESP (e.g., using a digital signature, clicking a button to indicate agreement, or any other suitable methods)
      vii. The PESP may leverage a third party solution to obtain the digital signature (e.g., a third party enabler subsystem)
      viii. The parties may also be able to sign a printed copy of the agreement, scan the agreement with their signature and/or print and send it in the mail for use by another party and/or the PESP
      ix. The agreement may have legal wording with casual explanations available to both parties, potentially by making the explanations appear over a clause when the user hovers their mouse over it or clicks on it
   c. Create and input a payment/progress schedule [PM and PSP]
      i. The PM and/or the PSP may be able to input into or otherwise generate on the PESP a schedule for the project delivery with milestone dates
      ii. The parties may be able to create a schedule of payments which may be tied to calendar dates on the project delivery or other schedule based milestones, job based milestones, or other factors
      iii. Milestones may be able to be set to automatically trigger a request for payment, deliver a notification via any suitable communication pathway (e.g., on the PESP, e-mail, text message, voice or video call, and/or the like), or potentially serve as reminders on the PESP without notifications or requests
         1. If a request for payment is triggered, the PM may be required to respond within a set timeframe or they may automatically authorize the payment tied to that milestone
      iv. The PSP can trigger a request for payment by indicating that a milestone has been achieved. This may be done by clicking a button, sending an email, updating their progress via a text based status update, or other means on the PESP
      v. There may be functionality for the PSP and/or the PM to provide evidence of completion of a milestone on the PESP, including, but not limited to, photos, videos, technical drawings, written communication, legal documentation, and/or the like
      vi. If a request for payment or notification of milestone is triggered, the PM may be able to dispute the request and/or enter a dispute resolution process of the PESP for the milestone concerned
      vii. In some cases, payments might be held in escrow (e.g., by the PESP or by a third party engaged by the PESP) based on any suitable factors, potentially including, but not limited to, credit of the PM and/or of the PSP, dispute history, size of job, size of payment for a given milestone, local laws and regulations, request by one or both parties in a transaction, and/or the like
         1. In certain instances, funds may be held in escrow from a certain time (e.g., from the signing of the agreement, from the beginning of the work on the project, and/or from the end of the previous milestone) and released per the milestone schedule, potentially subject to completion of milestones
         2. An escrow payment process of the PESP may help the PM by guaranteeing the funds are only released on proper achievement of milestones. It may help PSPs by guaranteeing access to funds upon successful achievement of milestones
         3. An escrow agent (e.g., PES subsystem 10 and/or a third party enabler subsystem) may also potentially use the funds in escrow to buy materials for the PM and/or the PSP and/or to pay subcontractors and/or to pay other outstanding costs of the project
      viii. Milestones may be visible from a project dashboard directly or by clicking a link
      ix. The payment schedule can be updated via signed agreement at any time
      x. There may be a credit checking progress for the next or all remaining payment installments once payment for a milestone is completed
   d. Display payment/process schedule and scope/terms [PM and PSP]
      i. The scope of work, terms, and schedule may be available to both parties throughout the project. See details in the Service Provider portal and Homeowner portal
      ii. The schedule may be sharable with another user
   e. Dispute request for payment [PM]
      i. A PM may be able to authorize release of funds requested or dispute the validity of the request for payment using the PESP
      ii. A PM may be able to authorize part of the payment and dispute a portion of the payment using the PESP
      iii. A PM may be able to trigger a payment after the resolution of a dispute using the PESP
      iv. Disputing a payment may trigger a dispute or inform a PSP that a request has been rejected, allowing the PSP to reconsider or request payment again using the PESP
   f. Ability to update scope and terms [PM and PSP]
      i. Scope changes, which may be referred to as change orders, can be proposed by either party during the course of a project and may need to be approved by the other party
      ii. Scope changes may be able to be completed on the online portal, on a mobile application, over email, or using other methods using the PESP
      iii. Changes to scope may result in a new digital agreement to be digitally or physically signed by both parties and either added as an amendment to the initial agreement or created as a separate document
      iv. Changes may be fully created and signed on mobile devices
      v. The scope change process may be designed to minimize the amount of time and/or number of operations. This may enable the scope and/or terms features of the PESP to be as clear and efficient as possible.
      vi. The scope change process may be done completely on a mobile app, allowing PSPs to update scope on the go before doing additional work at a project site using the PESP
      vii. One party of an agreement may request a scope or terms change and the other party may dispute such a request. In this case, the parties would enter the dispute flow of the PESP, while all such actions may be fully documented by the PESP for later analysis
   g. PSP project dashboard [PM and PSP]
      i. A PSP dashboard may be operative to present key facts about a project and/or help a PSP manage their work, milestones, payments, and/or the like.
      ii. A PSP dashboard may include and/or be operative to provide any suitable features, including, but not limited to, one or more of the following features (e.g., during the bidding process or otherwise) for use by any suitable party:
         1. A view of all PMs the PSP has had communications with
         2. See information about a PM and its history on the platform
         3. See the PM's proposed scope, terms, and/or the like.
         4. Provide feedback or send questions to the PM
         5. Save or favorite a project to come back to it
         6. Save a response without sending it to the PM
         7. Create cost estimates based on estimates of labor, materials, and other costs
         8. Syncing with the PSP's calendar that may be on the PESP or external to the PESP (e.g., on a PSP subsystem or on a third party enabler subsystem)
         9. Ability to share photos, videos, and/or any other suitable media to show samples of past work to a PM
         10. Contact PM support
         11. See and maintain project schedule
         12. Keep track of costs
         13. Indicate completion of milestones
         14. Indicate that work is behind schedule
         15. Launch change order/scope change request
         16. Upload photos, videos, and/or any other suitable media to show evidence of milestones and document the work
         17. Communicate with the PM in real-time or otherwise using the PESP (e.g., send instant messages back and forth with the PM)
      iii. The dashboard may include a set of statistics for the PSP about the bidding process and/or the project execution process, including, but not limited to, one or more of the following:
         1. Percentage of successful bids/quotes
         2. Number of views on bids/quotes
         3. Number of disputes per project completed
         4. Number of projects completed
         5. Project on-time completeness
         6. Project initial price versus end price averages and/or any other suitable indicators of frequency and magnitude of variance (e.g., max price escalation, % of time a project is more than 30% overestimate, etc.)
   h. PM project dashboard [PM and PSP]
      i. The PESP may provide a PM dashboard that may be operative to present key facts about a project (e.g., about a project at the bidding phase and/or during project execution) and/or help a PM track the number of bids, PSP communications, in-project execution progress, authorize payments, dispute completion of work, and/or the like.
      ii. A PM dashboard may include and/or be operative to provide any suitable features, including, but not limited to, one or more of the following features (e.g., during a project or otherwise) for use by any suitable party:
         1. See PSPs who have submitted bids/quotes
         2. See saved/favorited projects of other users
         3. Track comments made about PSPs
         4. Access all projects in progress and historical
         5. See and maintain in-project schedule
         6. Indicate completion of milestones and/or respond to PSP claims of milestone completion
         7. Authorize payment, including, but not limited to, payment based on achievement of milestones
         8. Indicate that work is behind or ahead of schedule
         9. Launch change order/scope change request
         10. Upload photos, videos, and/or any other suitable media to show evidence of milestones and document the work
         11. Contact customer support (e.g., the PESP may be operative to provide any suitable user with a quick way to contact a customer support group that may be employed by the PESP, as a user may have questions that they want answers to and a live person may be made available by the PESP via phone, email, chat, or an automated chat service that could quickly answer any questions the user had).
         12. Communicate with the PSP in real-time or otherwise using the PESP (e.g., send instant messages back and forth with the PSP)
   i. Leave rating and review [PM and PSP]
      i. Prior to closing a project, a PM and/or a PSP may be able to review each other
      ii. Reviews may be used as input to create PSP scores and/or project scores
         1. PSP reviews may include any suitable data, including, but not limited to, any one or more of the following types of data that can be used as input to a unique PSP score and/or project score
         a. PM rating of specific categories including, but not limited to, PSP politeness, PSP professionalism, PSP cleanliness, PSP timeliness, and/or the like
         b. Comments made with free text or any other suitable medium on specific categories and overall feedback. Sentiment analysis can be applied to this to determine positivity or negativity in such comments
         c. Overall PM rating for the PSP or overall rating for the PSP by the entire PESP (e.g., across multiple PM ratings for the PSP, as a “consolidated PSP score”) or PM rating for the PSP for a particular project
         d. Whether project was completed on time, and/or on budget, properly. This could come from PM feedback or data from processing the transaction and/or any disputes. Any suitable rating/score of a PSP may be based on any suitable mathematical equation(s) that may incorporate any suitable data, including, but not limited to, the PM's rating of the PSP across a number of sub categories, the project statistics related to on-time and on-budget completion, a sentiment analysis of the qualitative comments to discover if they are positive or negative (e.g., the sentiment analysis may provide another factor for a PSP score determination), and/or the like.
   j. Close project [PM and PSP]
      i. A process may be provided by the PESP for closing a project once the scope is complete and the final payment has been made
      ii. In the case of a dispute over the final completion of the project, the project may be closed by the PESP after the dispute is resolved (e.g., using the PESP or otherwise)
      iii. The closing process may require confirmation from one or both parties in the project. Confirmation might take the form of any one of the following or other suitable methods: clicking a button online on a portal, sending an email, making a phone call, and/or the like that may be detected or shared with the PESP
      iv. If either party does not confirm or refute closing of the project, it may be closed automatically by the PESP after any suitable period of time (e.g., 7 days).
5. Dispute
   a. Facilitated negotiation to resolve dispute with or without binding arbitration [PM and PSP] (see, e.g., process 5800 of FIG. 58)
      i. A structured process may be provided at least partially by the PESP to help parties in a dispute reach an agreement about a dispute without needing to use binding arbitration
      ii. Process could be a multi-operation bidding system whereby (e.g., for a financial dispute):
         1. Both parties privately enter an amount into the PESP that they are willing to settle for
         2. If the amounts overlap or are within a certain percentage of one another (e.g., 10%), then the PESP may facilitate the parties settling for the average of the two amounts
         3. If the amounts are not within a certain range of one another, then the PESP may facilitate one or both parties privately entering a new amount that is closer to an agreement. For example, in a dispute where the PM feels they should pay less than the agreed price, the PM may have to enter a higher amount they are willing to pay and the PSP could enter a lower amount they are willing to accept
      iii. A process could be a negotiation discussion with a remote or in-person facilitator (e.g., an entity provided by PES subsystem 10 or by a third party enabling subsystem)
      iv. A process could be producing a set of computer generated potential outcomes and having both parties independently (e.g., blind to the other party) indicating which outcomes they would accept, then choosing an outcome that all parties agree to accept
         1. A computer program of the PESP could use artificial intelligence/machine learning to determine the range of likely outcomes in a dispute and their likelihood and fairness based on different types of evidence. Then it could provide a recommendation based on the evidence which both parties could agree to or decline. Some examples of evidence may include, but are not limited to, photos or videos automatically assessed by a computer algorithm and compared with the scope of work to determine if the scope is met (e.g., scope could include 2×10 wood, and photo could be processed to determine that 2×6 wood has been used, or computer could be operative to detect whether a material is the material claimed or a less expensive one, or computer can be trained to understand from a photo or video or other suitable media whether the workmanship was of acceptable quality (e.g., by examining the quality of finishes, evenness of tiles, etc.)), comparing costs claimed to initial quote, along with rationale for cost escalations and using history of past transactions to determine if any changes in scope or price are reasonable or are indicative of negligence or poor planning/workmanship, invoices for materials or sub-contractor work or payroll logs may be automatically assessed to determine if a PSP's claimed expense is legitimate and is indeed incurred for the project in question, and/or the like. Such techniques may all be combined in any suitable way by one or more algorithms or processing techniques of the PESP to provide a final judgement, which may need to be learned over time through machine learning such as supervised deep learning.
         2. A program of the PESP could additionally or alternatively determine a range of outcomes and propose a number of potential outcomes that it may determine both parties have some likelihood of accepting based on any suitable factors, including, but not limited to, past experience with disputes, known history of PM and/or PSP, evidence provided, type of job, and/or the like. A program of the PESP may use negotiated outcomes to previous disputes, particularly those including the PM or PSP if possible, as an input to determine what range of outcomes a party might accept in a dispute. For example, if a PSP has accepted a 20% reduction in payment in the negotiation phase of another project when evidence has suggested workmanship was low quality, or they do not accept any reduction in payment when customer complains they have not used the right material and they have provided legitimate invoices, then such data may be utilized by the PESP as a factor in determining a negotiation technique. Additionally or alternatively, a PM's past behavior may be utilized by the PESP as a factor in determining a negotiation technique (e.g., if a PM has made a lot of claims that arbitration has determined to be false in the past, that PM may receive a less favorable outcome from the PESP in a new negotiation process based on that previous data).
      v. A process could be a single computer generated outcome of the PESP that all parties may agree to be bound to before the outcome is generated. The outcome could be generated randomly or based on a non-random algorithm. A random outcome may determine a range of possible outcomes (e.g., all of which may meet somewhere in the middle between the two parties' positions), and the PESP may then randomly choose an outcome. A non-random algorithm may be different in that the algorithm's recommendation may be taken as the final outcome, whereas in a range of outcomes, the PESP may generate 5 potential outcomes and the PM and PSP may indicate to the PESP which of the 5 outcomes they would accept.
      vi. If a multi-stage negotiation fails, the dispute may move to binding arbitration
   b. Provide evidence for a dispute [PM and PSP]
      i. An online portal of the PESP may be provided with instructions for enabling a party to present evidence to support that party's position in a dispute regarding a contracted job including, but not limited to, disputes regarding completeness of work, quality of work, timeliness of work, changes in price from agreed price, and/or the like.
      ii. An ability to upload evidence in support of a dispute may include any suitable type of evidence, including, but is not limited to, photos, videos, text explanations, technical drawings, written communications, receipts and invoices, weather reports, third party assessments, and/or the like.
      iii. Guidance around what is appropriate to include as evidence to support one's claims in a dispute may be provided
      iv. Different types of projects and different types of disputes may be associated with different types of evidence from the parties in dispute that may be required by the PESP
      v. The PESP may be configured with the ability to detect false and/or falsified evidence in a dispute, including but not limited to checking evidence remotely and manually, checking evidence in person, application of computer algorithms, application of machine learning to detect false evidence, and/or the like. For example, with respect to photographical evidence or any other suitable media evidence, the PESP may be operative to do any suitable analysis. For example, in order to determine if photographical evidence is original, the PESP may be operative to employ any suitable image search (e.g., a Google Image search or scrape images from websites that have designs, contractor projects, etc.—using third party subsystem(s)) and compare the evidence uploaded to those photos to see if there is a match that may indicate fraud, and/or the PESP or a third party program may be operative to determine if an image has been doctored from an original (e.g., through detecting stitching, inconsistencies in color/background, other means, etc.) and/or the PESP may be operative to use geotagging and/or time stamping on an image to determine whether the image was taken on a date or location that suggests the image is not what it is claimed to be by a party of the PESP, and/or the PESP may be operative to automatically check dates on invoices or receipts uploaded to see if they correspond to project dates, and/or the PESP may be operative to search for businesses mentioned in invoices to validate their existence, check for conflicts-of-interest with contractor and/or the like, and/or the PESP may be operative to scan barcodes or any other suitable data on an invoice/product/receipt or other evidence to determine if materials or work are a match with the information in the invoice/product/receipt.
         1. One or more processors of the PESP (e.g., at PES subsystem 10 and/or at one or more third party enabler subsystems) and/or one or more human entities managed by the PESP (e.g., via a user interface at PES subsystem 10 and/or at one or more third party enabler subsystems) may be operative to detect false evidence based on any suitable factors, including, but not limited to, one or more of the following factors: evidence of editing in photos, videos, drawings, written or verbal communications, or any other media, logical inconsistencies in the evidence and explanations provided, past history of honest/dishonest behavior of one or more parties, comparison of evidence to evidence from other projects and/or disputes, and/or the like.
         2. One or more processors of the PESP (e.g., at PES subsystem 10 and/or at one or more third party enabler subsystems) and/or one or more human entities managed by the PESP (e.g., via a user interface at PES subsystem 10 and/or at one or more third party enabler subsystems) may be operative to search the internet or any suitable accessible data base of information for images, agreements, videos, or other media used in the dispute to see if any evidence has been taken from other sources instead of being genuine evidence pertaining to the project in dispute.
      vi. The PESP may be configured with the ability to allow any party to add and/or remove evidence up until a predetermined deadline.
      vii. The PESP may include one or more computer algorithms and/or one or more artificial intelligence/machine learning/neural networks that may be trained using any suitable data (e.g., anonymized evidence collected in a dispute) to enable the PESP to better understand different types of evidence and its relationship to different dispute outcomes (e.g., outcomes determined by one or more trusted and accredited arbiters). Any suitable algorithm(s) may be used by the PESP to determine any suitable outcomes and/or reasons, and may be compared to outcomes from real arbiters to give feedback to the algorithm(s). Such algorithm(s) may be provided by or run on publicly available historical arbitration cases that may be similar to one or more cases handled by the PESP in one or more ways by collecting all the evidence of the arbitration and letting the algorithm run, then comparing the recommendation with the historical outcome to train the algorithm. An algorithm may be given ‘evidence’ from jobs that were completed with no disputes as input for running an arbitration, and then receive feedback that the project was a success to help it learn the characteristics of when a dispute is not reasonable.
   c. View evidence, and ask questions, create ruling [DAs] (see, e.g., process 5900 of FIG. 59)
      i. The PESP may be operative to provide an online portal to any suitable DA subsystem for providing an arbiter with access to any suitable evidence provided by all sides of a dispute.
      ii. The PESP may enable multiple arbiters (e.g., two or more of DA subsystems 100g-100i) to review the same evidence via the PESP and/or to ask follow up questions to and receive answers from all parties in a dispute via the PESP. The PESP does may be operative to prevent different arbiters to identify and/or communicate with one another (e.g., directly and/or via the PESP), which may prevent collusion and provide more effective arbitration.
      iii. The arbiters may be selected from a network across the U.S. and potentially other countries, where each arbiter may be any suitable arbiter using a DA subsystem and verified by the PESP as an arbiter user, such as subject matter experts, regular citizens, licensed arbiters, lawyers, PMs and/or PSPs who have used the PESP, and/or the like. PSPs from different cities may be used as arbiters in disputes. For example, such PSPs may be chosen if they have a rating that exceeds a certain threshold. They would then get to show that they are an arbiter on their profile to lend them credibility, possibly with the number of disputes they have arbitrated (e.g., with or without the outcomes). Successfully resolving disputes could also be an input into the PSP's rating score. PMs may be used as one of several arbiters in a process to balance out the perspectives. These PMs may be required to have completed a minimum number of projects on the platform and received a minimum rating.
      iv. The PESP may be operative to check if any of the arbiters have a potential conflict of interest with any parties in the dispute or with another arbiter that may be used for the dispute.
      v. The PESP may be operative to allow for arbiters to use remote evaluation of evidence, in-person collection of evidence, or any other suitable methods to inform a recommendation.
      vi. All questions asked by any arbiter on a dispute, and the answers, may be shared with every arbiter reviewing that dispute via the PESP.
      vii. The PESP may be operative to organize evidence from each side in any suitable manner that may help to ensure the most helpful sequencing of evidence for the arbiters to make a fair, informed, unbiased recommendation, for example, organization in a random order, computer algorithm generated order, manually generated order, pre-determined order for each type of evidence, and/or the like
         1. A computer algorithm of the PESP may be used to determine if the sequence and design with which the evidence is presented to an arbiter influences its recommendations and then to determine an appropriate sequencing and layout for the evidence to minimize likelihood of bias in the arbiter's recommendations. The PESP may be operative to identify disputes with similar evidence and an a/b test by putting the evidence in a different order for the arbiters. Then, the algorithm may compare the outcomes to see which order of evidence leads to more favorable outcomes for PMs versus PSPs (e.g., in order to identify a most fair evidence order for use in arbitrations).
      viii. A framework to help arbiters incorporate each piece of evidence into their recommendations as they process the evidence may be provided by the PESP and may include, but is not limited to, enabling an arbiter to provide a score or written comment or other type of feedback on each piece or section of evidence, to create an interim recommendation at different points in the evidence review, and/or the like.
      ix. The PESP may provide a dispute recommendation form that each arbiter may complete (e.g., via the PESP) based on the evidence in the dispute, which may include a recommendation that may include any suitable information, including, but not limited to, financial compensation, requirement of completion of work, discount on agreed upon price, non-requirement to pay, and/or the like.
      x. The PESP may include one or more algorithms that may collect multiple arbiter recommendations and other inputs (e.g., inputs that may include, but not limited to, one or more of a machine's evaluation of the evidence provided) and may provide a final outcome for the dispute that may include any suitable information, including, but not limited to, financial compensation, requirement of completion of work, discount on agreed upon price, non-requirement to pay, and/or the like, which may then be facilitate by the PESP between the parties.
         1. The PESP may include one or more computer algorithms and/or one or more artificial intelligence/machine learning/neural networks that may be trained using any suitable data to enable the PESP to better predict arbitration outcomes based on any suitable data provided by PMs and/or PSPs or otherwise. Once the predicted recommendations become accurate within an acceptable range of error, the algorithm(s) or network(s) of the PESP may be used independently to determine the outcome of binding arbitration with or without involvement from human arbiters at one or more DA subsystems. For example, an algorithm may be operative to make recommendations based on evidence from different disputes and be trained using feedback based on the difference in algorithm recommendations and real arbiter recommendations.
   d. The PESP may be operative to synthesize arbitration based on results of remote arbiters. For example, the PESP may be operative to utilize two or more arbiters for one project, and then may use the recommendations of all the arbiters as input to an algorithm for determining the final outcome of binding arbitration (e.g., by taking an average or weighted average of the recommendations).
6. Payments, credit, and collections
   a. Consumer credit evaluation [PESP]
      i. The PESP may be operative to determine what credit evaluation process may be required for each customer using a number of any suitable job characteristic indicators. For example, larger jobs may require more extensive consumer information to be gathered.
      ii. The PESP may facilitate a workflow to gather consumer information easily and effectively from various parties (e.g., via PM subsystems, PSP subsystems, and/or third part enabler subsystems (e.g., financial institutions and/or social networks of one or more parties)).
      iii. The PESP may be operative to utilize one or more application program interfaces (“APIs”) (e.g., of one or more third party enabler subsystems) to get credit scoring information and/or other information related to PM ability to pay or PSP financial stability returned to the PESP.
      iv. The PESP may be operative to provide an automated process to selectively manage PMs as a function of credit score (e.g., lowest credit customers may be rejected or may require escrow). If the PESP determines that a PM has a low credit score, the PESP may be operative to treat that PM differently than someone with an adequate credit score. For example, the PESP may not serve someone with a low credit score and block them from being able to finalize an agreement with a PSP. Alternatively, the PESP may make them pre-pay and hold funds in an escrow account, something that may not be required of a user with an adequate credit score.
   b. PSP credit evaluation & payments enrollment [PESP]
      i. The PESP may be operative to access and utilize payments enrollment information to provide a credit evaluation. The PESP may be operative to generate and/or receive a credit evaluation on the PSP based on the information they have provided about their personal financial information.
      ii. The PESP may be operative to provide a full payments enrollment process for any suitable party, which may include accessing and/or utilizing any suitable company information for know your customer (“KYC”), anti-money laundering (“AML”), insurance (e.g., Blue Cross Blue Shield (“BCBS”)), and/or the like.
   c. Collect payment from PM [PESP]
      i. The PESP may be operative to enable payment sign up that may include:
         1. Credit, debit, and/or Automated Clearing House (“ACH”)
         2. Full enrollment process
      ii. The PESP may be operative to enable a commitment to binding arbitration
         1. The PESP may be operative to provide a flow for communication of obligations under binding arbitration and/or a form/system to facilitate any suitable party(ies) to enter agreement.
   d. Collect from PM [PESP]
      i. The PESP may be operative to provide a flow for collecting payment from a PM following a dispute finding against a PM. For example, the PESP may be operative to confirm post dispute that the PM has to make an additional payment. It may or may not require explicit consent from the PM for the payment collection process to be initiated (e.g., depending on the terms of the agreement). The timing and method of the payment collection may be disclosed to the PM and the PSP could track progress.
      ii. The PESP may be operative to provide a collections mechanism for reconciling PM default (e.g., with PES subsystem 10 alone or in combination with any suitable third part enabler subsystem(s) (e.g., a collections agency or any other suitable service provider)).
   e. Collect penalty from PSP [PESP]
      i. The PESP may be operative to provide a workflow for collecting from a PSP following a dispute finding against a PSP (e.g., a penalty). The PESP may be operative to confirm post dispute that the PSP has to make an additional payment. It may or may not require explicit consent from the PSP for the payment collection process to be initiated (e.g., depending on the terms of the agreement). The timing and method of the payment collection may be disclosed to the PSP and the PM could track progress.
      ii. The PESP may be operative to provide a collections mechanism for reconciling PSP default (e.g., with PES subsystem 10 alone or in combination with any suitable third part enabler subsystem(s) (e.g., a collections agency or any other suitable service provider)).

### Description of FIG. 58

As described above, FIG. 58 is a flowchart of an illustrative process 5800 for facilitating negotiation to resolve dispute. with or without binding arbitration. It is understood that the operations shown in process 5800 of FIG. 58 are only illustrative and that existing operations may be modified or omitted, additional operations may be added, and the order of certain operations may be altered.

### Description of FIG. 59

As described above, FIG. 59 is a flowchart of an illustrative process 5900 for collecting evidence and creating a ruling. It is understood that the operations shown in process 5900 of FIG. 59 are only illustrative and that existing operations may be modified or omitted, additional operations may be added, and the order of certain operations may be altered.

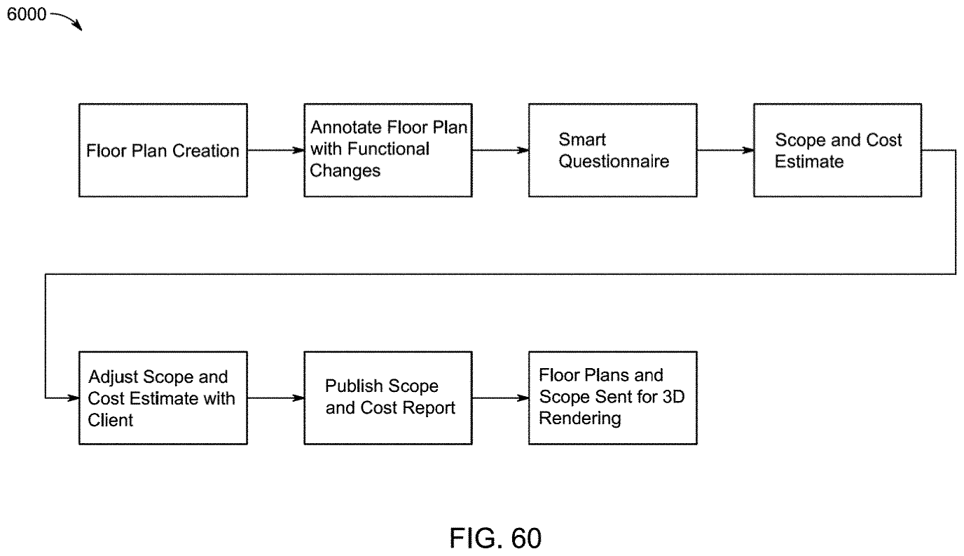

### Description of FIGS. 60-66

PESP system 1 can provide various pre-construction services, such as, for example, for a home remodel, from design to construction, including, for example, a guarantee to be on budget. Various pre-construction services may be provided, prior to a construction phase, to set up a project for success. The components of various pre-construction services can include:
1. Homeowner (or any entity responsible for a property) On-Boarding
   a. Speaking to homeowner regarding a home (or any other type of property) visit
   b. Delivering a home visit
   c. Using a “Skylight Home Visit App” to deliver an automated design specification experience
   d. Evaluating projects according to their unforeseen site condition risk to screen and price projects appropriately
2. System for Automating Design Workflow
   a. Capture detailed floor plans to facilitate design process
      i. Visiting the home and using an application to capture floor plans digitally
   b. Facilitating design process electronically
      i. Providing floor plans and homeowner design objectives that may be captured by Home Visit App to architect or designer, to perform conceptual design
   c. Facilitating structural engineering, MEP engineering, soil engineering other engineering processes electronically
      i. Using remotely generated conceptual and detailed architectural drawings, provide such to structural engineer to perform structural engineering analysis
   d. Facilitating rendering process
      i. Using owner design objectives captured by Home Visit App to create specifications for creating photo-realistic 3D rendering of intended renovation, inclusive of finishings
3. System for Putting Project to Bid, Evaluating Responses and Awarding Contract
   a. Putting project to bid with group of Skylight contractors
   b. Evaluating contractor bids

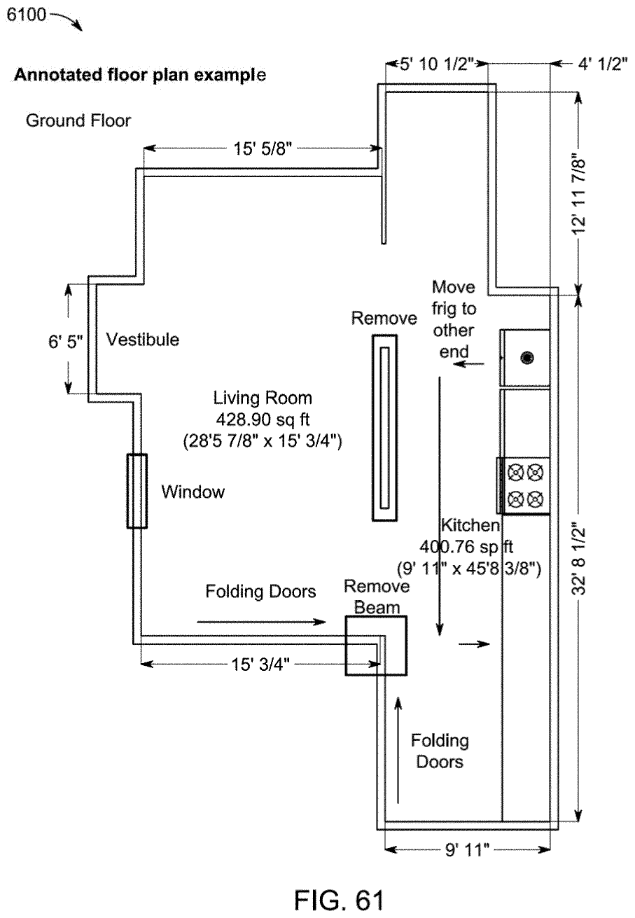

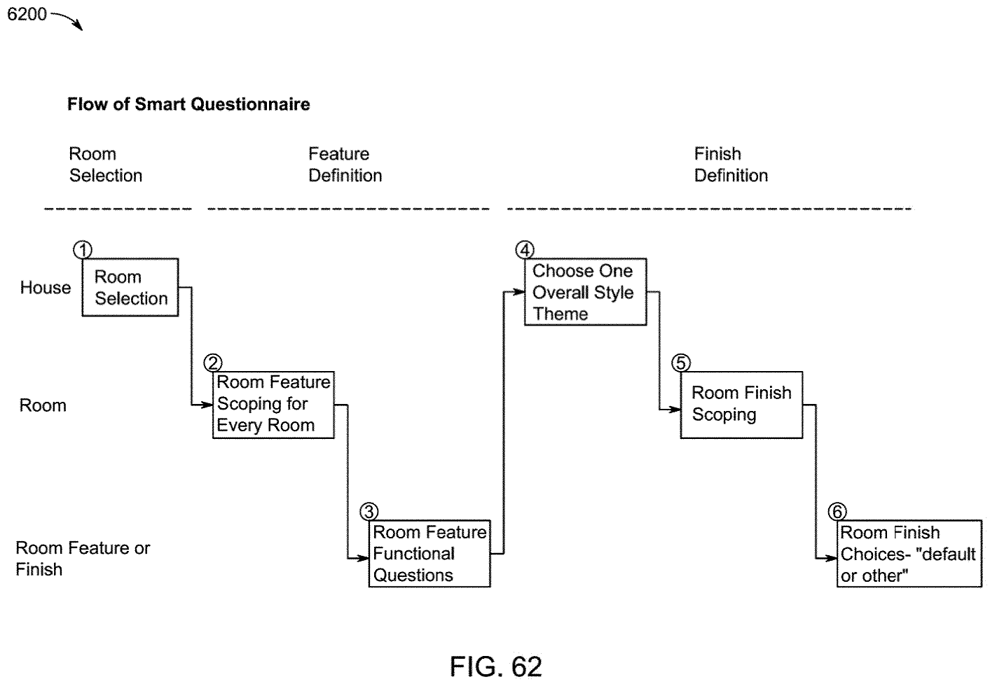

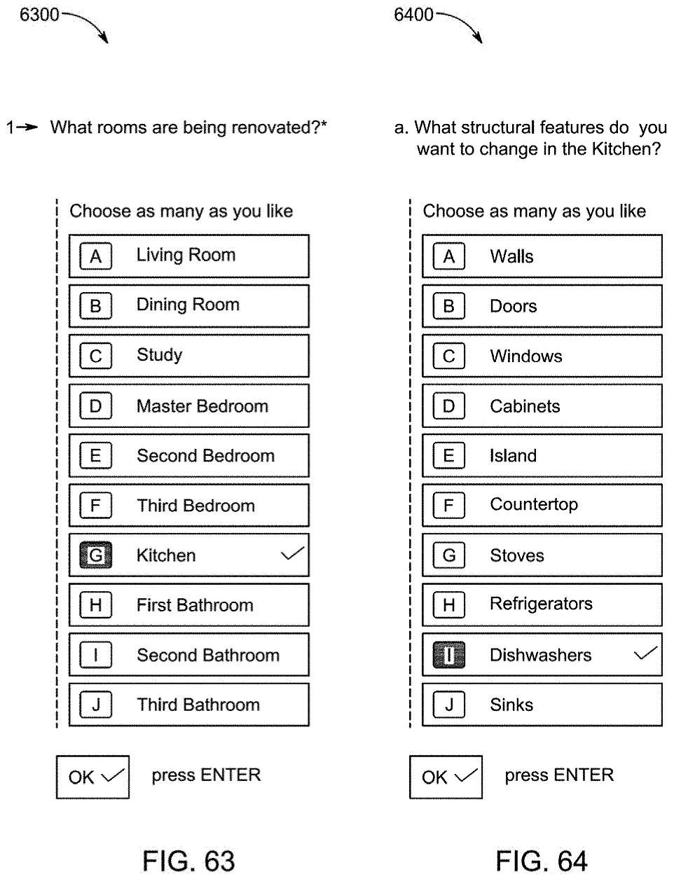

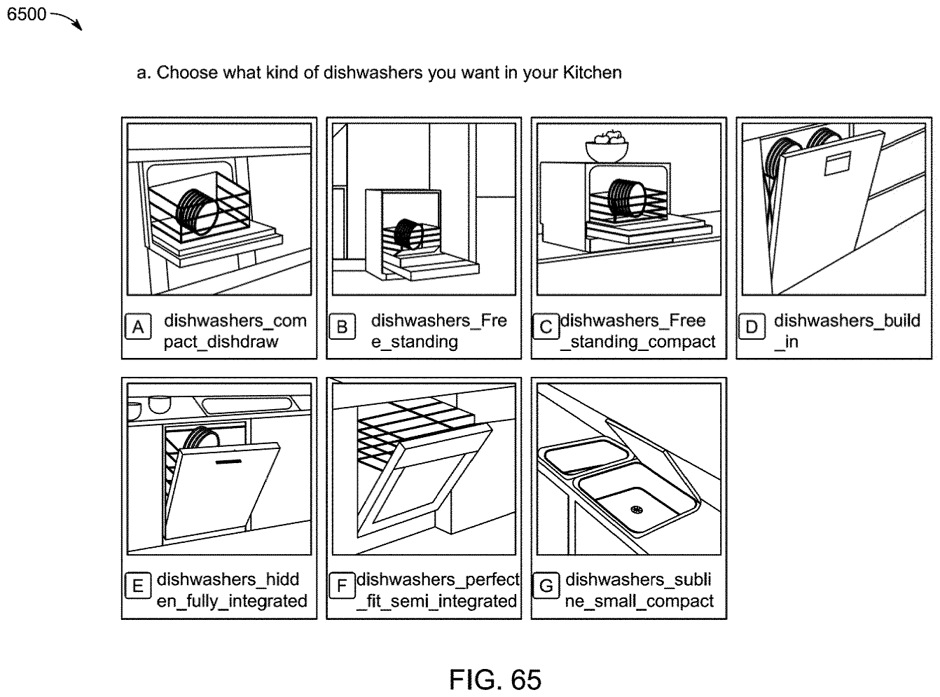

With respect to a “Home Visit App” that may deliver an automated design specification experience (e.g., of 1(c) above), a home visit application may be provided by the PESP to allow a non-expert to provide a detailed and accurate home renovation scope of work and cost estimate. This may be done during a home visit, or potentially remotely. The application may be operative to guide a user through various operations and questions to turn a homeowner's rough ideas for a renovation into a specific scope of work and associated cost estimate. The application may be web-based or may be a mobile app or any other suitable type of application or otherwise that may be accessed and utilized by any suitable end user using any suitable device. The elements of such a Home Visit (“HV”) app may include any suitable elements, including, but not limited to the following:
1. An operation by operation flow that may present to the user what to do at each operation to capture the required or any suitable information
2. Creating floor plans using a smartphone or tablet camera and/or other tools that connect to a computer or tablet via Bluetooth or other technologies
3. Making notes on the floor plan with a client to detail the functional scope changes
4. A smart questionnaire asking about every aspect of the renovation. The user may only be asked relevant questions (e.g., they only get questions about the Kitchen if they are renovating the Kitchen, they only get questions about flooring if they intend to replace the flooring, etc.) for the project being handled, such as, for example:
   a. What rooms are to be renovated?
   b. Functional goals?
   c. What functional changes will be required?
   d. What features will be removed, added, and replaced?
   e. Style preferences?
   f. What finishes will be removed, added, and replaced?
   g. What materials will be used in the renovation?
5. The results of the questionnaire and floor plan annotation may be used to automatically generate a scope of work document and cost estimate for the project
6. A set of broad style categories that may determine what appliances, finishings, and functional components may be recommended
7. Results of the questionnaire and floor plan annotation may be used to create a 3D rendering of the potential end state of the home after renovation
8. An interface where the user and homeowner can make adjustments to the initial cost estimate by modifying the scope may be provided (e.g., if the cost estimate was too high, they might try less expensive appliance selections to see if estimate now comes within budget)
9. A report may be automatically published for the homeowner with the scope and cost estimate
   Questions that may be asked in the application to create scope and cost estimates may vary by room type, where room types may include, but are not limited to the following room types: Kitchen; Bathroom; Living Room; Bedroom; Hallway; Office; Garage; and Basement. Functional changes may impact the way the space is used. Functional features may include, but are not limited to, the following types of functional features (per room type): living room/office/bedroom: walls; stairs; doors; windows; and shelves; kitchen: walls; doors; windows; cabinets; island; counter tops; stove; dishwasher; refrigerator; dishwasher; and sink; bathroom: walls; doors; windows; shower; bath; bathroom cabinets; counters; sink; vanity; toilet; washer; and dryer. Finishes may be aesthetic features that do not impact the way the space is used. Finishes may include, but are not limited to, the following types of finishes: painting; flooring; lighting; wall tiling; window covers; trim; outlets; and switches. FIG. 60 is a flowchart of an illustrative process 6000 for using an HV app. It is understood that the operations shown in process 6000 of FIG. 60 are only illustrative and that existing operations may be modified or omitted, additional operations may be added, and the order of certain operations may be altered. For example, a floor plan may be created, the created floor plan may be annotated with any functional changes (e.g., as shown by annotated floorplan 6100 of FIG. 61), a smart questionnaire may be provided, a scope and/or cost estimate may be determined, a determined scope and/or cost estimate may be adjusted with the client, a scope and/or cost report may be generated and/or published, one or more floor plans and/or scope may be sent for 3D rendering, and/or the like. FIG. 62 is a flowchart of an illustrative process 6200 for a smart questionnaire that may be used by an HV app. It is understood that the operations shown in process 6200 of FIG. 62 are only illustrative and that existing operations may be modified or omitted, additional operations may be added, and the order of certain operations may be altered. For example, a room may be selected (e.g., as shown by an exemplary questionnaire example 6300 of FIG. 63 for selecting a room to be renovated (e.g., choose a room or rooms to be renovated)), a room feature scoping for a room may be selected (e.g., as shown by an exemplary questionnaire example 6400 of FIG. 64 for selecting which functional feature(s) are to be renovated (e.g., choose as many kitchen features as the client wants)), a room functional feature may be selected (e.g., as shown by an exemplary questionnaire example 6500 of FIG. 65 for selecting one or more types of features (e.g., choose what kind of dishwasher(s) a user wants in the kitchen)), an overall style and/or theme may be chosen, room finish scoping may be handled, and room finish choices may be determined (e.g., default or other), and/or the like.

An introduction phase of an HV app may be provided that may be operative to systematically collect input on a client's objectives, create a good impression through a highly organized and thorough experience, and give the client a sense of what is possible for a particular budget range. For example, the app may provide an introduction with respect to an estimation and design session, provide an introduction and explanation of its role, provide an explanation of purpose and likely duration of visit (whether in person or only via app), obtain a short description of project from client, provide an explanation of PESP framework for function and style (function and style framework), provide an explanation of floor plans and discussion of specific functional and style goals, and/or the like.

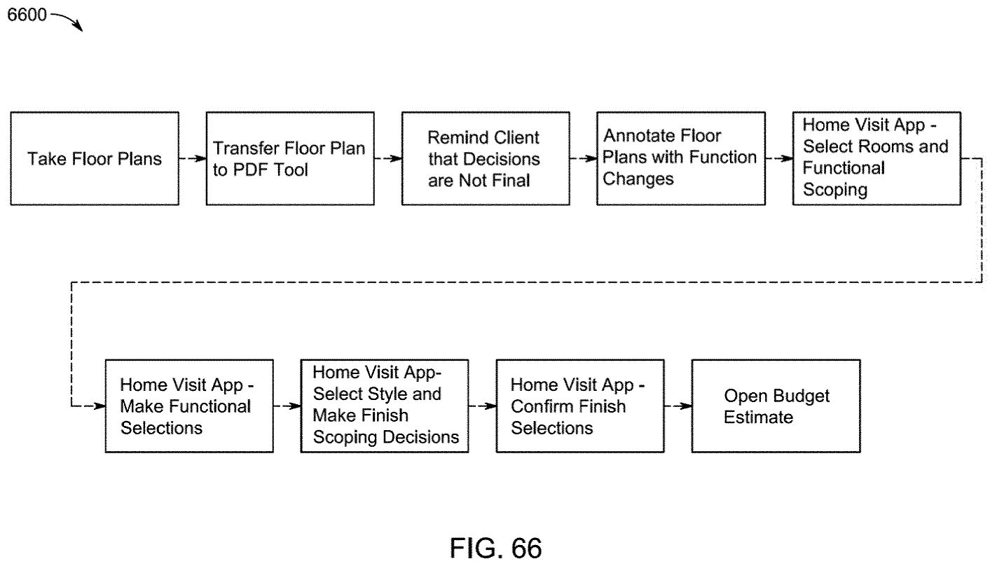

An initial scoping phase of an HV app may be provided that may be operative to provide an initial scope of what may be done. For example, the PESP (e.g., app and/or agent) may obtain floor plans alone or with client watching, discuss functional changes and mark up the floor plan, explain that no final decisions are being made at this phase but that a goal is to give them a sense right away of what they can achieve for a particular budget so they can start planning with the facts, perform HV app walk through, open automatic budget estimator, and/or the like. FIG. 66 is a flowchart of an illustrative process 6600 for collecting and/or annotating a floor plan. It is understood that the operations shown in process 6600 of FIG. 66 are only illustrative and that existing operations may be modified or omitted, additional operations may be added, and the order of certain operations may be altered. For example, a floor plan may be obtained, the obtained floor plan may be transferred to a tool (e.g., to a PDF tool), the client may be reminded that decisions are not final at this phase, the floor plan may be annotated with any functional changes, the HV app may select rooms and functional scoping, the HV app may make functional selections, the HV app may select style and make finish scoping decisions, the HV app may confirm finish selections, and open a budget estimate.

A budget and scope phase of an HV app may be provided that may be operative to tailor an estimate and/or a proposed scope to a client's budget, function, and/or style objective. For example, the PESP (e.g., app and/or agent) may recap the proposed scope of the project, share the cost estimate, work with client to tune or otherwise adjust the scope and cost estimate, discuss options to explore in follow up, and/or the like.

An additional phase of an HV app may be provided that may be operative to agree on a specific follow up plan, get client excited about the design to be produced for them, give client a sense that they are going down the proper path, and/or the like. For example, the PESP (e.g., app and/or agent) may explain the basic process of how the PESP will work with the client, explain next steps, such as no cost 3D rendering of one room and/or 3D model of entire renovation, leave client with cost estimate, discuss plans to revise scope or estimate based on client objectives, book follow up video call where client may be shown a design rendering and discuss client feedback, such that the client may get to know how the PESP works and the PESP may learn about the client's preferences, and/or the like.

With respect to unforeseen site condition risk (e.g., of 1(d) above), an Unforeseen Site Condition Risk Evaluation System (“USCRE” system) may be provided by the PESP. Unforeseen site conditions (“USC”), or conditions of a property discovered during construction that increase cost during construction, can have an unpredictable and negative impact on a construction project. USC (e.g., by definition) may not be detected prior to opening the structure of the home, and therefore may cause a project's costs to increase after the project is started. Because there is not currently a system to predict USC risk, a worst case impact of USC cost increases can be damaging to an owner. Additionally, USC risk creates financial unpredictability for renovation projects, which is a disincentive to undertake these projects. The PESP may be configured to provide a unique system for evaluating unforeseen site condition risk, and appropriately pricing a service that protects the owner from that risk. The system may use characteristics of the owner's property and/or characteristics of the owner's project to predict the likelihood and cost of USC. The USCRE system for predicting USC risk may be based on any suitable input data, including, but not limited to, the following types input data: project characteristics; location of the property; age of property; and permit history of the property. The USCRE system may use a rules based statistical model, such as based on historical renovation history data gathered by the PESP (e.g., by PES subsystem 10 via its construction partners) to predict average expected USC events and associated cost. It may do so across any suitable USC categories, including, but not limited to, the following types of USC categories: unexpected plumbing; unexpected electrical; unexpected HVAC; dry rot; water damage; termite damage; various work arounds; structural issues; asbestos/lead paint/mold; planning errors; and unexpected demolition. The system may be based on a set of rules around the relationship between project characteristics and property characteristics to make a prediction regarding specific categories of USC risk. Rules may be based on research and data around the nature of each category of USC risk, and the relationship between project characteristics and property characteristics that may be indicative of each of the categories of risk.

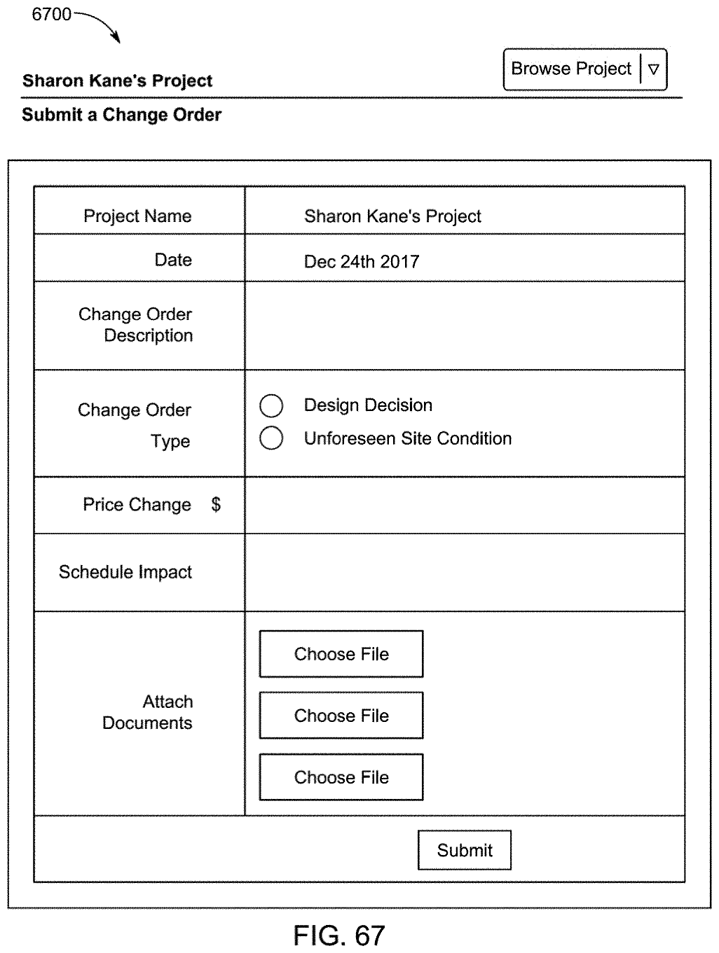

### Description of FIG. 67

A digital change order process for a core project management feature of the PESP may be provided. Generally, as mentioned (e.g., with respect to one or more of FIGS. 7, 33, 45a, 45b, 46, 50, and 55), a change order can be a record of a change in price or a change in schedule on a renovation or construction project or any other suitable type of project of the PESP. Any time there is any deviation from the originally set budget/cost for a project, an associated change order may document the reason(s) for the change and the approval from the homeowner for the change(s). A change order process may be provided by the PESP as a project process for a homeowner. When a new project is initiated for a homeowner, a budget/cost for the project (e.g., what the homeowner pays) may be locked down at the start of the project. As Contractors or any other suitable property service provider or otherwise may issue invoices to the homeowner, each invoice may be compared (e.g., automatically by the PESP and/or by any suitable PESP operator) to the original budget for the invoiced item(s). If there is any difference or discrepancy detected between the invoice amount and the original budget amount, then a change order may be generated (e.g., automatically by the PESP and/or by any suitable PESP operator). In the case of a budget difference, a change order form may be submitted online by the contractor. The change order form may include the details of the project, the change, and any associated attachments. For example, as shown in FIG. 67, an exemplary change order submission form 6700 may include various suitable information regions for identifying any suitable information, including, but not limited to, project name or other suitable project identifier, date, change order description, change order type (e.g., design decision, unforeseen site condition, etc.), price change, schedule impact (if any), and an attachment option. There may be any suitable types of reasons for a change order, including (1) unforeseen site condition(s), where the different cost may have been unforeseen by the contractor upon initial scope of the project and it may or may not be the homeowner's responsibility to pay, and (2) homeowner design decision, where the different cost may be due to a change of scope by the homeowner from the initial project scope and it may be the homeowner's responsibility to pay. The change order may be assessed (e.g., automatically without human intervention by the PESP (e.g., via any suitable machine learning algorithms operative to determine the appropriateness of a change order) and/or by any suitable PESP operator) for appropriateness and may be approved or disapproved by the PESP. If a change order is approved, the budget may be revised automatically. Otherwise, the change order may be sent back to the contractor as rejected and the contractor may be held responsible for the increased costs.

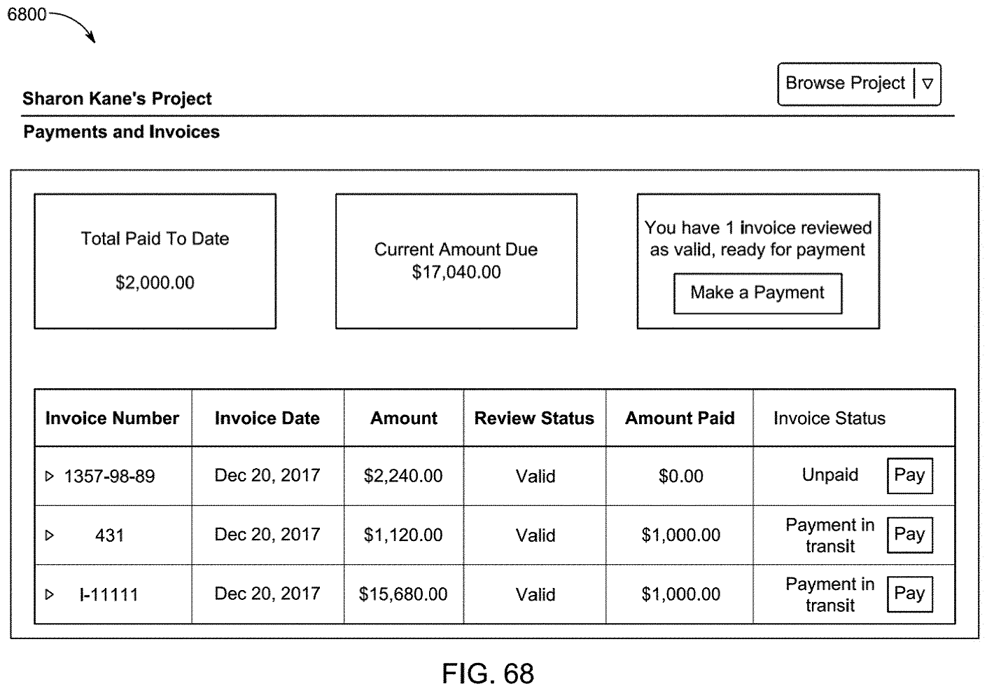

### Description of FIGS. 68-74

A payment process may be provided by the PESP that may enable a homeowner to pay for any suitable service/product provided to the homeowner and that may enable a contractor or any other suitable property service provider or otherwise to receive payment for any suitable service/product provided to the homeowner. A third party payments provider (e.g., any suitable third party enabler subsystem (e.g., one of third party enabler subsystems 100j-1001)), such as Stripe of San Francisco, Calif., may be used by the PESP to allow for homeowner payments to contractors or any other suitable PSPs. One, some, or each invoice may be reviewed (e.g., automatically without human intervention by the PESP and/or by any suitable PESP operator) for validity and a match to the original budget for its associated project. Once an invoice has been marked valid by the PESP, the homeowner can initiate a payment through the PESP.

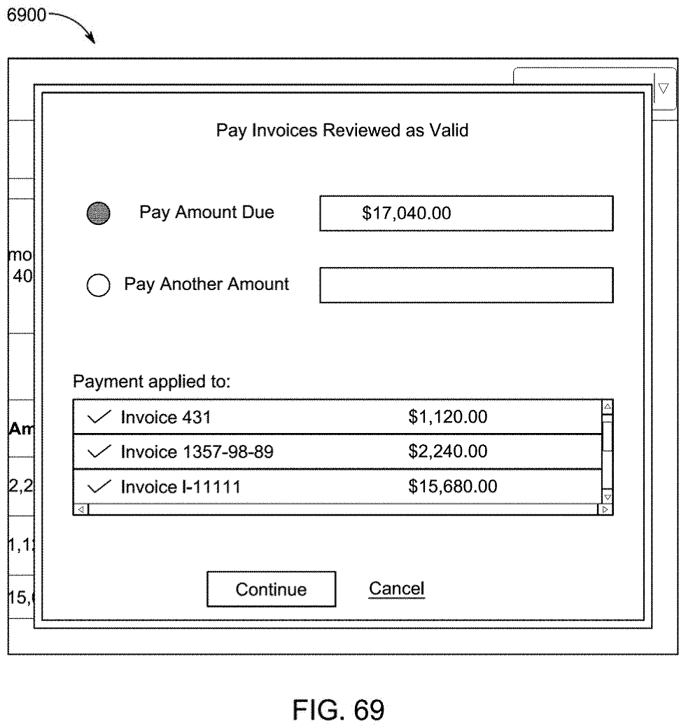

A payment flow for an invoice by a contractor for a homeowner may be configured such that the homeowner may provide payment using the PESP for purchasing from Skylight (or any suitable partner) a certificate or any other suitable entity (e.g., digital or otherwise), which may then be redeemed with the contractor. For example, as shown in FIGS. 68-74, various suitable user interfaces 6800-7400 may be provided by the PESP for carrying out at least a portion of such a payment flow process. As shown in FIG. 68, for example, a screen shot of interface 6800 may enable the PESP to provide a listing of invoices for a particular project and/or for a particular PESP user. Interface 6800 may provide a total of all invoices paid to date, a total of all unpaid invoices, any associated notices, and/or the like for a particular project or generally for a particular user if such a user may be associated with two or more projects. Itemized invoices may include an invoice number, invoice date, amount, review status (e.g., validated by the PESP, etc.), amount paid to date, and current invoice status. Each invoice may be viewed in more detail and/or selected for payment (e.g., through user selection of a “Pay” radio button). Alternatively, any suitable payment may be made for covering any or all of the invoices to be paid (e.g., through user selection of a “Make a Payment” radio button). For example, as shown in FIG. 69, a screen shot of interface 6900 may be provided by the PESP in response to a user selecting the “Make a Payment” radio button of interface 6800, which may enable the user to make a payment for covering a portion or all of one, some, or each unpaid invoice.

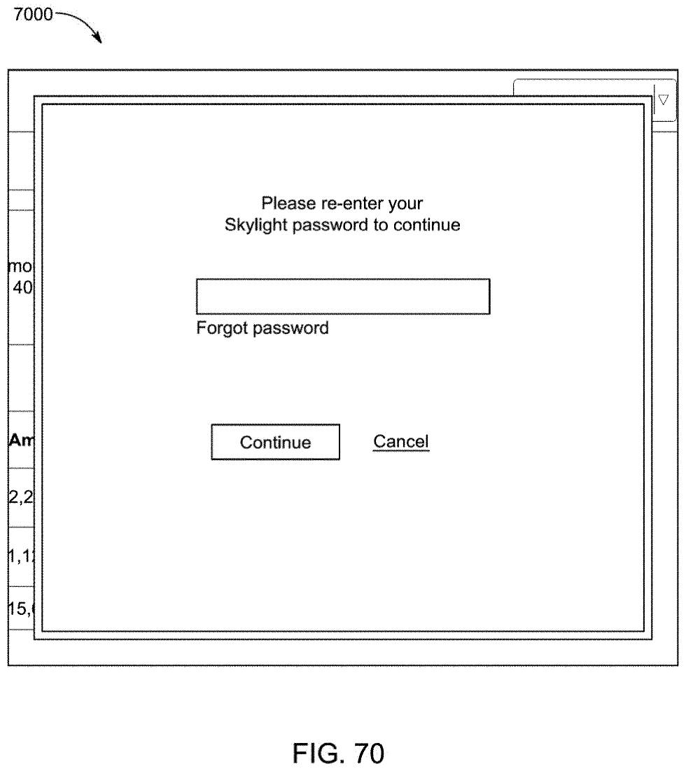

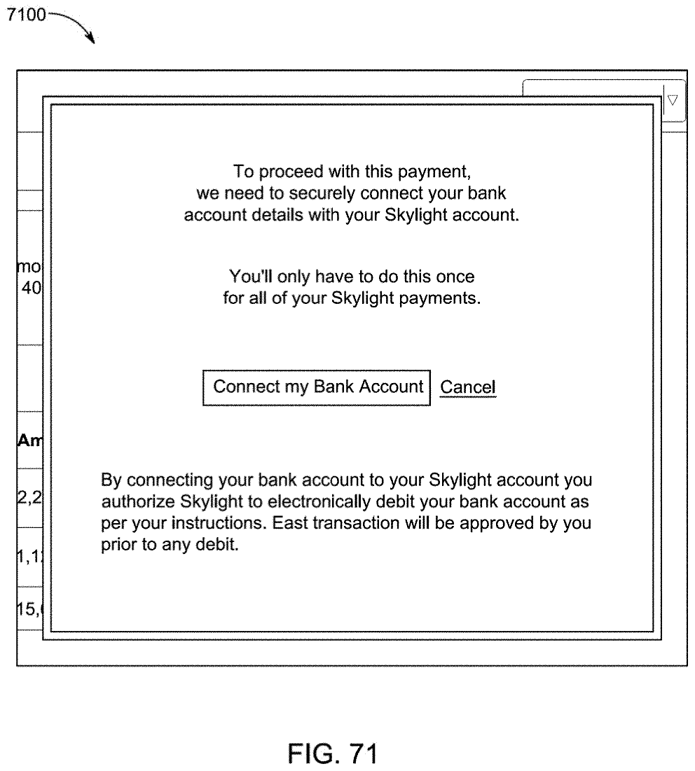

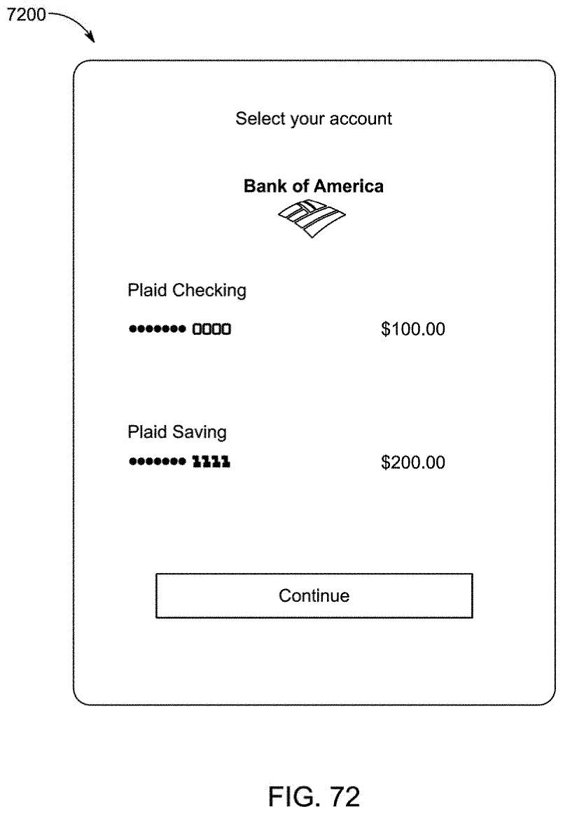

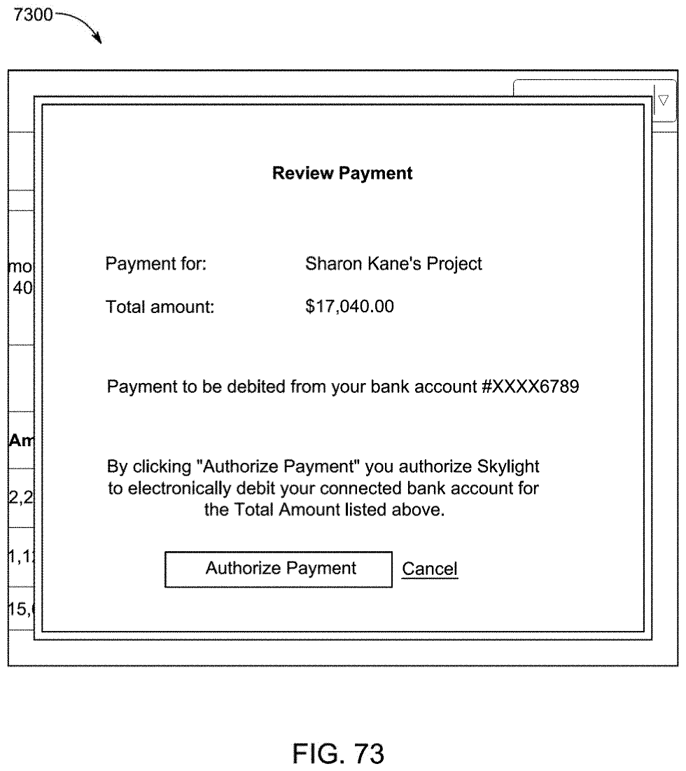

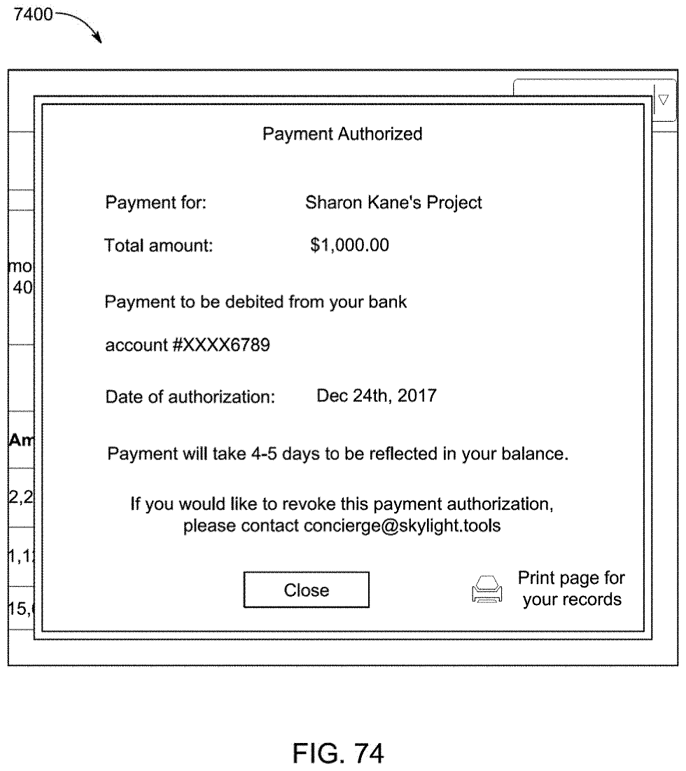

As shown in FIG. 69, interface 6900 may include an opportunity for a user to pay a total amount due or to enter another particular (e.g., lesser) amount to be paid. Moreover, interface 6900 may be configured to enable a user to select one or more pending invoices to which the selected payment amount (e.g., total or a lesser amount) is to be applied, whereby the user may make a payment for an amount X, where, for example, 20% of X may be applied to a first invoice and 80% of X may be applied to a second invoice. Once a user has made any appropriate selections at interface 6900, the user may select a “Continue” radio button, which may cause the PESP to proceed to another suitable interface. For example, as shown in FIG. 70, a screen shot of interface 7000 may be provided by the PESP in response to a user selecting the “Continue” radio button of interface 6900, which may require the user to enter (e.g., re-enter) an authentication credential of the user with the PESP (e.g., re-enter a Skylight password of the user) to enable the user to securely continue with the payment process. Once a user has entered the requested credential(s) at interface 7000, the user may select a “Continue” radio button, which may cause the PESP to proceed to another suitable interface. For example, as shown in FIG. 71, a screen shot of interface 7100 may be provided by the PESP in response to a user selecting the “Continue” radio button of interface 7000, which may request that the user connect any third party banking details or accounts of the user with the PESP, which may only have to be done once by the user for a particular bank or other suitable financial entity (e.g., any suitable third party enabler subsystem (e.g., one of third party enabler subsystems 100j-1001)), such as Bank of America, where such a process may authorize Skylight to debit the user's selected bank account per the amount selected by the user (e.g., at interface 6900). Once a user has agreed to the request to connect at interface 7100, the user may select a “Connect my Bank Account” radio button, which may cause the PESP to proceed to another suitable interface. For example, as shown in FIG. 72, a screen shot of interface 7200 may be provided by the PESP (e.g., using any suitable third party payments provider (e.g., Stripe)) in response to a user selecting the “Connect my Bank Account” radio button of interface 7100, which may enable the user to select and connect the bank account details of its choice. Once a user has chosen any suitable funds account for connection to the PESP at interface 7200, the user may select a “Continue” radio button, which may cause the PESP to proceed to another suitable interface. For example, as shown in FIG. 73, a screen shot of interface 7300 may be provided by the PESP in response to a user selecting the “Continue” radio button of interface 7200, which may enable the user to review and confirm any and all payment details (e.g., amount, funding source, etc.) before the payment process is advanced. Once a user has reviewed and confirmed the payment details at interface 7300, the user may select an “Authorize Payment” radio button, which may cause the PESP to proceed to another suitable interface. For example, as shown in FIG. 74, a screen shot of interface 7400 may be provided by the PESP in response to a user selecting the “Authorize Payment” radio button of interface 7300, which may provide confirmation details of the payment (e.g., name of project, total amount, identity of funding account, date of authorization, etc.). The funds of the payment may be received by a holding fund under control of the PESP or a third party partner thereof, and then the funds may be distributed to the appropriate contractor(s) or any other suitable property service provider(s). Additionally or alternatively, in response to carrying out such a payment, the paying user (or a partner thereof) may receive from the PESP (or a partner thereof) any suitable certificate, which may then be redeemed with the contractor. In the event that a contractor does not perform to any guarantee of Skylight, Skylight may provide the homeowner with a refund (e.g., full or partial, as appropriate) for the purchased certificate. In some embodiments, if a payment covers more than one invoice, different certificates may be issued for respective different paid invoices.

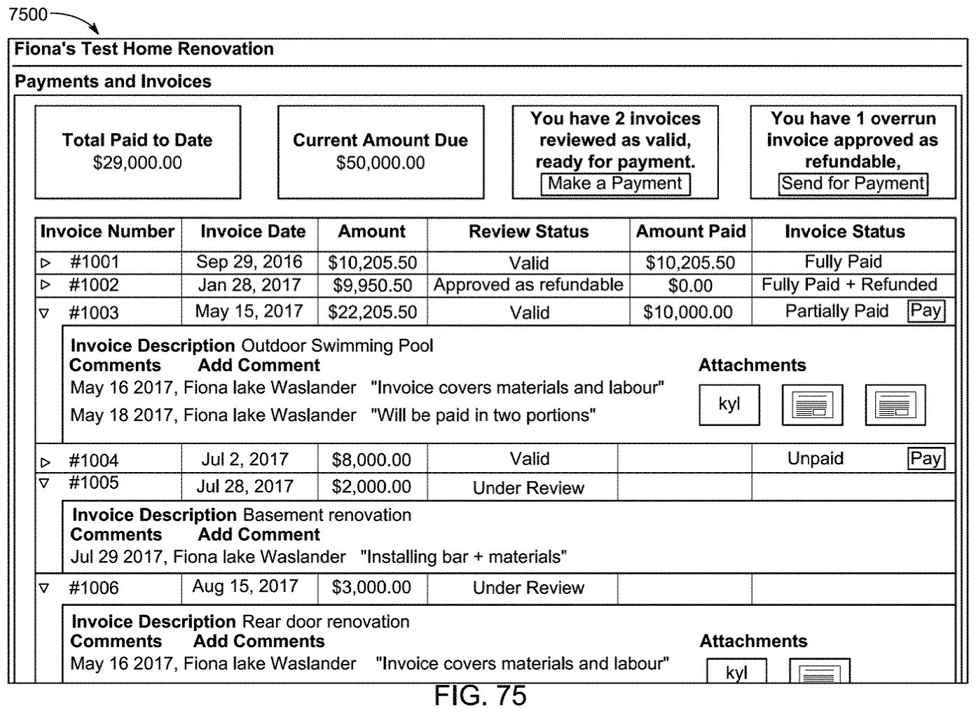

### Description of FIGS. 75-79

While the payment process described above (e.g., with respect to FIGS. 68-74) may be carried out for standard payments, a different payment process may be provided by the PESP that may enable a homeowner to pay for certain type(s) of payments, such as payments for unforeseen site condition (USC) payments. For example, a certain invoice can be flagged by Skylight as an “Unforeseen Site Condition” (USC) invoice (e.g., for a change order invoice for a change order due to one or more unforeseen site conditions, where the different cost that may have required the change order may have been unforeseen by the contractor upon initial scope of the project and it may or may not be the homeowner's responsibility to pay). Therefore, for such an invoice, the homeowner may be due a refund on their payment of that invoice. In such embodiments, Skylight may be operative to cover the cost of the unforeseen site condition cost (e.g., as described herein). As is mentioned in a standard payments flow, homeowners may pay on Skylight by purchasing from Skylight a certificate, which may then be redeemed with the appropriate contractor. In the event that a contractor does not perform to any applicable guarantees of the PESP, Skylight may provide the homeowner with an appropriate refund on the purchased certificate.

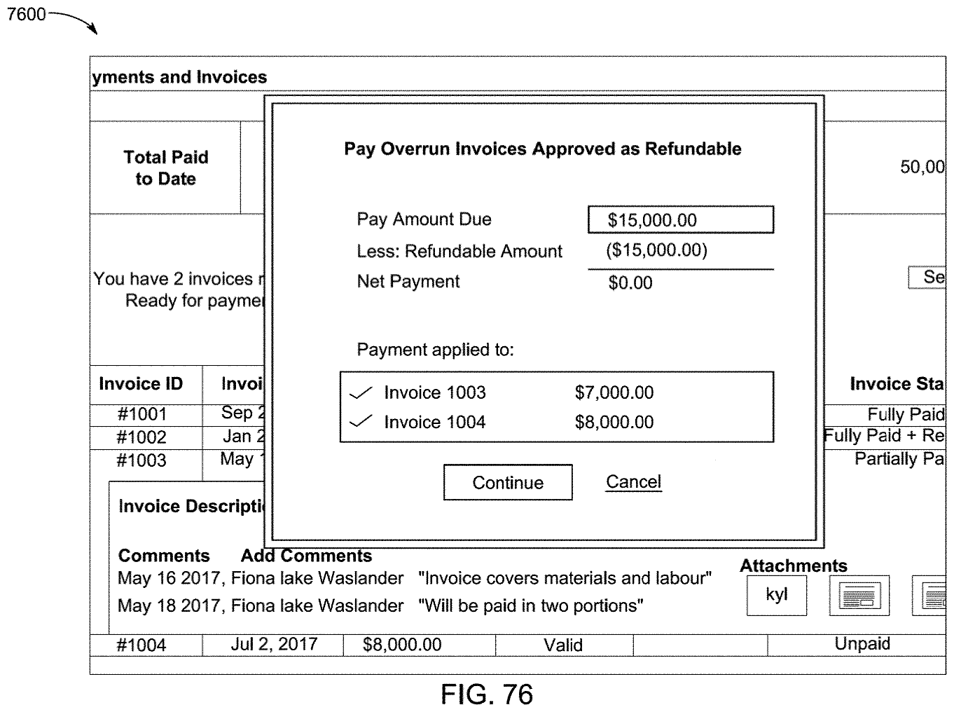

A payment flow for a USC may be configured such that the homeowner may provide payment using the PESP for purchasing from Skylight (or any suitable partner) a certificate or any other suitable entity (e.g., digital or otherwise), which may then be redeemed with the contractor. For example, as shown in FIGS. 75-79, various suitable user interfaces 7500-7900 may be provided by the PESP for carrying out at least a portion of such a payment flow process. Such a flow through the Skylight system may be operative such that a homeowner may verify that certain work has been completed by approving a payment to the contractor, and, when the user may initiate the payment for such work, the user may receive a refund on their purchased certificate. Skylight may pay the contractor for the work completed at the time when the homeowner redeems the certificate. As shown in FIG. 75, for example, a screen shot of interface 7500 may enable the PESP to provide a listing of invoices for a particular project and/or for a particular PESP user, which may be similar to interface 6800 of FIG. 68. Interface 7500 may provide a total of all invoices paid to date, a total of all unpaid invoices, any associated notices, and/or the like for a particular project or generally for a particular user if such a user may be associated with two or more projects. Itemized invoices may include an invoice number, invoice date, amount, review status (e.g., validated by the PESP, approved as refundable, etc.), amount paid to date, and current invoice status. Each invoice may be viewed in more detail and/or selected for payment (e.g., through user selection of a “Pay” radio button) and/or selected for refund. Alternatively, any suitable payment may be made for covering any or all of the invoices to be paid (e.g., through user selection of a “Make a Payment” radio button). Alternatively, any suitable invoice(s) that have been approved as refundable may be identified in order to be sent for payment (e.g., through user selection of a “Send for Payment” radio button). For example, as shown in FIG. 76, a screen shot of interface 7600 may be provided by the PESP in response to a user selecting the “Send for Payment” radio button of interface 7500, which may enable the user homeowner and/or contractor to receive a refund.

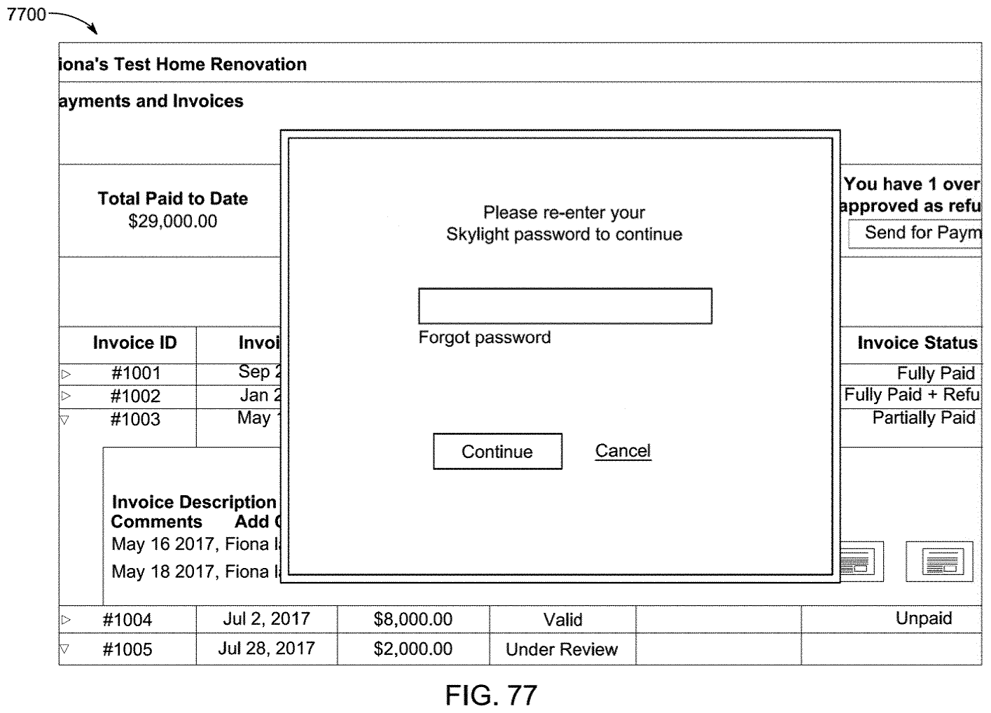

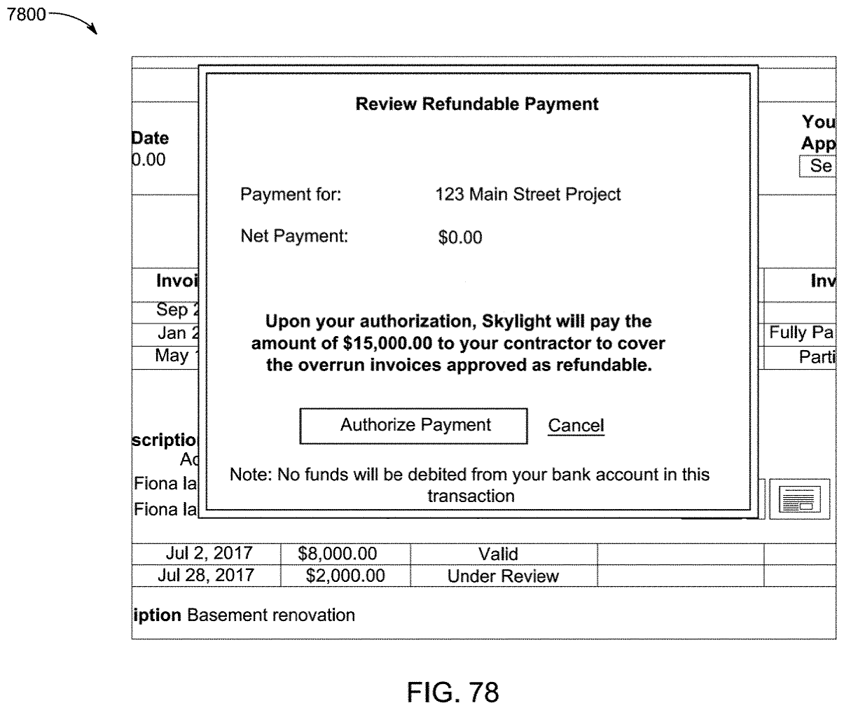

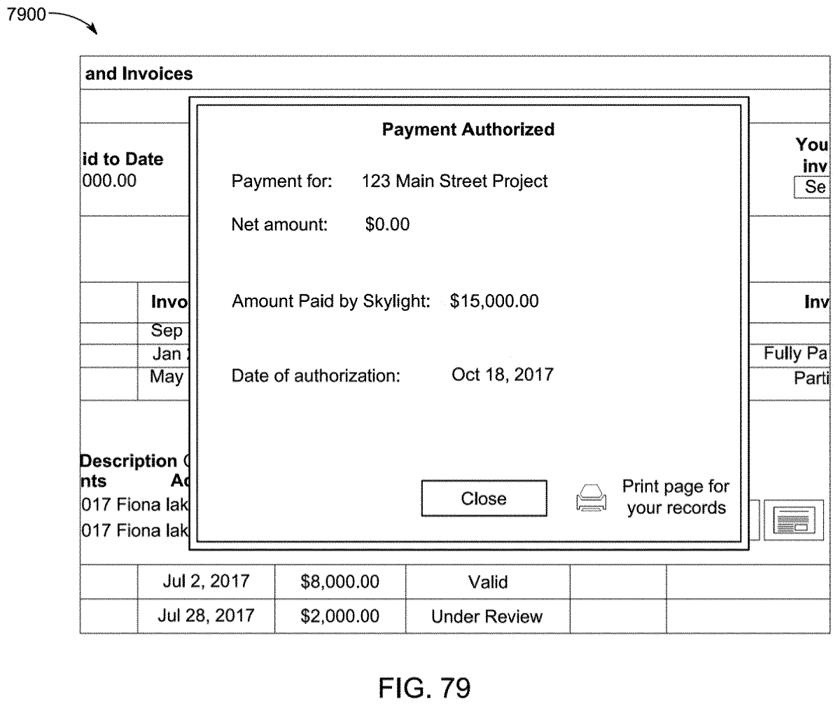

As shown in FIG. 76, interface 7600 may include an opportunity for a user to identify any portion or total of one or more invoices that may have been approved as refundable, such as an original pay amount due and any refundable amount to identify any net payment that may be due from the user or paid to the user. If any refundable amount, interface 7500 may be configured to enable a user to select one or more pending invoices to which the selected refundable amount (e.g., total or a lesser amount) is to be applied, whereby the user may be due a refundable amount Y, where, for example, 20% of Y may be applied to a first invoice and 80% of Y may be applied to a second invoice. Once a user has made any appropriate selections at interface 7600, the user may select a “Continue” radio button, which may cause the PESP to proceed to another suitable interface. For example, as shown in FIG. 77, a screen shot of interface 7700 may be provided by the PESP in response to a user selecting the “Continue” radio button of interface 7600, which may require the user to enter (e.g., re-enter) an authentication credential of the user with the PESP (e.g., re-enter a Skylight password of the user) to enable the user to securely continue with the payment process. Once a user has entered the requested credential(s) at interface 7700, the user may select a “Continue” radio button, which may cause the PESP to proceed to another suitable interface. For example, as shown in FIG. 78, a screen shot of interface 7800 may be provided by the PESP in response to a user selecting the “Continue” radio button of interface 7700, which may enable the user to review and confirm any and all payment details (e.g., project details for which the payment is associated, net payment amount, etc.) before the payment process is advanced, such that Skylight may pay the refundable amount to any suitable contractor(s) to cover any overrun invoices that may have been approved as refundable, while no funds may be debited from the homeowner's bank account for such a payment process. As one example, the PESP may internally record a charge to the homeowner and then a refund to the homeowner, followed by a payment to the contractor. Even though the homeowner does not owe anything or perhaps even ever pay anything during the process, the homeowner may initiate this process. Once a user has reviewed and confirmed the payment details at interface 7800, the user may select an “Authorize Payment” radio button, which may cause the PESP to proceed to another suitable interface. For example, as shown in FIG. 79, a screen shot of interface 7900 may be provided by the PESP in response to a user selecting the “Authorize Payment” radio button of interface 7800, which may provide confirmation details of the payment (e.g., name of project, net payment amount, amount paid by Skylight, date of authorization, etc.). The funds of the payment may be distributed to the appropriate contractor(s) or any other suitable property service provider(s).

### Further Description of FIG. 75

As mentioned, like interface 6800 of FIG. 68, interface 7500 of FIG. 75 may enable the PESP to provide a listing of invoices for a particular project and/or for a particular PESP user. Such an interface may be operative to keep the user (e.g., a homeowner) up to date on all of the relevant invoices, payments, and transactions. A goal of such an interface may be to give the homeowner full visibility into all aspects of their invoices, payments and transactions. The interface may allow for initiation of a payment (e.g., based on amount due), such as described above with respect to FIGS. 69-74 and/or FIGS. 76-79. Many suitable features may be provided by such an interface. For example, as shown in FIG. 75, screen shot of interface 7500 may enable the PESP to provide a listing of invoices for a particular project and/or for a particular PESP user, which may be similar to interface 6800 of FIG. 68. Interface 7500 may provide a total amount of all invoices paid to date, where the total may be calculated based on historical transactions. Additionally or alternatively, interface 7500 may provide a total amount due, where the total may be calculated based on invoices that may be marked valid but that are unpaid. Interface 7500 may provide a list of relevant invoices, where each listed invoice may be identified in any suitable manner, such as by a unique reference number or any suitable other identifier(s). Moreover, each invoice may be presented along with its associated invoice date (e.g., date it was generated or submitted to the PESP). An amount may also be presented for each invoice, which may be the total amount to be paid to cover the invoice, which may also include an appropriate fee(s) due to Skylight. The amount, or other suitable presented element of an invoice, may be clickable to enable additional information relevant to the particular invoice to be presented, such as a detailed breakdown of the fees that are combined to provide the total invoice amount (e.g., as shown with respect to invoices #1003, #1005, and #1006 in FIG. 75). Such additional information may additionally or alternatively include a further description of an invoice. Additionally or alternatively, interface 7500 may enable any suitable user to enter any suitable comments to be associated with an invoice (e.g., to describe certain details). Interface 7500 may enable a user to upload, download, and/or otherwise access any suitable attachments, including a copy of an invoice, receipt, or any other suitable attachments or files for association with the invoice that may detail out the invoice or any other supporting documentation. An invoice status may be provided by interface 7500 for each listed invoice, where such an invoice status may provide any suitable information, such as information indicative of whether or not an invoice has been fully paid, partially paid, is unpaid, whether at least partially refunded or refundable, whether the invoice is still in transit, and/or the like. The status or a portion thereof may be clickable for presenting additional information to the user, such as all historical transactions related to that invoice. A review status may be provided by interface 7500 for each listed invoice, where such a review status may provide any suitable information, such as whether the invoice can be paid based on an assessment of work completed and/or valid charges and/or is at least partially refundable and/or under review and/or the like. Interface 7500 may also present any suitable radio button(s) for enabling a user to pay an invoice or select an invoice for refund or otherwise. Any additional or alternative features may be provided by such a payment page to any suitable user to help a user manage invoices on the PESP.

### Description of FIGS. 80-89

The PESP of PESP system 1 may be operative to help a property manager (e.g., a homeowner) manage a renovation project (e.g., home renovation project or home construction project) and to identify the right contractor for the right job so as to keep the project on budget and on schedule. For example, system 1 may be at least partially configured as a construction analysis services (“CAS”) system for providing a CAS platform (“CASP”), which may be operative as a residential and/or small business (or big business) construction costing, communication, and coordination system. The CASP may be configured to use online automation and communication to coordinate, secure, and analyze data from multiple independent parties to support a design scope and cost iteration process with a homeowner. The CASP may be configured to create a digital language around all aspects of a renovation process to support an optimized digital system. The CASP may be configured to leverage machine learning to improve automation and accuracy over time. A goal of the CASP may be to enable a property manager to design the best renovation or construction within their budget and to lock down scope and plan prior to construction start. Each one of the terms “construction” and “renovation” may be used herein to refer to any project that may include, but is not limited to, a new construction, remodel, addition, or any modification to an existing building or other suitable type of property.

As described with respect to FIGS. 60-66, the PESP may be configured to offer one or more pre-construction services to a property manager, including, but not limited to, homeowner onboarding, automating design workflow, and putting project to bid. The CASP may be configured as a core, overarching platform for one or more of such pre-construction services for a homeowner. The CASP may be configured to be distinct from another core platform, such as one or more of the platforms described herein for supporting one or more in-construction phases of a project (e.g., as may be described with respect to one or more of FIGS. 1-59 and 67-79). The CASP may be configured to be an evolution of the capabilities described with respect to FIGS. 60-66, but may also offer capabilities new and distinct from those capabilities of FIGS. 60-66. The CASP may additionally or alternatively be configured to provide capabilities for any system for putting a project to bid, as also mentioned elsewhere herein. The CASP may be configured to act as a communication and organization system that may be operative automatically to connect all of the project participants (e.g., homeowner or property manager (e.g., of one or more of PM subsystems 100a-100c), designer/architect (e.g., of one or more of PD subsystems 100m-100o), contractor (e.g., of one or more of PSP subsystems 100d-100f), and/or HVAC engineer/structural engineer/MEP engineer/etc. (e.g., of one or more of TPE subsystems 100j-1001)) for ensuring one common digital language and an efficiency in process.

As shown in FIG. 80, a process 8000 may be provided for carrying out construction analysis of the CASP. At operation 8002 or process 8000, a CAS subsystem of the CASP (e.g., subsystem 10) may be operative to accept or otherwise receive any suitable renovation plan (e.g., renovation definition) for any suitable property from any suitable property manager or homeowner in any suitable manner (e.g., through any suitable tool (e.g., an online tool or online service of the CASP (e.g., any suitable applications (e.g., CASP application(s)) of a PM subsystem 100 (e.g., a web application or a native application or a hybrid application that may be at least partially produced by a CAS subsystem (e.g., subsystem 10) for enabling the PM subsystem to interact with an online service of the CAS subsystem (e.g., a service of the CASP))))). The renovation plan may include any suitable description of what the homeowner wants to build, change, or redesign of a home or small business or any other suitable property. The renovation plan may be at least partially defined by one or more renovation objectives for what the property manager would like to achieve in the renovation plan. A tool may be configured to accept input from a CASP administrator (e.g., at subsystem 10) (e.g., as may first be received by the CASP administrator from a property manager (e.g., through an in person conversation)) or from a property manager directly (e.g., at subsystem 10 from one of PM subsystems 100a-100c (e.g., via an online tool user interface that allows a PM to enter the pertinent information that may then be communicated to a CAS subsystem)). A renovation plan with at least one renovation objective may be accepted in a structured form. For example, the CASP may be configured to act as or otherwise provide a structured repository (e.g., as a data structure 19 of subsystem 10) of renovation information and each renovation objective (or each renovation plan with one or more renovation objectives) received from the property manager may be an entry into the repository. A received renovation plan may be communicated from such a structured repository to a property designer through any suitable CASP tool (e.g., via an online tool to a PD subsystem 100) such that the property designer may have the appropriate input in order to create a design for the construction or renovation based on the renovation plan. For example, an exemplary screen shot may be provided by screen shot 8100 of FIG. 81 to show information of an exemplary structured entry of received renovation objectives for a received renovation plan as may be received by the CASP (e.g., at operation 8002) and then provided into a structured repository of the CASP and then communicated to a property designer for the designer's use. For example, screen shot 8100 may be provided on a graphical user interface of any suitable output component of any suitable PD subsystem for communicating information of a renovation plan received by the CASP (e.g., by subsystem 10) to a property designer. Alternatively or additionally, a similar interface to that of screen shot 8100 may be provided on a graphical user interface of any suitable output component of any suitable PM subsystem for communicating information of a renovation plan being defined by a property manager that may be interfacing with the PM subsystem (e.g., for enabling the CASP to receive such a defined renovation plan (e.g., at operation 8002)).

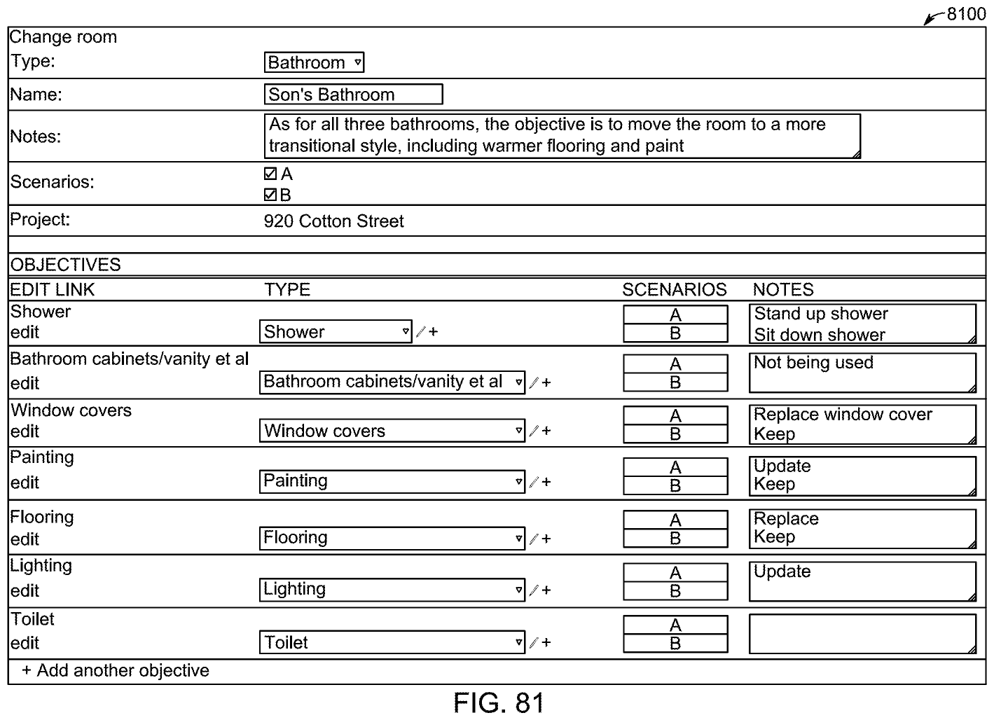

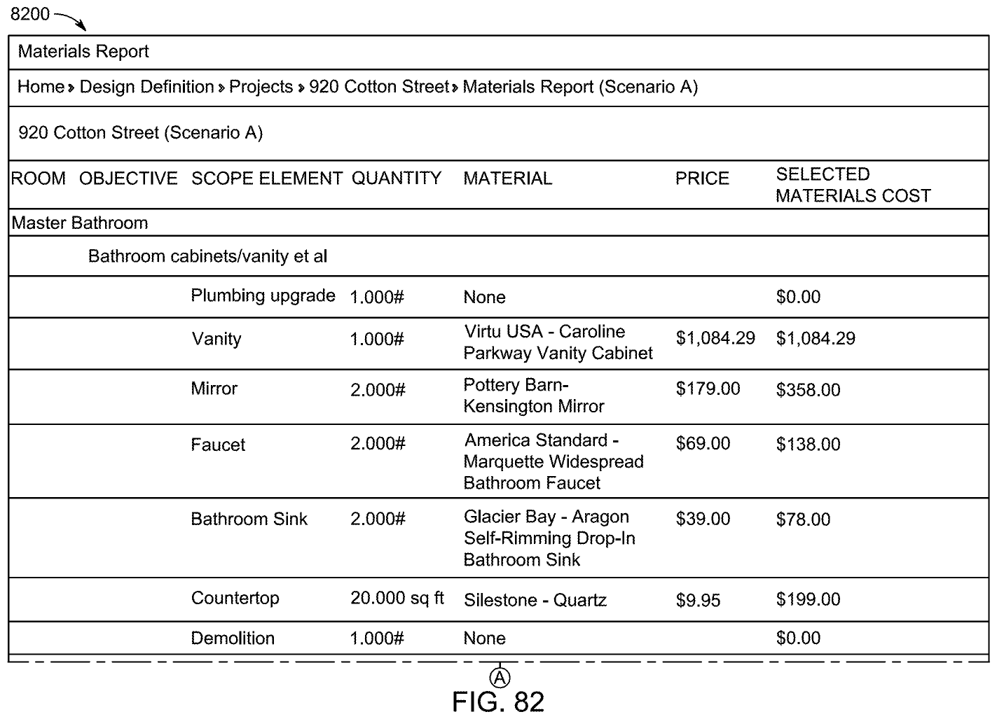

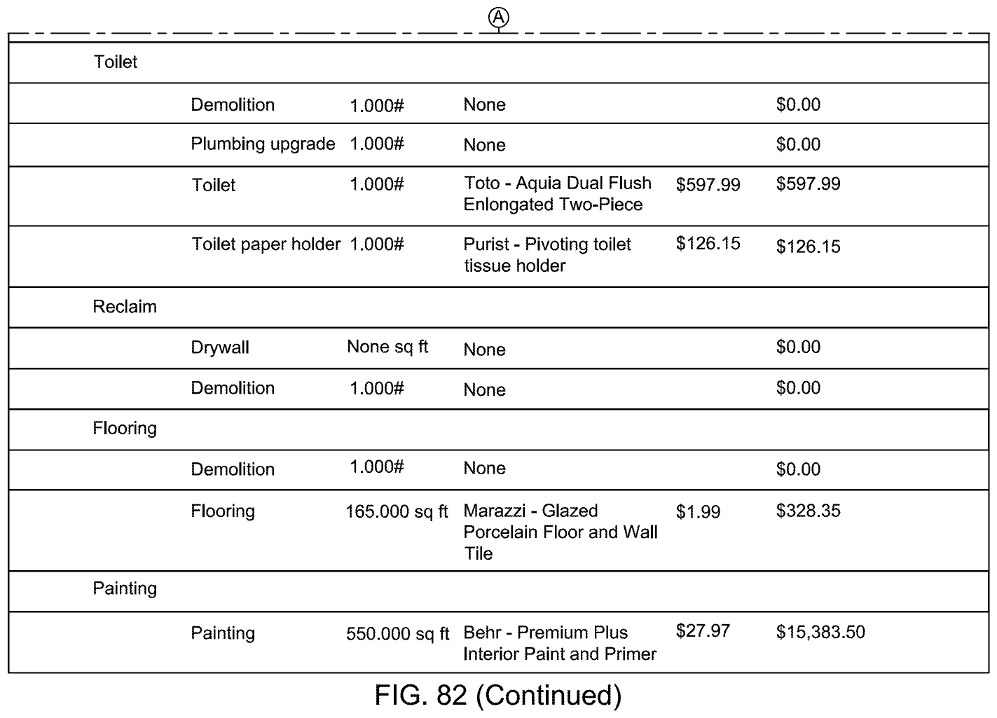

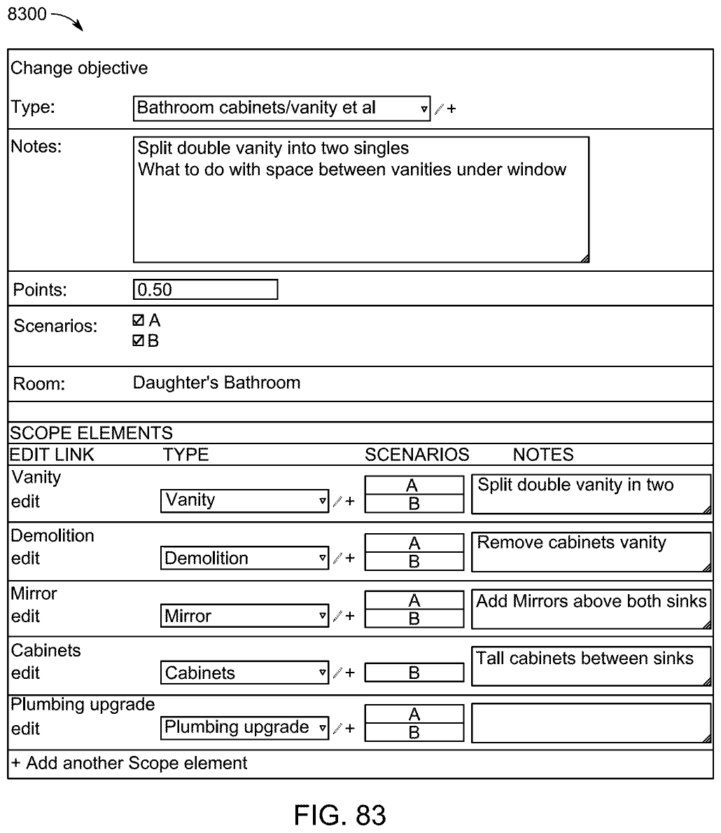

At operation 8004 of process 8000, a CAS subsystem of the CASP (e.g., subsystem 10) may be operative to accept or otherwise receive any suitable number of scope elements from any suitable property designer in any suitable manner for a renovation objective received at operation 8002 (e.g., through any suitable tool (e.g., an online tool or online service of the CASP (e.g., any suitable applications (e.g., CASP application(s)) of a PD subsystem 100 (e.g., a web application or a native application or a hybrid application that may be at least partially produced by a CAS subsystem (e.g., subsystem 10) for enabling the PD subsystem to interact with an online service of the CAS subsystem (e.g., a service of the CASP))))). For example, at operation 8004, by utilizing any suitable information available to the CASP (e.g., any of renovation objective data received by the CASP at operation 8002), a designer may be enabled to develop a vision and plan for the renovation (e.g., offline or online), which may include sketches, floor plans, renderings, and/or the like. With the CASP, as part of their design process, a designer may be enabled to input into the CASP, such as through an online input interface (e.g., using an administrator at subsystem 10 and/or via any suitable designer subsystem of PD subsystems 100m-100o), some or all of the details of the project in a classified structure. This may include a plurality of scope elements for each received renovation objective of a renovation plan. This may list any scope element that is new or has been changed as part of the renovation. For example, as shown by screen shot 8200 of FIG. 82, a set of scope elements may be defined and described (e.g., at operation 8004) for one or more renovation objectives of a bathroom renovation plan, where, for example, a set of scope elements may be listed for one, some, or each renovation objective of a set of renovation objectives of a PM's renovation plan as may be received by the CAS. As part of this operation, there may also be a materials selection module provided by the CASP that may be operative to allow a designer to specify some or all of the material selections for each scope element for the property manager and/or may allow the property manager to review and adjust such materials as applicable. In some or all cases, a designer may be enabled to define the quantity (e.g., number of units) that may be required for each scope element and/or the price that may be associated with each unit. For example, it might be 50 square feet of new wall, or 5 new light switches or 2 sinks or 20,000 square feet of countertop and/or the like. Multiple scenarios of design and material selections may be created for one, some, or each particular renovation objective (e.g., scenarios A and B for each objective of FIGS. 81 and 83 and/or particular scenario A of FIG. 82). For example, multiple scenarios may be created for a particular objective, and different scenarios may include different scope elements (e.g., a first scenario for a particular objective may include a scope element of installing 1,000 square feet of quartz countertop while a second scenario for the same particular objective may instead include a scope element of installing 800 square feet of granite countertop). Screen shot 8200 of FIG. 82 may show an illustrative materials selection report for a particular scenario of a particular objective. Screen shot 8300 of FIG. 83 may show an illustrative scope element entry interface for enabling a designer to enter and/or adjust any scope elements for a particular objective for the CASP. Therefore, the CASP may be operative to provide any suitable platform interface (e.g., an interface that may be operative to provide one or more of screen shots 8100-8300) for any suitable PD subsystem to enable any suitable PD to define any suitable scope elements for any suitable renovation objective.

At operation 8005 of process 8000, a CAS subsystem of the CASP (e.g., subsystem 10) may be operative to accept or otherwise receive any suitable feedback for any suitable scope elements (e.g., as received at operation 8004) from any suitable third party enabler (e.g., through any suitable tool (e.g., an online tool or online service of the CASP (e.g., any suitable applications (e.g., CASP application(s)) of a TPE subsystem 100 (e.g., a web application or a native application or a hybrid application that may be at least partially produced by a CAS subsystem (e.g., subsystem 10) for enabling the TPE subsystem to interact with an online service of the CAS subsystem (e.g., a service of the CASP))))). For example, at operation 8005, the CASP may be operative to enable third party specialist review (e.g., through any suitable tool(s) (e.g., an online tool)). For example, at operation 8005, depending on the renovation type, the CASP may be operative to enable one or more appropriate reviews by one or more third party specialists on the design of the renovation. The CASP may (e.g., automatically) facilitate communication of the renovation details to one or more appropriate third parties (e.g., via an administrator of subsystem 10 and/or via one or more of TPE subsystems 100j-1001) and may manage the communication and incorporation of the third party feedback.

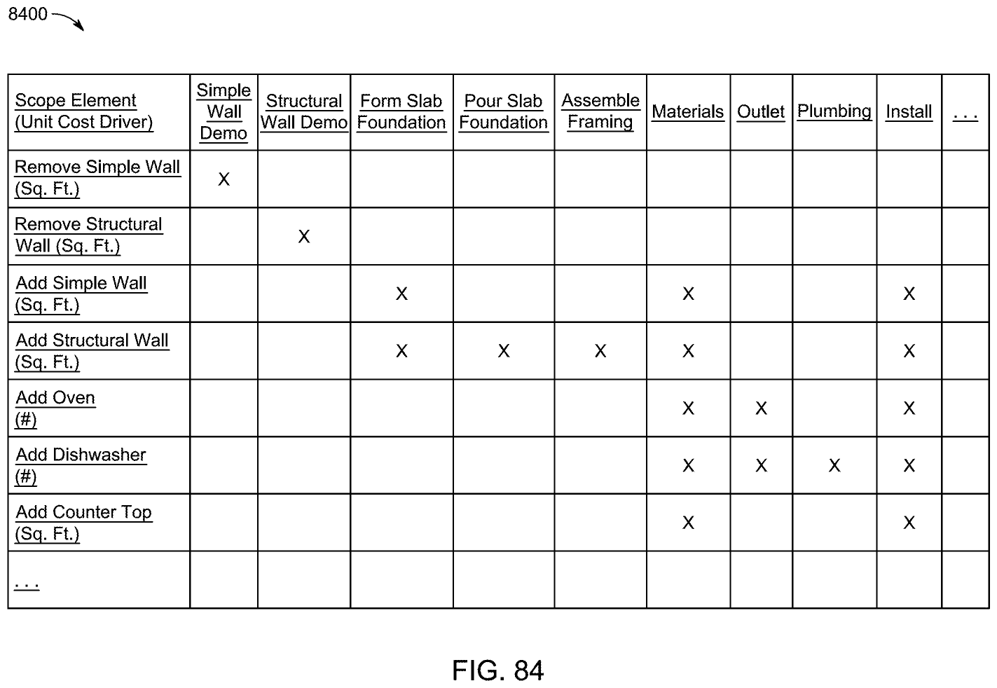

At operation 8006 of process 8000, a CAS subsystem of the CASP (e.g., subsystem 10) may be operative to automatically translate each scope element of the received scope elements (e.g., as received at operation 8004 for a renovation objective received at operation 8002) into at least one type of construction activity in any suitable manner using any suitable tools (e.g., using any suitable algorithm(s) and/or automated neural networks and/or the like (e.g., of any suitable data structure(s) 19)). For example, at operation 8006, the CASP may be operative to automate the translation of the design, as defined by the designer (e.g., at operation 8004), into the one or more activities that may be applicable to a contractor. A received renovation plan or project ought to be translated into “contractor language” so that a contractor may be able to apply costing and schedule planning (e.g., following phases). For example, a designer may indicate (e.g., to the CASP at operation 8004) that a scope element of a renovation objective (e.g., as received by the CASP at operation 8002) is that a new wall is to be added in a room and, to a contractor, this may be translated (e.g., automatically by the CASP at operation 8006) to three (3) construction activities: (i) build wall frame, (ii) apply drywall, and (iii) paint. The activities may incorporate information about labor and materials requirements. The CASP may be configured to ingest the designer designed scope elements for a renovation objective and, using a set of CASP pre-constructed algorithms, automatically output appropriate construction activity information. Initially, there may be manual intervention to tune such translation so that its results are accurate. The CASP may be configured to use any suitable automated machine learning to interpret the tuning and improve the results over time by feeding back the machine learning intelligence into the algorithm(s) (e.g., using any suitable neural network(s) or neuronal network(s) or artificial neural network(s) or any suitable artificial intelligence, machine learning, and or computer algorithm(s) that may be available to the CASP, such as any suitable model(s) (e.g., a computational model). An example of such translation may be illustrated by a data structure representation map 8400 of FIG. 84. For example, as shown, the CASP may be configured to automatically translate a scope element of “remove simple wall” with a unit cost driver of “square feet” into at least one type of construction activity, such as a “simple wall demolition” type of construction activity. As another example, as shown, the CASP may be configured to automatically translate a scope element of “add simple wall” with a unit cost driver of “square feet” into any suitable number of types of construction activity, such as a “slab foundation formation” type of construction activity and a “materials procurement” type of construction activity and an “installation” type of construction activity. As yet another example, as shown, the CASP may be configured to automatically translate a scope element of “add structural wall” with a unit cost driver of “square feet” into any suitable number of types of construction activity, such as a “slab foundation formation” type of construction activity and a “slab foundation pour” type of construction activity and a “framing assembly” type of construction activity a “materials procurement” type of construction activity and an “installation” type of construction activity. This may enable the CASP to provide an online system for PM renovations that enables an automated process for automatically interpreting scope elements of a renovation design for a renovation objective and automatically translating the interpreted scope elements into construction activities for one or more contractors.

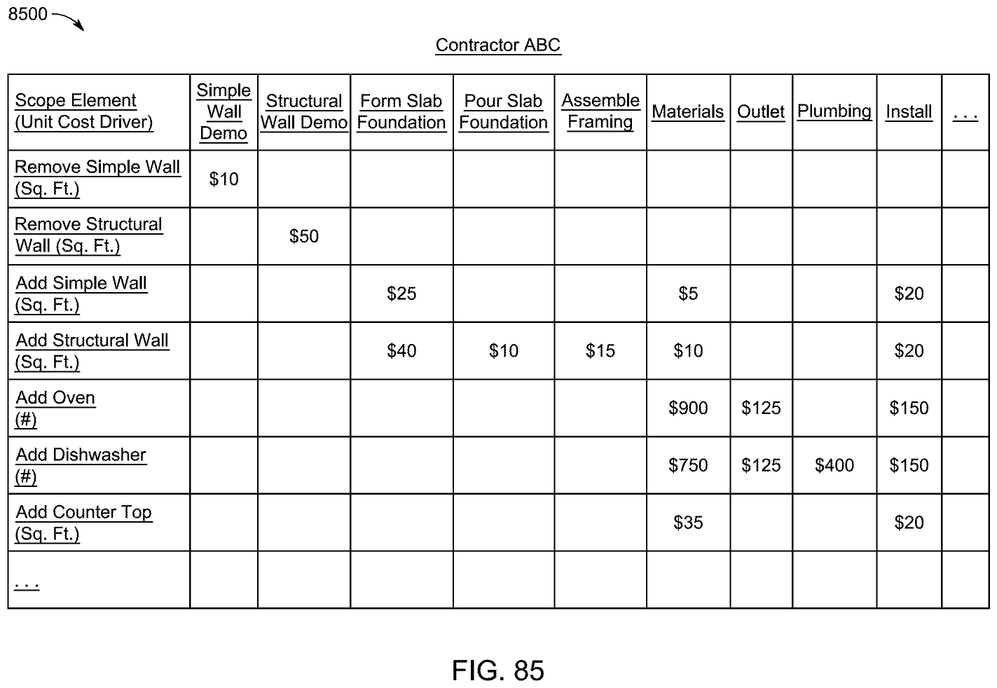

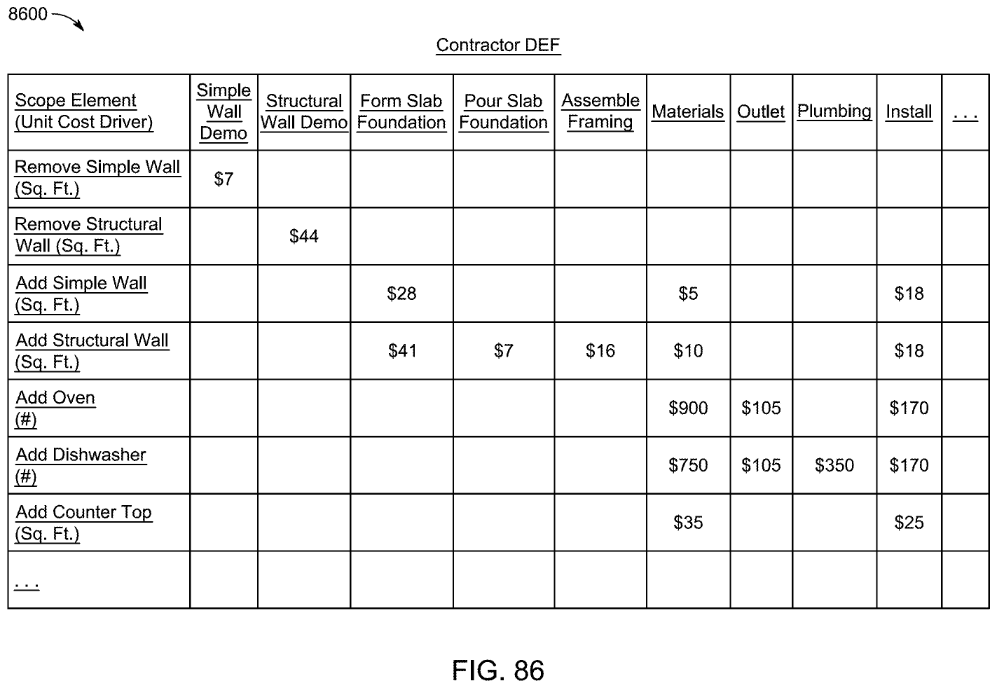

At operation 8008 of process 8000, a CAS subsystem of the CASP (e.g., subsystem 10) may be operative to accept or otherwise receive any suitable types of work information from at least one suitable property service provider (e.g., contractor) for various construction activity types in any suitable manner (e.g., through any suitable tool (e.g., an online tool or online service of the CASP (e.g., any suitable applications (e.g., CASP application(s)) of a PSP subsystem 100 (e.g., a web application or a native application or a hybrid application that may be at least partially produced by a CAS subsystem (e.g., subsystem 10) for enabling the PSP subsystem to interact with an online service of the CAS subsystem (e.g., a service of the CASP))))). Such received work information may be received at operation 8008 for one, some, or each of the at least one type of construction activity of the translation of operation 8006 for each received scope element of operation 8004 for a received renovation objective of operation 8002, however, such work information may be received at operation 8008 prior to one, some, or each of operations 8002, 8004, and 8006. Alternatively, such work information may be received at operation 8008 in response to operation 8006. For example, at operation 8004, the CASP may be operative to enable at least one contractor to maintain a cost type of work information and/or a schedule type of work information for each construction activity (e.g., through any suitable tool(s) (e.g., an online tool)). For example, at operation 8004, the CASP may be operative to enable one or more contractors to maintain data/knowledge of costs and/or timeline schedules by construction activity. This work information may generally be generic across projects. For example, for a particular contractor, the cost to install a particular type drywall per square foot may be generally stable for all renovation plans. The CASP may be configured to allow a contractor to provide its specific costs and schedule amounts by construction activity. The contractor may be enabled to input such cost and schedule work information through any suitable (e.g., secure) interface with the CASP with simple inputs to allow for quick entry (e.g., via an administrator at subsystem 10 and/or via any suitable one or more of PSP subsystems 100d-100f). In some embodiments, the cost and schedule work information for a particular contractor may not be shared by the CASP with any other contractor. For example, a data structure framework 8500 of FIG. 85 may illustrate exemplary cost work information for a first contractor (i.e., contractor ABC) for various scope elements as may be received at operation 8008, while a data structure framework 8600 of FIG. 86 may illustrate exemplary cost work information for a second contractor (i.e., contractor DEF) for various scope elements as may be received at operation 8008. For example, as shown, the CASP may be configured to receive from a first contractor ABC for a scope element of “add simple wall” with a unit cost driver of “square feet” particular cost work information of data structure framework 8500 that may be indicative of “$25 per square foot” for the “slab foundation formation” type of construction activity and of “$5 per square foot” for the “materials procurement” type of construction activity and of “$20 per square foot” for the “installation” type of construction activity, while the CASP may be configured to receive from a second contractor DEF for a scope element of “add simple wall” with a unit cost driver of “square feet” particular cost work information of data structure framework 8600 that may be indicative of “$28 per square foot” for the “slab foundation formation” type of construction activity and of “$5 per square foot” for the “materials procurement” type of construction activity and of “$18 per square foot” for the “installation” type of construction activity. It is to be noted that each one of frameworks 8500 and 8600 may just illustrate cost work information for various construction activities (e.g., of various scope elements), but schedule work information may be included additionally or alternatively (e.g., schedule work information indicative of the amount of time (e.g., per square foot) that the contractor may require (e.g., estimate requiring) for carrying out a particular construction activity, as opposed to cost work information indicative of the amount of money (e.g., per square foot) that the contractor may require (e.g., estimate requiring) for carrying out a particular construction activity). The CASP may be operative to receive cost and/or schedule work information from one or more contractors for one or more construction activities at operation 8008 before one or more of operations 8002, 8004, and 8006 (e.g., before a PM defines any particular renovation objectives, before a PD translates any such renovation objectives into any particular scope elements, and/or before the CASP translates any such scope elements into any particular construction activities).

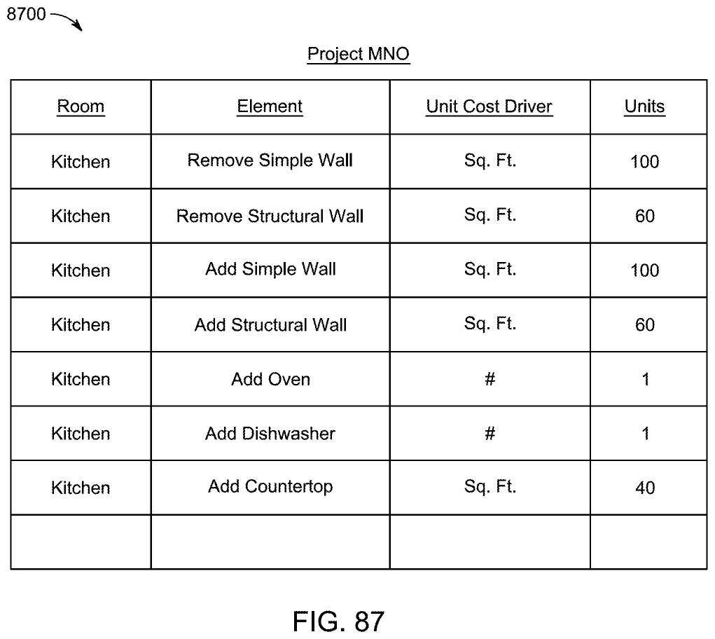

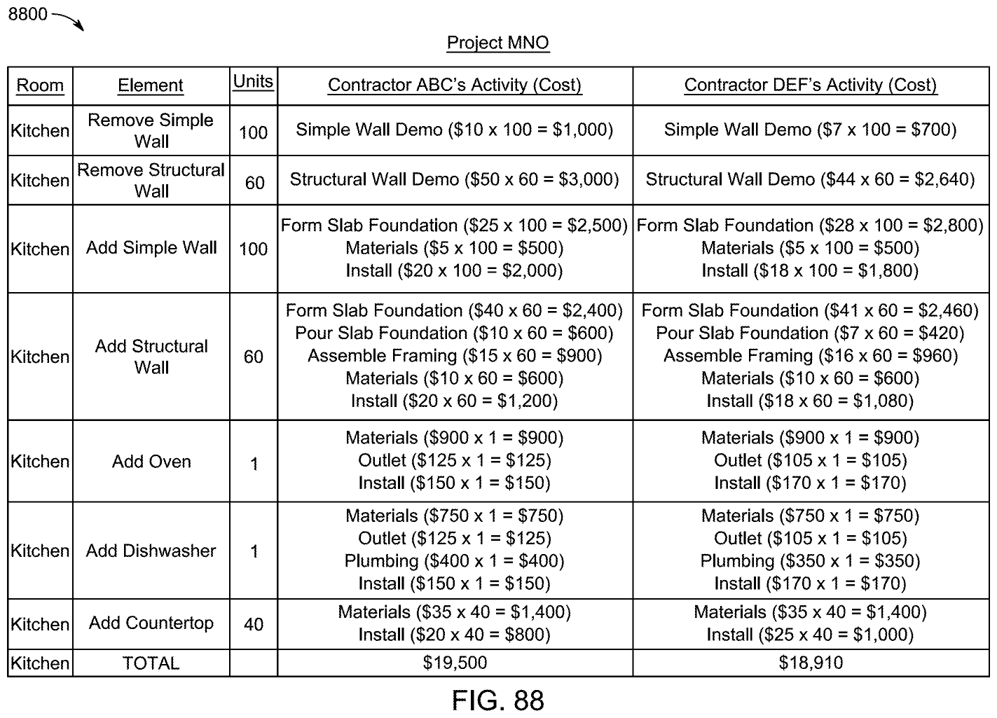

At operation 8010 of process 8000, a CAS subsystem of the CASP (e.g., subsystem 10) may be operative to automatically determine, based on the received work information (e.g., as received at operation 8008), a work amount that may be required by at least one property service provider for the received scope elements (e.g., as received at operation 8004) for the received renovation objective (e.g., as received at operation 8002) in any suitable manner using any suitable tools (e.g., using any suitable algorithm(s) and/or automated neural networks and/or the like (e.g., of any suitable data structure(s) 19)). For example, the CASP may be configured to include any suitable cost and/or schedule calculation engine(s) to calculate a particular contractor's cost and/or schedule (e.g., cost work amount and/or schedule work amount) for a particular renovation objective with particular scope elements, such as by using the contractor work information as may be received by the CASP (e.g., at operation 8008) and the amounts of the construction activities as may be automatically translated by the CASP from the scope elements of the objective (e.g., at operation 8006). Such an engine may be configured to incorporate any suitable set(s) of calculation rules to apply fixed and/or variable pricing and/or scheduling concepts to the overall price and/or schedule calculation. Initially, the results of the engine may be manually tuned by an appropriate contractor (e.g., at operation 8013) to make sure the final costs and/or schedules are accurate, but, over time, such tuning information may be accessible to the CASP such that, through any suitable machine learning, the results may be improved over time so that operation 8010 may be fully automated. For example, very basic calculations (e.g., of operation 8010) may be shown through use of exemplary data structure framework 8700 of FIG. 87 and exemplary data structure framework 8800 of FIG. 88 for determining an exemplary cost calculation (e.g., cost work amount) for each one of contractors ABC and DEF for all scope elements of a renovation objective (e.g., kitchen renovation) of a project MNO (e.g., to indicate that contractor DEF may be able to accomplish the kitchen renovation objective for a cost work amount of $590.00 less than contractor ABC). Similar frameworks may be provided for calculating scheduling work amounts (e.g., the length of time it may take each contractor to accomplish the kitchen renovation objective).

At operation 8012 of process 8000, a CAS subsystem of the CASP (e.g., subsystem 10) may be operative to present the determined work amount(s) (e.g., as determined for one or more contractors at operation 8010) to a property manager (e.g., via a PM subsystem 100 as may have been used by the CASP to receive the renovation objective from a property manager at operation 8002) and/or to a property designer (e.g., via a PD subsystem 100 as may have been used by the CASP to receive the scope elements from a property designer at operation 8004) and/or to at least one property service provider (e.g., via a PSP subsystem 100 as may have been used by the CASP to receive the work information from a property service provider at operation 8008). For example, a property manager may utilize such determined work amounts to make a decision as to which contractor to use and/or as to what scenario of scope elements to proceed with.

The CASP may be operative to iterate design and scope (e.g., through any suitable tool(s) (e.g., an online tool)) one or more operations of process 8000. For example, the CASP may be operative to enable the work amount calculations described above to be applied to multiple scenarios for one particular renovation objective (e.g., scenarios A and B of FIGS. 81-83) so a homeowner can get an accurate view of cost/value trade-offs on various design decisions for their renovation. The CASP may enable the communication of the cost/value trade-offs between the project participants in an automated, scalable way. Process 8000 may be configured such that a designer may be enabled by the CASP to present multiple options (e.g., scenarios) to the homeowner and have the cost/schedule analyzed quickly so that the design and the scope can be iterated quickly (e.g., substantially immediately at operation 8010)). The process could even go through the design/scope-translation-cost/schedule process multiple times at a very low cost and at a very high speed for various scenarios (e.g., different scenarios) by various contractors.

Additionally or alternatively, a contractor may utilize such determined work amounts, such as a work amount for that particular contractor such that that contractor may potentially update any work information that may have been used to make such a work amount determination. For example, at operation 8013 of process 8000, a CAS subsystem of the CASP (e.g., subsystem 10) may be operative to accept or otherwise receive any suitable types of adjusted work information from at least one suitable property service provider (e.g., contractor) for various construction activity types in any suitable manner (e.g., through any suitable tool (e.g., an online tool or online service of the CASP (e.g., any suitable applications (e.g., CASP application(s)) of a PSP subsystem 100 (e.g., a web application or a native application or a hybrid application that may be at least partially produced by a CAS subsystem (e.g., subsystem 10) for enabling the PSP subsystem to interact with an online service of the CAS subsystem (e.g., a service of the CASP))))). Such received adjusted work information may be received at operation 8013 for one, some, or each of the at least one type of construction activity of the determination of operation 8010 in order to allow the contractor to adjust one or more of its work information elements to be more particularly tailored to the renovation objective at issue and/or to become more competitive, and operation 8010 may be repeated based on such adjusted work information.

Additionally or alternatively (e.g., at operation 8013 of process 8000 or otherwise), the CASP may be operative to enable bidding by one or more contractors (e.g., through any suitable tool(s) (e.g., an online tool)). For example, although the cost and schedule analysis in the CASP may be configured to initially run (e.g., at operation 8010) off non-project specific cost/schedule work information received from contractors (e.g., at operation 8008) to drive cost/schedule calculations, the CASP may be opened up to contractors on a renovation-specific basis to input/adjust their cost or schedule work information and submit their offer in a competitive bidding environment. For example, the CASP may be configured to provide any suitable (e.g., secure) interface where a contractor may log in and access all of the renovation information for a particular renovation. Each contractor may have a view of the renovation with their generic cost/schedule information applied to the renovation (e.g., information that may be initially received at operation 8008 and used at a first iteration of operation 8010) and an opportunity to adjust such information for the particular renovation at issue. If the CASP does not already have cost/schedule information from the contractor, it could be inputted directly by the contractor at this point and saved for future use. The contractor may be enabled by the CASP to make adjustments to any of its costs or schedule work information to make it more or less competitive for a particular project. The contractor may thus be able to determine the resulting total cost/schedule of its bid for the renovation.

It is understood that the operations shown in process 8000 of FIG. 80 are only illustrative and that existing operations may be modified or omitted, additional operations may be added, and the order of certain operations may be altered.

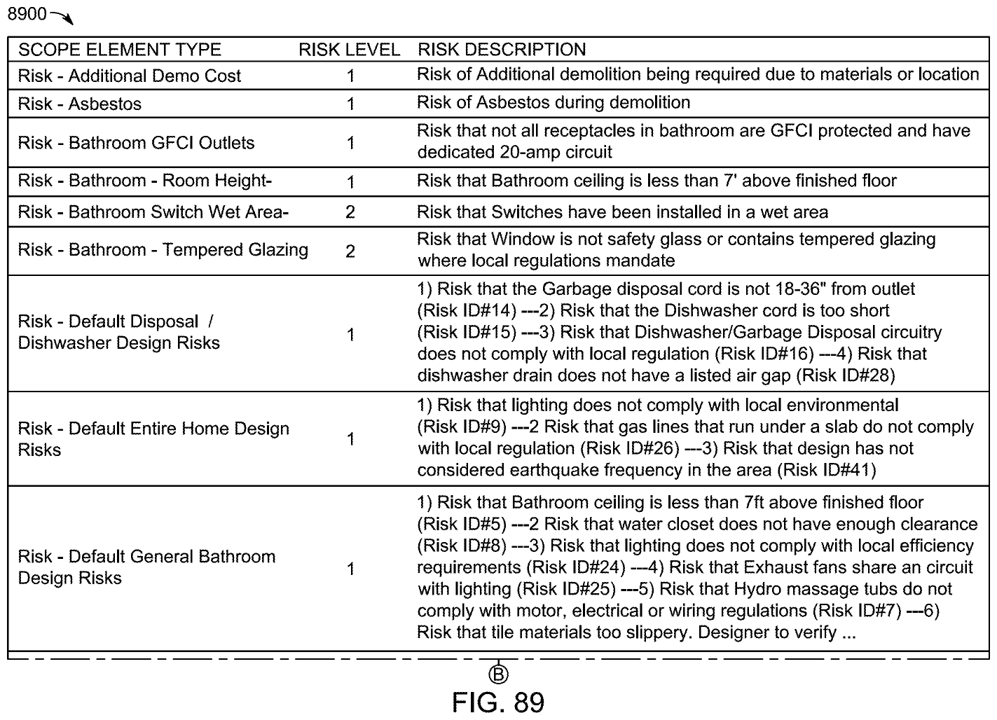

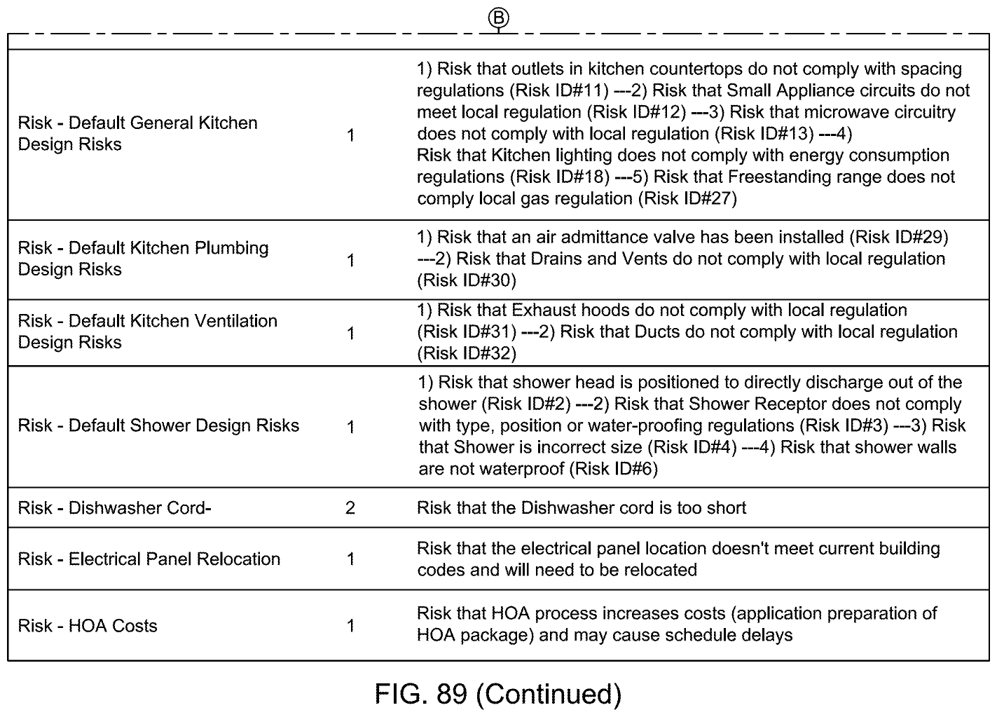

In some embodiments, the CASP may generate or otherwise access a catalog (e.g., a data structure 19 of subsystem 10 or of a TPE subsystem or the like) of potential risks on a renovation objective (e.g., an objective as received at operation 8002) and where those risks would likely occur for the objective (e.g., on what scope element(s) of the objective as received at operation 8004). An illustrative example of at least a portion of exemplary data of such a catalog may be shown by an exemplary data structure framework 8900 of FIG. 89, which may include a risk level and a risk description for various scope element types. A risk may be defined as something that could go wrong on a project if it were not specifically addressed, or investigated, or considered in the planning phase of a renovation. Machine learning or any other procedures may be used by the CASP so that risks can automatically be applied to projects based on their characteristics. Once a risk is applied to a project, the operations of the CASP may be configured to ensure that a consideration for that risk is included in the construction plan and/or the construction cost for that project (e.g., at operation 8010). By considering these items in advance, the probability of a project going over budget or over schedule may be greatly reduced.

Therefore, in some embodiments, the CASP may be configured to provide a method of tracking and monitoring a renovation project, through the construction phase, across budget and schedule, in an automated framework. Additionally or alternatively, once a particular contractor and scenario have been selected for carrying out a particular renovation objective for a property, the CASP may be configured to facilitate gathering actual construction results of budget and schedule for the renovation and may be able to compare such results to the predictions (e.g., the determination of operation 8010). This may allow the CASP to build a forecasting model using any suitable machine learning to predict outcomes of renovations before they start. Additionally or alternatively, the CASP may be configured to analyze contractor inputted costs to generate intelligence about construction costs by geography so that the CASP may be operative to do cost predictions for a certain renovation design, without having to get cost data inputted by a contractor (e.g., rather than receiving work information at operation 8008 from particular contractors geographically local to the property of the renovation objective at issue, the CASP may predict such work information at operation 8008, where actual contractors may then review and potentially adjust at operation 8013 any determinations made at operation 8010 using such predicted work information. Intelligence may be generated based on any suitable learning of data inputted by contractors in the past and/or any trends in costs or schedules that may be seen in that geography or other geographies for certain activities.

The logic of the CASP may be able to determine both a scope element (e.g., add a simple wall) and a dimension unit cost driver that may drive the cost of the scope element (e.g., square feet of simple wall) (e.g., the what) as well as both a set of construction activities for the scope element (e.g., form slab foundation, materials, install) and a contractor cost per construction activity (e.g., $25 per square foot for slab foundation formation, $5 per square foot for materials, $20 per square foot for installation) (e.g., the how). For all projects, a general model of relationship between scope elements and construction activities may be determined (e.g., form slab foundation for a new simple wall (see, e.g., FIG. 84)) and contractor unit costs may be established for each construction activity for each contractor (e.g., $25 per square foot of simple wall for contractor ABC and $28 per square foot of simple wall for contractor DEF (see, e.g., FIGS. 85 and 86)), while, for a specific project, an aggregate construction activity by type may be determined using a scope element (e.g., 100 square foot wall is 100 square feet of adding simple wall for each construction activity of that scope element (see, e.g., FIG. 87)) and aggregate user construction activity for a project and unit costs per contractor may be used to calculate cost per contractor per project (e.g., $25 per square foot for 100 square feet of slab foundation formation is $2,500 for contractor ABC and $28 per square foot for 100 square feet of slab foundation formation is $2,800 for contractor DEF, etc. (see, e.g., FIG. 88)). Therefore, the CASP may be operative to give contractors a scope element list, to give contractors a model of construction activity, and/or to allow contractors to enter unit costs or time work information to calculate overall cost or schedule, such that the CASP may be in synch with contractors to identify lower contractor work for a lower price and/or shorter time, to identify lower contractor risk for a lower price, and/or to identify comparable bids for better competition.

Therefore, a CASP may provide a system for residential and commercial construction costing and scheduling, communication, and project coordination. The system may provide an online automation and communication system to coordinate, secure, and analyze data from multiple independent parties to support a design scope and cost iteration process with a customer, with a structured renovation definition functionality. The CASP may be configured to cultivate a digital language around all aspects of the renovation process to support an optimized digital delivery of a construction plan. A translation engine of the CASP may be configured to translate a project scope into construction activities, expected costs, and schedule. The CASP may enable a customer to design a renovation that may be an optimization of its desired scope and budget constraints using cost/value trade-off functionality on various design scenarios. A bidding system may be provided where contractors can bid on renovations based on their actual costs and schedules and mark-ups applied to a specific construction scope. A risk prediction system may be provided to apply to a renovation project, pre-construction, to predict and avoid budget and schedule overruns.

### Further Description of FIGS. 1-89

One, some, or all of the processes described with respect to FIGS. 1-89 may each be implemented by software, but may also be implemented in hardware, firmware, or any combination of software, hardware, and firmware. Instructions for performing these processes may also be embodied as machine- or computer-readable code recorded on a machine- or computer-readable medium. In some embodiments, the computer-readable medium may be a non-transitory computer-readable medium. Examples of such a non-transitory computer-readable medium include but are not limited to a read-only memory, a random-access memory, a flash memory, a CD-ROM, a DVD, a magnetic tape, a removable memory card, and a data storage device (e.g., memory 13 and/or data structure 19 of FIG. 1 and/or memory 113 and/or data structure 119 of FIG. 2). In other embodiments, the computer-readable medium may be a transitory computer-readable medium. In such embodiments, the transitory computer-readable medium can be distributed over network-coupled computer systems so that the computer-readable code may be stored and executed in a distributed fashion. For example, such a transitory computer-readable medium may be communicated from a PES subsystem 10 to a subsystem 100, from a subsystem 100 to PES subsystem 10, and/or from one subsystem 100 to another subsystem 100 using any suitable communications protocol (e.g., the computer-readable medium may be communicated to a subsystem 100 via communications component 14/114 (e.g., as at least a portion of a data structure 119)). Such a transitory computer-readable medium may embody computer-readable code, instructions, data structures, program modules, or other data in a modulated data signal, such as a carrier wave or other transport mechanism, and may include any information delivery media. A modulated data signal may be a signal that has one or more of its characteristics set or changed in such a manner as to encode information in the signal.

It is to be understood that any, each, or at least one module or component or subsystem of the disclosure may be provided as a software construct, firmware construct, one or more hardware components, or a combination thereof. For example, any, each, or at least one module or component or subsystem of system 1 may be described in the general context of computer-executable instructions, such as program modules, that may be executed by one or more computers or other devices. Generally, a program module may include one or more routines, programs, objects, components, and/or data structures that may perform one or more particular tasks or that may implement one or more particular abstract data types. It is also to be understood that the number, configuration, functionality, and interconnection of the modules and components and subsystems of system 1 are only illustrative, and that the number, configuration, functionality, and interconnection of existing modules, components, and/or subsystems may be modified or omitted, additional modules, components, and/or subsystems may be added, and the interconnection of certain modules, components, and/or subsystems may be altered.

A neural network or neuronal network or artificial neural network or any suitable artificial intelligence, machine learning, and or computer algorithm may be hardware-based, software-based, or any combination thereof, such as any suitable model (e.g., a computational model), which, in some embodiments, may include one or more sets or matrices of weights (e.g., adaptive weights, which may be numerical parameters that may be tuned by one or more learning algorithms or training methods or other suitable processes) and/or may be capable of approximating one or more functions (e.g., non-linear functions or transfer functions) of its inputs (e.g., to predict or estimate certain outcomes based on any suitable input data). The weights may be connection strengths between neurons of the network, which may be activated during training and/or prediction. A neural network may generally be a system of interconnected neurons that can compute values from inputs and/or that may be capable of machine learning and/or pattern recognition (e.g., due to an adaptive nature). A neural network may use any suitable machine learning techniques to optimize a training process. A neural network may be used to estimate or approximate functions that can depend on a large number of inputs and that may be generally unknown. A neural network may generally be a system of interconnected “neurons” that may exchange messages between each other, where the connections may have numeric weights (e.g., initially configured with initial weight values) that can be tuned based on experience, making the neural network adaptive to inputs and capable of learning (e.g., learning pattern recognition). A suitable optimization or training process may be operative to modify a set of initially configured weights assigned to the output of one, some, or all neurons from the input(s) and/or hidden layer(s). A non-linear transfer function may be used to couple any two portions of any two layers of neurons, including an input layer, one or more hidden layers, and an output (e.g., an input to a hidden layer, a hidden layer to an output, etc.).

Different input neurons of a neural network may be associated with respective different types of data categories and may be activated by category data of a respective PM, PSP, DA, third party enabler subsystem, dispute, and/or the like. The weight assigned to the output of each neuron may be initially configured using any suitable determinations that may be made by PES subsystem 10 based on the data available to PES subsystem 10 or otherwise. Any suitable training methods or algorithms (e.g., learning algorithms) may be used to train a neural network of any functional engine of the PESP, including, but not limited to, Back Propagation, Resilient Propagation, Genetic Algorithms, Simulated Annealing, Levenberg, Nelder-Meade, and/or the like. Such training methods may be used individually and/or in different combinations to get the best performance from a neural network.

While there have been described systems, methods, and computer-readable media for a property enhancement service, it is to be understood that many changes may be made therein without departing from the spirit and scope of the subject matter described herein in any way. Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

Therefore, those skilled in the art will appreciate that the invention can be practiced by other than the described embodiments, which are presented for purposes of illustration rather than of limitation.

1. A method for managing property renovations using a construction analysis subsystem of a system further comprising a property manager subsystem of a property manager, a property designer subsystem of a property designer, and at least one property service provider subsystem of at least one respective property service provider, the method comprising:
receiving, at the construction analysis subsystem, a renovation objective for a renovation plan for a property from the property manager subsystem;
receiving, at the construction analysis subsystem, a plurality of scope elements for the received renovation objective from the property designer subsystem;
translating automatically, at the construction analysis subsystem, each scope element of the received plurality of scope elements into at least one type of construction activity;
receiving, at the construction analysis subsystem, work information for various construction activity types from the at least one property service provider subsystem; and
determining automatically, at the construction analysis subsystem, a work amount by the at least one property service provider for the received plurality of scope elements for the received renovation objective based on the received work information, wherein the receiving the work information is done prior to the receiving the renovation objective.

2. The method of claim 1, wherein the received work information comprises cost work information indicative of an estimated amount of money required by the at least one property service provider for at least one of the various construction activity types.

3. The method of claim 1, wherein the received work information comprises schedule work information indicative of an estimated amount of time required by the at least one property service provider for at least one of the various construction activity types.

4. The method of claim 1, wherein the received work information comprises:
cost work information indicative of an estimated amount of money required by the at least one property service provider for at least one of the various construction activity types; and
schedule work information indicative of an estimated amount of time required by the at least one property service provider for the at least one of the various construction activity types.

5. The method of claim 1, further comprising presenting the determined work amount to at least one of:
the property manager;
the property designer; or
the at least one property service provider.

6. The method of claim 1, wherein:
the receiving the work information comprises:
receiving, at the construction analysis system, first work information for the various construction activity types from a first property service provider of the at least one property service provider; and
receiving, at the construction analysis system, second work information for the various construction activity types from a second property service provider of the at least one property service provider; and
the determining automatically the work amount comprises:
determining automatically, at the construction analysis system, a first work amount by the first property service provider for the received plurality of scope elements for the received renovation objective based on the received first work information; and
determining automatically, at the construction analysis system, a second work amount by the second property service provider for the received plurality of scope elements for the received renovation objective based on the received second work information.

7. The method of claim 6, further comprising presenting the determined first work amount and the determined second work amount to at least one of:
the property manager; or
the property designer.

8. The method of claim 6, wherein:
the received first work information comprises first cost work information indicative of an estimated amount of money required by the first property service provider for at least one of the various construction activity types; and
the received second work information comprises second cost work information indicative of an estimated amount of money required by the second property service provider for at least one of the various construction activity types.

9. The method of claim 8, wherein:
the determined first work amount is indicative of an estimated amount of money required by the first property service provider for carrying out the received renovation objective; and
the determined second work amount is indicative of an estimated amount of money required by the second property service provider for carrying out the received renovation objective.

10. The method of claim 6, wherein:
the received first work information comprises first schedule work information indicative of an estimated amount of time required by the first property service provider for at least one of the various construction activity types; and
the received second work information comprises second schedule work information indicative of an estimated amount of time required by the second property service provider for at least one of the various construction activity types.

11. The method of claim 10, wherein:
the determined first work amount is indicative of an estimated amount of time required by the first property service provider for carrying out the received renovation objective; and
the determined second work amount is indicative of an estimated amount of time required by the second property service provider for carrying out the received renovation objective.

12. The method of claim 1, wherein:
the receiving the plurality of scope elements comprises:
receiving, at the construction analysis system, a first plurality of scope elements of a first scenario for the received renovation objective from the property designer; and
receiving, at the construction analysis system, a second plurality of scope elements of a second scenario for the received renovation objective from the property designer; and
the determining automatically the work amount comprises:
determining automatically, at the construction analysis system, a first work amount by the at least one property service provider for the received first plurality of scope elements of the first scenario for the received renovation objective based on the received work information; and
determining automatically, at the construction analysis system, a second work amount by the at least one property service provider for the received second plurality of scope elements of the second scenario for the received renovation objective based on the received work information.

13. The method of claim 12, wherein:
the received work information comprises cost work information indicative of an estimated amount of money required by the at least one property service provider for at least one of the various construction activity types;
the determined first work amount is indicative of an estimated amount of money required by the at least one property service provider for carrying out the first scenario for the received renovation objective; and
the determined second work amount is indicative of an estimated amount of money required by the at least one property service provider for carrying out the second scenario for the received renovation objective.

14. The method of claim 12, wherein:
the received work information comprises schedule work information indicative of an estimated amount of time required by the at least one property service provider for at least one of the various construction activity types;
the determined first work amount is indicative of an estimated amount of time required by the at least one property service provider for carrying out the first scenario for the received renovation objective; and
the determined second work amount is indicative of an estimated amount of time required by the at least one property service provider for carrying out the second scenario for the received renovation objective.

15. The method of claim 12, wherein:
the received work information comprises:
cost work information indicative of an estimated amount of money required by the at least one property service provider for at least one of the various construction activity types; and
schedule work information indicative of an estimated amount of time required by the at least one property service provider for at least one of the various construction activity types;
the determined first work amount is indicative of an estimated amount of money and an estimated amount of time required by the at least one property service provider for carrying out the first scenario for the received renovation objective; and
the determined second work amount is indicative of an estimated amount of money and an estimated amount of time required by the at least one property service provider for carrying out the second scenario for the received renovation objective.

16. (canceled)

17. The method of claim 1, further comprising:
presenting the determined work amount to the at least one property service provider; and
after the presenting, receiving, at the construction analysis system, adjusted work information for the at least one type of construction activity of the translation from the at least one property service provider.

18. The method of claim 17, further comprising, determining automatically, at the construction analysis system, an adjusted work amount by the at least one property service provider for the received plurality of scope elements for the received renovation objective based on the received adjusted work information.

19. A non-transitory computer-readable storage medium storing at least one program, the at least one program comprising instructions, which when executed by at least one processor of a construction analysis system, cause the construction analysis system to:
receive, at the construction analysis system, a renovation objective for a renovation plan for a property from a property manager;
receive, at the construction analysis system, a plurality of scope elements for the received renovation objective from a property designer;
translate automatically, at the construction analysis system, each scope element of the received plurality of scope elements into at least one type of construction activity;
receive, at the construction analysis system, work information for various construction activity types from at least one property service provider;
determine automatically, using a learning engine at the construction analysis system, a predicted work amount by the at least one property service provider for the received plurality of scope elements for the received renovation objective based on the received work information;
after the determination, receive, at the construction analysis system, an actual work amount carried out by the at least one property service provider for completing the received plurality of scope elements; and
train the learning engine using the received actual work amount.

20. A construction analysis system comprising:
a memory;
a communications component; and
a processor communicatively coupled to the memory and the communications component, the processor configured to:
receive, at the construction analysis system, a renovation objective for a renovation plan for a property from a property manager;
receive, at the construction analysis system, a plurality of scope elements for the received renovation objective from a property designer;
translate automatically, at the construction analysis system, each scope element of the received plurality of scope elements into at least one type of construction activity;
receive, at the construction analysis system, first work information for various construction activity types from at least one property service provider;
predict, using a learning engine at the construction analysis system, second work information based on the first work information and based on a geographic location of the property; and
determine automatically, at the construction analysis system, a work amount by the at least one property service provider for the received plurality of scope elements for the received renovation objective based on the predicted second work information.
